(19) United States
(12) Patent Application Publication
(10) Pub. No.: US 2020/0318255 A1
(43) Pub. Date: Oct. 8, 2020

(54) FAR-INFRARED, THz NANOCRYSTALS, HETEROSTRUCTURED MATERIAL WITH INTRABAND ABSORPTION FEATURE AND USES THEREOF

(71) Applicant: NEXDOT, Romainville (FR)

(72) Inventors: Emmanuel LHUILLIER, Paris (FR); Nicolas GOUBET, Limeil-Brévannes (FR); Amardeep JAGTAP, Le Kremlin-Bicetre (FR); Clément LIVACHE, Montrouge (FR); Yu-Pu LIN, Versailles (FR)

(73) Assignee: NEXDOT, Romainville (FR)

(21) Appl. No.: 16/753,533

(22) PCT Filed: Oct. 4, 2018
(86) PCT No.: PCT/EP2018/077006

§ 371 Date: Apr. 3, 2020

(30) Foreign Application Priority Data
Oct. 4, 2017 (FR) 1759276
Apr. 6, 2018 (FR) 1852988

(51) Int. Cl. C30B 29/48; C30B 7/14; H01L 31/0352; H01L 31/101; H01L 31/032

(52) U.S. Cl. CPC C30B 29/48; C30B 7/14; B82Y 20/00; H01L 31/101; H01L 31/0324; H01L 31/035218

(57) ABSTRACT

A plurality of metal chalcogenide nanocrystals AₙXₘ having an optical absorption feature above 12 μm and having a size superior to 20 nm. The metal A is selected from Hg, Pb, Ag, Bi, Cd, Sn, Sb or a mixture thereof. The chalcogen X is selected from S, Se, Te or a mixture thereof. The subscripts n and m are independently a decimal number from 0 to 5 and are not simultaneously equal to 0. Also, a method for manufacturing the plurality of metal chalcogenide nanocrystals AₙXₘ, a material, a photoabsorptive film, a photoconductor, photodetector, photodiode or phototransistor, a device, the use of the plurality of metal chalcogenide nanocrystals, and a reflective or transmission filter.

### FIELD OF INVENTION

The present invention pertains to the field of infrared optics. Especially, the present invention relates to metal chalcogenide nanocrystals, methods and devices in the field of LWIR (Long-Wavelength InfraRed) and THz with optical features above 12 μm; and to materials with intraband absorption feature.

### BACKGROUND OF INVENTION

Since the first synthesis of colloidal nanocrystals reported in the early 90's, lots of interest have been devoted to the integration of such nanocrystals into optoelectronic devices. Colloidal nanocrystals, also known as quantum dots, exhibit a bright and tunable luminescence in the visible range of wavelengths and a high stability due to their inorganic nature. Most of the efforts were focused on visible wavelengths at the early stage, and the idea to use these nanocrystals for applications such as lightning and bio-imaging rapidly appeared.

In the mid 2000's, materials such as lead chalcogenides (PbS) became popular because of their well suited band gap to absorb the near infrared part of the solar spectrum. Such nanocrystals were of great interest to address the absorption of the near IR range of wavelength of the sun light for photovoltaic application. It is only later that narrower band gap material with optical properties in the mid infrared have started to be synthetized.

However, the use of colloidal nanocrystals into optoelectronic applications have to compete with existing technology such as Complementary Metal Oxide Semiconductor (CMOS) or Indium Gallium Arsenide (InGaAs) which are far more mature and already cost effective. Nanocrystals may offer some interesting properties to compete with existing technologies if they can exhibit absorption above 12 μm and higher mobility.

US 2014/0299772 discloses a mid-infrared photodetector comprising HgTe nanoparticles and exhibiting an increased conductivity across the photoabsorptive layer under illumination with light at a wavelength in a range from 1.7 to 12 μm. In this patent and in Adv Mat 25, 137 (2013), the authors describe the use of HgTe colloidal quantum dots as infrared active material. However the transport properties and in particular the carrier mobility remain rather low (<0.1 cm²V⁻¹s⁻¹), which limits the overall photoresponse of the system.

WO2017/017238 discloses HgSe nanocrystals exhibiting an optical absorption feature in a range from 3 μm to 50 μm and a carrier mobility of at least 1 cm²V⁻¹s⁻¹. This was an important breakthrough in the field of infrared nanocrystals as a low mobility is highly detrimental for their photoconduction properties and remained a limitation. However, disclosed HgSe nanocrystals do not exhibit optical absorption feature above 50 μm. Indeed, the optical absorption feature disclosed in document WO2017/017238 is to date the reddest absorption which has been reported using HgSe nanocrystals.

To push even further the absorption to the VLWIR (Very Long-Wavelength InfraRed) and to the THz range of wavelengths, larger metal chalcogenide nanocrystals (such as mercury chalcogenide nanocrystals), typically larger than 20 nm, have to be synthetized. To date, such nanocrystals were not reported.

Furthermore, HgTe nanocrystals reported so far have anisotropic and faceted shapes (octahedron, tetrahedron) with exhibit poorly reactive facets which limit the growth of a shell on said nanocrystals. They also tend to aggregate in pairs leading to a loss of colloidal stability.

Document U.S. Pat. No. 7,402,832 describes a mid-infrared photodetector comprising HgTe nanoparticles and exhibiting an increased conductivity across the photoabsorptive layer under illumination with light at a wavelength in a range from 1.7 to 12 μm. However, disclosed device only uses interband photodetection.

Deng et al. discloses the design of photoconductive devices where the absorption relies on intraband transition in self-doped mercury chalcogenides compounds (Deng et al., ACS Nano, 2014, 8, 11707-11714). Such photoconductive devices based on intraband transition present a pretty high photoresponse. However, said devices suffer from a large dark current, which might be inherent to intraband device and their time response is slow (>s) (Lhuillier et al., IEEE Journal of Selected Topics in Quantum Electronics, 2017, 23, 1-8).

Two main strategies have been explored to improve the devices performances: i) tuning the surface chemistry toward short molecule to ensure good inter quantum dots coupling in a thin film of colloidal quantum dots; ii) synthetizing core shell structures wherein a wide band gap material is grown over a doped core material of HgSe or HgS (Lhuillier et al., Nano Letters, 2016, 16, 1282-1286; Shen et al., The Journal of Physical Chemistry C, 2016, 120, 11744-11753). However, i) the ligand exchange leads to a dramatic change of the absorption spectrum due to a surface gating effect which come as side effect of the tuning of the surface chemistry, and to a dramatic sensitivity of the film to its environment; ii) the introduction of the wide band gap shell leads to a complete disappearing of the intraband transition and the final material is only presenting near-IR interband transition.

Livache et al. disclose infrared nanocrystals based on mercury chalcogenides such as HgTe nanoplatelets having a record optical absorption feature at 12 μm and HgSe nanocrystals having an optical absorption feature ranging from 3 to 20 μm. (Livache et al., Proceedings of SPIE, 2017, vol. 10114). However, Livache et al. fails to teach nanocrystals having an optical absorption feature above 20 μm.

Document FR 3 039 531 and Lhuillier et al. disclose a plurality of metal chalcogenide nanocrystals wherein said metal is selected from Hg, Pb, Sn, Cd, Bi, Sb or a mixture thereof, and said chalcogen is selected from S, Se, Te or a mixture thereof (Lhuillier et al., Nano Letters, 2016, 16, 1282-1286). Said nanocrystals exhibit an optical absorption feature ranging from 3-50 μm. Said documents also disclose a method for manufacturing said plurality of metal chalcogenide nanocrystals. However, the metal precursor is a metal carboxylate which is more toxic and more expensive than halide precursors. The method disclosed does not allow the fabrication of nanocrystals exhibiting an optical absorption feature above 20 μm. Indeed, obtaining nanocrystals exhibiting an optical absorption feature above 20 μm would mean fabricating bigger nanocrystals; thus admixing withing the metal carboxylate precursor solution a chalcogenide precursor at a temperature higher than 130° C. However, the metal carboxylate precursor is not stable at such a temperature, and no nanocrystals can be obtained. Kershaw et al. discloses narrow bandgap colloidal metal chalcogenide nanocrystals and method for manufacturing said nanocrystals (Kershaw et al., Chemical Society Reviews, 2013, 42 (7), 3033). However, Kershaw et al.

does not disclose a method comprising a step of providing a solution comprising a halide precursor of a metal and a precursor of a chalcogen X (X being S, Se, Te or a mixture thereof) and a step of swiftly injecting said solution in degassed solution of coordinating solvent at a temperature ranging from 0 to 400° C. Indeed, Kershaw et al. only discloses methods comprising the injection of a chalcogen precursor in a solution comprising a metal precursor.

There is a real need for materials having an intraband transition, especially to push the absorption toward longer infrared wavelengths while keeping a good colloidal stability.

It is therefore an object of the present invention to provide a material having an intraband transition and presenting the following advantages: lower dark current; enhanced activation energy close to half the interband gap energy; high resistivity; good temperature dependence; fast time response; high charge carrier mobility.

A goal of the current invention is also to push further the optoelectronic properties of infrared nanocrystals. It is therefore an object of the present invention to provide metal chalcogenide nanocrystals with an improved colloidal stability; an extremely wide tunability of the nanocrystals size from 5 nm and up to several μm; a tunability of the optical absorption feature of the nanocrystals above 50 μm. Said metal chalcogenide nanocrystals are the first to address wavelength above 50 μm and in particular the THz range (λ>30 μm). This makes these nanoparticles promising candidates for optical filtering and optoelectronic applications.

### SUMMARY

According to a first aspect, the present invention relates to a plurality of metal chalcogenide nanocrystals AₙXₘ having an optical absorption feature above 12 μm and having a size superior to 20 nm;
wherein said metal A is selected from Hg, Pb, Ag, Bi, Cd, Sn, Sb or a mixture thereof;
wherein said chalcogen X is selected from S, Se, Te or a mixture thereof; and
wherein n and m are independently a decimal number from 0 to 5 and are not simultaneously equal to 0.

According to one embodiment, said nanocrystals have an isotropic shape.

According to a second aspect, the present invention relates to a method for manufacturing a plurality of metal chalcogenide nanocrystals AₙXₘ according to the first aspect of the present invention, said method comprising the following steps:
(a) heating a previously degassed solution of coordinating solvent at a temperature ranging from 0 to 400° C.;
(b) providing a solution comprising at least one precursor AYₚ and at least one precursor of the chalcogen X, wherein Y is Cl, Br or I;
(c) swiftly injecting the solution obtained at step (b) in the degassed solution of coordinating solvent at a temperature ranging from 0 to 400° C.;
(d) isolating the metal chalcogenide nanocrystals;
wherein said metal A is selected from Hg, Pb, Ag, Bi, Cd, Sn, Sb or a mixture thereof;
wherein said chalcogen X is selected from S, Se, Te or a mixture thereof; and
wherein n and m are independently a decimal number from 0 to 5 and are not simultaneously equal to 0;
wherein p is a decimal number from 0 to 5.

The present invention alsor relates to a material comprising a first optically active region comprising a first material presenting an intraband absorption feature, said first optically active region being a nanocrystal; a second optically inactive region comprising a semiconductor material having a bandgap superior to the energy of the intraband absorption feature of the first optically active region; and wherein said material presents an intraband absorption feature. In one embodiment, the semiconductor material has a doping level below 10¹⁸ cm⁻³. In one embodiment, the first material is doped. In one embodiment, the material presents an intraband absorption feature in a range from 0.8 μm to 12 μm. In one embodiment, the first material is selected from MₓEₘ, wherein M is a metal selected from Hg, Pb, Ag, Bi, Sn, Sb, Zn, In or a mixture thereof, and E is a chalcogen selected from S, Se, Te, O or a mixture thereof, and wherein x and m are independently a decimal number from 0 to 5 and are not simultaneously equal to 0; doped metal oxides; doped silicon; doped germanium; or a mixture thereof. In one embodiment, the semiconductor material is selected from N_{y}Zₙ, wherein N is a metal selected from Hg, Pb, Ag, Bi, Sn, Ga, In, Cd, Zn, Sb or a mixture thereof, and Z is selected from S, Se, Te, O, As, P or a mixture thereof, and wherein y and n are independently a decimal number from 0 to 5 and are not simultaneously equal to 0; metal oxides; silicon; germanium; perovskites; hybrid organic-inorganic perovskites; or a mixture thereof. In one embodiment, the material is a heterostructure. In one embodiment, the material is selected from HgSe/HgTe; HgS/HgTe; Ag₂Se/HgTe; Ag₂Se/PbS; Ag₂Se/PbSe; HgSe/PbS; HgS/PbS; HgSe/PbSe; HgS/PbSe; HgSe/CsPbI₃; HgSe/CsPbCl₃; HgSe/CsPbBr₃; HgS/CsPbI₃; HgS/CsPbCl₃; HgS/CsPbBr₃; Ag₂Se/CsPbI₃; Ag₂Se/CsPbCl₃; Ag₂Se/CsPbBr₃; HgS/CdS; HgSe/CdSe; doped Si/HgTe; doped Ge/HgTe; doped Si/PbS; doped Ge/PbS; doped ZnO/HgTe; doped ZnO/PbS; doped ZnO/ZnO; doped Si/Si; doped Ge/Ge; doped ZnO/Si; doped Si/ZnO; or a mixture thereof.

The present invention also relates to a photoabsorptive film comprising a plurality of metal chalcogenide nanocrystals of the invention, or at least one material of the invention.

The present invention also relates to an apparatus comprising:
a photoabsorptive layer comprising a photoabsorptive film of the invention, or at least one material of the invention; and
a first plurality of electrical connections bridging the photoabsorptive layer;
   wherein the photoabsorptive layer plurality of metal chalcogenide nanocrystals is positioned such that there is an increased conductivity between the electrical connections and across the photoabsorptive layer, in response to illumination of the photoabsortive layer with light at a wavelength ranging above 1.7 μm,

wherein said apparatus is a photoconductor, photodetector, photodiode or phototransistor.

In one embodiment, the photoabsorptive layer has a thickness ranging from 20 nm to 1 mm. In one embodiment, the photoabsorptive layer has an area ranging from 100 nm² to 1 m².

The present invention also relates to a device comprising a plurality of apparatus of the invention; and a readout circuit electrically connected to the plurality of apparatus.

The present invention also relates to the use of a plurality of metal chalcogenide nanocrystals of the invention, the material of the invention, or at least one film of the invention for optical filtering.

The present invention also relates to a reflective or transmission filter in 30-3000 μm range comprising a plurality of metal chalcogenide nanocrystals of the invention, the material of the invention, or at least one film of the invention.

The present invention also relates to the use of a plurality of metal chalcogenide nanocrystals of the invention, the material of the invention, or at least one film of the invention in paint.

The present invention also relates to a device comprising: at least one substrate; at least one electronic contact layer; at least one electron transport layer; and at least one photoactive layer; wherein said device has a vertical geometry. In one embodiment, the device further comprises at least one hole transport layer. In one embodiment, the at least one photoactive layer (34) is a layer or a film comprising a plurality of nanocrystals of the invention, the material of the invention, or at least one film of the invention. In one embodiment, the nanocrystals, the material or the film exhibit infrared absorption in the range from 800 nm to 12 μm. In one embodiment, the nanocrystals, the material or the film comprise a semiconductor material selected from the group consisting of group IV, group IIIA-VA, group IIA-VIA, group IIIA-VIA, group IA-IIIA-VIA, group IIA-VA, group IVA-VIA, group VIB-VIA, group VB-VIA, group IVB-VIA or mixture thereof. In one embodiment, the device further comprises at least one encapsulating layer. In one embodiment, the device comprises three encapsulating layers.

### Definitions

In the present invention, the following terms have the following meanings:
“Colloidal” refers to a substance in which particles are dispersed, suspended and do not settle or would take a very long time to settle appreciably, but are not soluble in said substance.
“Colloidal particles” refers to particles dispersed, suspended and which do not settle or would take a very long time to settle appreciably in another substance, typically in an aqueous or organic solvent, and which are not soluble in said substance.
“Core” refers to the innermost space within a particle.
“Free of oxygen” refers to a formulation, a solution, a film, or a composition that is free of molecular oxygen, O₂, i.e. wherein molecular oxygen may be present in said formulation, solution, film, or composition in an amount of less than about 10 ppm, 5 ppm, 4 ppm, 3 ppm, 2 ppm, 1 ppm, 500 ppb, 300 ppb or in an amount of less than about 100 ppb in weight.
“Free of water” refers to a formulation, a solution, a film, or a composition that is free of molecular water, H₂O, i.e. wherein molecular water may be present in said formulation, solution, film, or composition in an amount of less than about 100 ppm, 50 ppm, 10 ppm, 5 ppm, 4 ppm, 3 ppm, 2 ppm, 1 ppm, 500 ppb, 300 ppb or in an amount of less than about 100 ppb in weight.

“Intraband” refers to an optical transition, which is actually based on intraband transition within a single band or from a plasmonic absorption.
“Monodisperse” refers to particles or droplets, wherein the size difference is inferior than 20%, 15%, 10%, preferably 5%.
“Narrow size distribution” refers to a size distribution of a statistical set of particles less than 1%, 2%, 3%, 4%, 5%, 6%, 7%, 8%, 9%, 10%, 15%, 20%, 25%, 30%, 35%, or 40% of the average size.
“Optically transparent” refers to a material that absorbs less than 10%, 5%, 2.5%, 1%, 0.99%, 0.98%, 0.97%, 0.96%, 0.95%, 0.94%, 0.93%, 0.92%, 0.91%, 0.9%, 0.89%, 0.88%, 0.87%, 0.86%, 0.85%, 0.84%, 0.83%, 0.82%, 0.81%, 0.8%, 0.79%, 0.78%, 0.77%, 0.76%, 0.75%, 0.74%, 0.73%, 0.72%, 0.71%, 0.7%, 0.69%, 0.68%, 0.67%, 0.66%, 0.65%, 0.64%, 0.63%, 0.62%, 0.61%, 0.6%, 0.59%, 0.58%, 0.57%, 0.56%, 0.55%, 0.54%, 0.53%, 0.52%, 0.51%, 0.5%, 0.49%, 0.48%, 0.47%, 0.46%, 0.45%, 0.44%, 0.43%, 0.42%, 0.41%, 0.4%, 0.39%, 0.38%, 0.37%, 0.36%, 0.35%, 0.34%, 0.33%, 0.32%, 0.31%, 0.3%, 0.29%, 0.28%, 0.27%, 0.26%, 0.25%, 0.24%, 0.23%, 0.22%, 0.21%, 0.2%, 0.19%, 0.18%, 0.17%, 0.16%, 0.15%, 0.4%, 0.13%, 0.12%, 0.11%, 0.1%, 0.09%, 0.08%, 0.07%, 0.06%, 0.05%, 0.04%, 0.03%, 0.02%, 0.01%, 0.009%, 0.008%, 0.007%, 0.006%, 0.005%, 0.004%, 0.003%, 0.002%, 0.001%, 0.0009%, 0.0008%, 0.0007%, 0.0006%, 0.0005%, 0.0004%, 0.0003%, 0.0002%, 0.0001%, or 0% of light at wavelengths between 200 nm and 50 nm, between 200 nm and 12 nm.
“Partially” means incomplete. In the case of a ligand exchange, partially means that 5%, 10%, 15%, 20%, 25%, 30%, 35%, 40%, 45%, 50%, 55%, 60%, 65%, 70%, 75%, 80%, 85%, 90%, 95% of the ligands at the surface of a particle have been successfully exchanged.
“Pixel pitch” refers to the distance from the center of a pixel to the center of the next pixel.
“Polydisperse” refers to particles or droplets of varied sizes, wherein the size difference is superior or equal to 20%.
“Shell” refers to at least one monolayer of material coating partially or totally a core.
“Statistical set” refers to a collection of at least 2, 3, 4, 5, 6, 7, 8, 9, 10, 11, 12, 13, 14, 15, 16, 17, 18, 19, 20, 30, 40, 50, 60, 70, 80, 90, 100, 150, 200, 250, 300, 350, 400, 450, 500, 550, 600, 650, 700, 750, 800, 850, 900, 950, or 1000 objects obtained by the strictly same process. Such statistical set of objects allows determining average characteristics of said objects, for example their average size, their average size distribution or the average distance between them.
The terms “Film”, “Layer” or “Sheet” are interchangeable in the present invention.

### DETAILED DESCRIPTION

The following detailed description will be better understood when read in conjunction with the drawings. For the purpose of illustrating, the nanocrystals, material, method and devices are shown in the preferred embodiments. It should be understood, however that the application is not limited to the precise arrangements, structures, features, embodiments, and aspect shown. The drawings are not drawn to scale and are not intended to limit the scope of the claims to the embodiments depicted. Accordingly it should be understood that where features mentioned in the appended claims are followed by reference signs, such signs are included solely for the purpose of enhancing the intelligibility of the claims and are in no way limiting on the scope of the claims.

This invention relates to a plurality of metal chalcogenide nanocrystals AₙXₘ having an optical absorption feature above 12 μm and having a size distribution centered above 20 nm (illustrated in FIG. 1A-B);

wherein said metal A is selected from Hg, Pb, Ag, Bi, Cd, Sn, Sb or a mixture thereof;

wherein said chalcogen X is selected from S, Se, Te or a mixture thereof; and

wherein n and m are independently a decimal number from 0 to 5 and are not simultaneously equal to 0.

According to one embodiment, the metal chalcogenide nanocrystals comprise a narrow bandgap semiconductor material.

According to one embodiment, the metal chalcogenide nanocrystals comprise at least one semimetal.

According to one embodiment, examples of semimetal include but are not limited to: C, Bi, Sn, SnTe, HgTe, HgSe, Cd₃As₂.

According to one embodiment, the metal chalcogenide nanocrystals comprise at least one metal with a sparse density of state near the fermi energy.

According to one embodiment, A is selected from the group consisting of Ia, IIa, IIIa, IVa, IVb, IV, Vb, VIb, or mixture thereof; and X is selected from the group consisting of Va, VIa, or mixture thereof.

According to one embodiment, the metal chalcogenide nanocrystals comprise a semiconductor material selected from the group consisting of group IV, group IIIA-VA, group IIA-VIA, group IIIA-VIA, group IA-IIIA-VIA, group IIA-VA, group IVA-VIA, group VIB-VIA, group VB-VIA, group IVB-VIA or mixture thereof.

According to one embodiment, metal A is selected from the group consisting of Hg or a mixture of Hg and at least one of Pb, Ag, Sn, Cd, Bi, or Sb.

According to one embodiment, the metal chalcogenide nanocrystals comprise a material selected from the group consisting of HgS, HgSe, HgTe, HgₓCd₁₋ₓTe wherein x is a real number strictly included between 0 and 1, PbS, PbSe, PbTe, Bi₂S₃, Bi₂Se₃, Bi₂Te₃, SnS, SnS₂, SnTe, SnSe, Sb₂S₃, Sb₂Se₃, Sb₂Te₃, Ag₂S, Ag₂Se, Ag₂Te or alloys, or mixture thereof.

According to one embodiment, the metal chalcogenide nanocrystals comprise a mercury chalcogenide, or alloys, or mixture thereof.

According to one embodiment, the metal chalcogenide nanocrystals comprise a material selected from the group consisting of HgS, HgSe, HgTe, or alloys, or mixture thereof.

According to one embodiment, the metal chalcogenide nanocrystals comprise HgSe.

According to one embodiment, the metal chalcogenide nanocrystals consist of HgSe.

According to one embodiment, the metal chalcogenide nanocrystals comprise HgSeTe.

According to one embodiment, the metal chalcogenide nanocrystals consist of HgSeTe.

According to one embodiment, the metal chalcogenide nanocrystals comprise HgTe.

According to one embodiment, the metal chalcogenide nanocrystals consist of HgTe.

According to one embodiment, the metal chalcogenide nanocrystals comprise HgS.

According to one embodiment, the metal chalcogenide nanocrystals consist of HgS.

According to one embodiment, the metal chalcogenide nanocrystals do not comprise PbSe.

According to one embodiment, the metal chalcogenide nanocrystals have a cation rich surface.

According to one embodiment, the metal chalcogenide nanocrystals have an anion rich surface.

According to one embodiment, the metal chalcogenide nanocrystals have a size superior to 20 nm.

According to one embodiment, the metal chalcogenide nanocrystals have a size distribution centered above 20 nm.

According to one embodiment, the metal chalcogenide nanocrystals have an average size distribution centered above 20 nm.

According to one embodiment, the metal chalcogenide nanocrystals have an average size ranging from 20 nm to 10 μm, preferably between 20 nm to 2 μm, more preferably between 20 nm and 1 μm.

According to one embodiment, the metal chalcogenide nanocrystals have an average size of at least 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 55 nm, 60 nm, 65 nm, 70 nm, 75 nm, 80 nm, 85 nm, 90 nm, 95 nm, 100 nm, 105 nm, 110 nm, 115 nm, 120 nm, 125 nm, 130 nm, 135 nm, 140 nm, 145 nm, 150 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.1 μm, 1.2 μm, 1.3 μm, 1.4 μm, 1.5 μm, 1.6 μm, 1.7 μm, 1.8 μm, 1.9 μm, 2 μm, 2.1 μm, 2.2 μm, 2.3 μm, 2.4 μm, 2.5 μm, 2.6 μm, 2.7 μm, 2.8 μm, 2.9 μm, 3 μm, 3.1 μm, 3.2 μm, 3.3 μm, 3.4 μm, 3.5 μm, 3.6 μm, 3.7 μm, 3.8 μm, 3.9 μm, 4 μm, 4.1 μm, 4.2 μm, 4.3 μm, 4.4 μm, 4.5 μm, 4.6 μm, 4.7 μm, 4.8 μm, 4.9 μm, 5 μm, 5.1 μm, 5.2 μm, 5.3 μm, 5.4 μm, 5.5 μm, 5.6 μm, 5.7 μm, 5.8 μm, 5.9 μm, 6 μm, 6.1 μm, 6.2 μm, 6.3 μm, 6.4 μm, 6.5 μm, 6.6 μm, 6.7 μm, 6.8 μm, 6.9 μm, 7 μm, 7.1 μm, 7.2 μm, 7.3 μm, 7.4 μm, 7.5 μm, 7.6 μm, 7.7 μm, 7.8 μm, 7.9 μm, 8 μm, 8.1 μm, 8.2 μm, 8.3 μm, 8.4 μm, 8.5 μm, 8.6 μm, 8.7 μm, 8.8 μm, 8.9 μm, 9 μm, 9.1 μm, 9.2 μm, 9.3 μm, 9.4 μm, 9.5 μm, 9.6 μm, 9.7 μm, 9.8 μm, 9.9 μm, or 10 μm.

According to one embodiment, the largest dimension of the metal chalcogenide nanocrystals is at least 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 105 nm, 110 nm, 115 nm, 120 nm, 125 nm, 130 nm, 135 nm, 140 nm, 145 nm, 150 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.1 μm, 1.2 μm, 1.3 μm, 1.4 μm, 1.5 μm, 1.6 μm, 1.7 μm, 1.8 μm, 1.9 μm, 2 μm, 2.1 μm, 2.2 μm, 2.3 μm, 2.4 μm, 2.5 μm, 2.6 μm, 2.7 μm, 2.8 μm, 2.9 μm, 3 μm, 3.1 μm, 3.2 μm, 3.3 μm, 3.4 μm, 3.5 μm, 3.6 μm, 3.7 μm, 3.8 μm, 3.9 μm, 4 μm, 4.1 μm, 4.2 μm, 4.3 μm, 4.4 μm, 4.5 μm, 4.6 μm, 4.7 μm, 4.8 μm, 4.9 μm, 5 μm, 5.1 μm, 5.2 μm, 5.3 μm, 5.4 μm, 5.5 μm, 5.6 μm, 5.7 μm, 5.8 μm, 5.9 μm, 6 μm, 6.1 μm, 6.2 μm, 6.3 μm, 6.4 μm, 6.5 μm, 6.6 μm, 6.7 μm, 6.8 μm, 6.9 μm, 7 μm, 7.1 μm, 7.2 μm, 7.3 μm, 7.4 μm, 7.5 μm, 7.6 μm, 7.7 μm, 7.8 μm, 7.9 μm, 8 μm, 8.1 μm, 8.2 μm, 8.3 μm, 8.4 μm, 8.5 μm, 8.6 μm, 8.7 μm, 8.8 μm, 8.9 μm, 9 μm, 9.1 μm, 9.2 μm, 9.3 μm, 9.4 μm, 9.5 μm, 9.6 μm, 9.7 μm, 9.8 μm, 9.9 μm, or 10 μm.

According to one embodiment, the smallest dimension of the metal chalcogenide nanocrystals is superior to 20 nm.

According to one embodiment, the metal chalcogenide nanocrystals have a size distribution of their smallest dimension centered above 20 nm.

According to one embodiment, the smallest dimension of the metal chalcogenide nanocrystals is at least 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 30 nm, 40 nm, 50 nm, 60 nm, 70 nm, 80 nm, 90 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.1 μm, 1.2 μm, 1.3 μm, 1.4 μm, 1.5 μm, 1.6 μm, 1.7 μm, 1.8 μm, 1.9 μm, 2 μm, 2.1 μm, 2.2 μm, 2.3 μm, 2.4 μm, 2.5 μm, 2.6 μm, 2.7 μm, 2.8 μm, 2.9 μm, 3 μm, 3.1 μm, 3.2 μm, 3.3 μm, 3.4 μm, 3.5 μm, 3.6 μm, 3.7 μm, 3.8 μm, 3.9 μm, 4 μm, 4.1 μm, 4.2 μm, 4.3 μm, 4.4 μm, 4.5 μm, 4.6 μm, 4.7 μm, 4.8 μm, 4.9 μm, 5 μm, 5.1 μm, 5.2 μm, 5.3 μm, 5.4 μm, 5.5 μm, 5.6 μm, 5.7 μm, 5.8 μm, 5.9 μm, 6 μm, 6.1 μm, 6.2 μm, 6.3 μm, 6.4 μm, 6.5 μm, 6.6 μm, 6.7 μm, 6.8 μm, 6.9 μm, 7 μm, 7.1 μm, 7.2 μm, 7.3 μm, 7.4 μm, 7.5 μm, 7.6 μm, 7.7 μm, 7.8 μm, 7.9 μm, 8 μm, 8.1 μm, 8.2 μm, 8.3 μm, 8.4 μm, 8.5 μm, 8.6 μm, 8.7 μm, 8.8 μm, 8.9 μm, 9 μm, 9.1 μm, 9.2 μm, 9.3 μm, 9.4 μm, 9.5 μm, 9.6 μm, 9.7 μm, 9.8 μm, 9.9 μm, or 10 μm.

According to one embodiment, the smallest dimension of the metal chalcogenide nanocrystals is smaller than the largest dimension of said nanocrystals by a factor (aspect ratio) of at least 1.5; at least 2; at least 2.5; at least 3; at least 3.5; at least 4; at least 4.5; at least 5; at least 5.5; at least 6; at least 6.5; at least 7; at least 7.5; at least 8; at least 8.5; at least 9; at least 9.5; at least 10; at least 10.5; at least 11; at least 11.5; at least 12; at least 12.5; at least 13; at least 13.5; at least 14; at least 14.5; at least 15; at least 15.5; at least 16; at least 16.5; at least 17; at least 17.5; at least 18; at least 18.5; at least 19; at least 19.5; at least 20; at least 25; at least 30; at least 35; at least 40; at least 45; at least 50; at least 55; at least 60; at least 65; at least 70; at least 75; at least 80; at least 85; at least 90; at least 95; at least 100, at least 150, at least 200, at least 250, at least 300, at least 350, at least 400, at least 450, at least 500, at least 550, at least 600, at least 650, at least 700, at least 750, at least 800, at least 850, at least 900, at least 950, or at least 1000.

According to one embodiment, the metal chalcogenide nanocrystals have at least one dimension, namely length, width, thickness, or diameter, superior to 20 nm.

According to one embodiment, the metal chalcogenide nanocrystals with a size superior to 12 nm are n-type semiconductors.

According to one embodiment, the metal chalcogenide nanocrystals with a size superior to 12 nm present only electron conduction.

According to one embodiment, the metal chalcogenide nanocrystals with a size less than 5 nm are p-type semiconductors.

According to one embodiment, the metal chalcogenide nanocrystals with a size less than 5 nm present a higher hole conduction compared to the electron conduction.

According to one embodiment, the metal chalcogenide nanocrystals with a size from 5 nm to 12 nm present both hole and electron conduction.

According to one embodiment illustrated in FIG. 9, as the nanocrystals size increases, said nanocrystals switch from p-type semiconductors (conduction under hole injection, see FIG. 9A) to ambipolar (FIG. 9B) and finally to n-type only (conduction under electron injection, see FIG. 9C) for the largest sizes.

“Ambipolar” material refers to a material exhibiting both electron and hole mobility.

According to one embodiment, the metal chalcogenide nanocrystals are polydisperse.

According to one embodiment, the metal chalcogenide nanocrystals are monodisperse.

According to one embodiment, the metal chalcogenide nanocrystals have a narrow size distribution.

According to one embodiment, the size distribution for the average size of a statistical set of metal chalcogenide nanocrystals is inferior than 1%, 2%, 3%, 4%, 5%, 6%, 7%, 8%, 9%, 10%, 15%, 20%, 25%, 30%, 35%, or 40% of said average size.

According to one embodiment, the size distribution for the smallest dimension of a statistical set of metal chalcogenide nanocrystals is inferior than 1%, 2%, 3%, 4%, 5%, 6%, 7%, 8%, 9%, 10%, 15%, 20%, 25%, 30%, 35%, or 40% of said smallest dimension.

According to one embodiment, the size distribution for the largest dimension of a statistical set of metal chalcogenide nanocrystals inferior than 1%, 2%, 3%, 4%, 5%, 6%, 7%, 8%, 9%, 10%, 15%, 20%, 25%, 30%, 35%, or 40% of said largest dimension.

According to one embodiment, the metal chalcogenide nanocrystals have an isotropic shape.

According to one embodiment, the metal chalcogenide nanocrystals have an anisotropic shape.

According to one embodiment, the metal chalcogenide nanocrystals have a 0D, 1D or 2D dimension.

In one embodiment, examples of shape of metal chalcogenide nanocrystals include but are not limited to: quantum dots, sheet, rod, platelet, plate, prism, wall, disk, nanoparticle, wire, tube, tetrapod, ribbon, belt, needle, cube, ball, coil, cone, piller, flower, sphere, faceted sphere, polyhedron, bar, monopod, bipod, tripod, star, octopod, snowflake, thorn, hemisphere, urchin, filamentous nanoparticle, biconcave discoid, worm, tree, dendrite, necklace, chain, plate triangle, square, pentagon, hexagon, ring, tetrahedron, truncated tetrahedron, or combination thereof.

According to one embodiment, the metal chalcogenide nanocrystals are quantum dots.

According to one embodiment illustrated in FIG. 1B, the metal chalcogenide nanocrystals have a spherical shape.

According to one embodiment, spherical metal chalcogenide nanocrystals have a diameter ranging from 20 nm to 10 μm, preferably between 20 nm to 2 μm, more preferably between 20 nm and 1 μm.

According to one embodiment, spherical metal chalcogenide nanocrystals have a diameter of at least 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 30 nm, 40 nm, 50 nm, 60 nm, 70 nm, 80 nm, 90 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.1 μm, 1.2 μm, 1.3 μm, 1.4 μm, 1.5 μm, 1.6 μm, 1.7 μm, 1.8 μm, 1.9 μm, 2 μm, 2.1 μm, 2.2 μm, 2.3 μm, 2.4 μm, 2.5 μm, 2.6 μm, 2.7 μm, 2.8 μm, 2.9 μm, 3 μm, 3.1 μm, 3.2 μm, 3.3 μm, 3.4 μm, 3.5 μm, 3.6 μm, 3.7 μm, 3.8 μm, 3.9 μm, 4 μm, 4.1 μm, 4.2 μm, 4.3 μm, 4.4 μm, 4.5 μm, 4.6 μm, 4.7 μm, 4.8 μm, 4.9 μm, 5 μm, 5.1 μm, 5.2 μm, 5.3 μm, 5.4 μm, 5.5 μm, 5.6 μm, 5.7 μm, 5.8 μm, 5.9 μm, 6 μm, 6.1 μm, 6.2 μm, 6.3 μm, 6.4 μm, 6.5 μm, 6.6 μm, 6.7 μm, 6.8 μm, 6.9 μm, 7 μm, 7.1 μm, 7.2 μm, 7.3 μm, 7.4 μm, 7.5 μm, 7.6 μm, 7.7 μm, 7.8 μm, 7.9 μm, 8 μm, 8.1 μm, 8.2 μm, 8.3 μm, 8.4 μm, 8.5 μm, 8.6 μm, 8.7 μm, 8.8 μm, 8.9 μm, 9 μm, 9.1 μm, 9.2 μm, 9.3 μm, 9.4 μm, 9.5 μm, 9.6 μm, 9.7 μm, 9.8 μm, 9.9 μm, or 10 μm.

According to one embodiment illustrated in FIG. 1B, the metal chalcogenide nanocrystals are faceted.

According to one embodiment, the metal chalcogenide nanocrystals comprises at least one facet.

According to one embodiment illustrated in FIG. 1B, the metal chalcogenide nanocrystals are not faceted. This embodiment will allow the growth of a shell on said metal chalcogenide nanocrystals as poor reactive facets can limit such growth.

According to one embodiment, HgTe nanocrystals comprise reactive facets. In this embodiment, unreactive facets include but are not limited to (111) facets.

According to one embodiment, HgSe nanocrystals comprise reactive facets. In this embodiment, unreactive facets include but are not limited to (111) facets.

According to one embodiment, the metal chalcogenide nanocrystals are not aggregated. This embodiment prevents the loss of colloidal stability.

According to one embodiment, the metal chalcogenide nanocrystals are aggregated.

According to one embodiment, the metal chalcogenide nanocrystals are crystalline nanoparticle.

According to one embodiment, the metal chalcogenide nanocrystals are colloidal nanocrystals.

According to one embodiment, the metal chalcogenide nanocrystals are homostructures. In this embodiment, the metal chalcogenide nanocrystals are core nanoparticles without a shell.

According to one embodiment, the metal chalcogenide nanocrystals are heterostructures. In this embodiment, the metal chalcogenide nanocrystals comprise a core and at least one shell.

According to one embodiment, the metal chalcogenide nanocrystals are core/shell nanocrystals. In this embodiment, a metal chalcogenide nanocrystal comprises a core and at least one overcoating or at least one shell on the surface of said core.

According to one embodiment, the metal chalcogenide nanocrystals are core/shell nanocrystals, wherein the core is partially or totally covered with at least one shell comprising at least one layer of material.

According to one embodiment, the metal chalcogenide nanocrystals are core/shell nanocrystals, wherein the core is covered with at least one shell.

According to one embodiment, the at least one shell has a thickness ranging from 0.2 nm to 10 mm, from 0.2 nm to 1 mm, from 0.2 nm to 100μm, from 0.2 nm to 10 μm, from 0.2 nm to 1 μm, from 0.2 nm to 500 nm, from 0.2 nm to 250 nm, from 0.2 nm to 100 nm, from 0.2 nm to 50 nm, from 0.2 nm to 25 nm, from 0.2 nm to 20 nm, from 0.2 nm to 15 nm, from 0.2 nm to 10 nm or from 0.2 nm to 5 nm.

According to one embodiment, the at least one shell has a thickness of at least 0.2 nm, 0.3 nm, 0.4 nm, 0.5 nm, 1 nm, 1.5 nm, 2 nm, 2.5 nm, 3 nm, 3.5 nm, 4 nm, 4.5 nm, 5 nm, 5.5 nm, 6 nm, 6.5 nm, 7 nm, 7.5 nm, 8 nm, 8.5 nm, 9 nm, 9.5 nm, 10 nm, 10.5 nm, 11 nm, 11.5 nm, 12 nm, 12.5 nm, 13 nm, 13.5 nm, 14 nm, 14.5 nm, 15 nm, 15.5 nm, 16 nm, 16.5 nm, 17 nm, 17.5 nm, 18 nm, 18.5 nm, 19 nm, 19.5 nm, 20 nm, 30 nm, 40 nm, 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 300 μm, 400 μm, 500 μm, 600 μm, 700 μm, 800 μm, 900 μm, 1 mm, 1.5 mm, 2 mm, 2.5 mm, 3 mm, 3.5 mm, 4 mm, 4.5 mm, 5 mm, 5.5 mm, 6 mm, 6.5 mm, 7 mm, 7.5 mm, 8 mm, 8.5 mm, 9 mm, 9.5 mm, or 10 mm

According to one embodiment, the core/shell nanocrystals have an average size or diameter of at least 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 30 nm, 40 nm, 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 8.2 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100μm, 200 μm, 300 μm, 400 μm, 500 μm, 600 μm, 700 μm, 800 μm, 900 μm, 1 mm, 1.5 mm, 2 mm, 2.5 mm, 3 mm, 3.5 mm, 4 mm, 4.5 mm, 5 mm, 5.5 mm, 6 mm, 6.5 mm, 7 mm, 7.5 mm, 8 mm, 8.5 mm, 9 mm, 9.5 mm, or 10 mm

According to one embodiment, the shell comprises a semiconductor material.

According to one embodiment, the shell comprises a material AₙXₘ as described hereabove.

According to one embodiment, the shell comprises a material selected from the group consisting of CdS, CdSe, PbS, PbSe, PbTe, ZnO, ZnS, ZnSe, HgS, HgSe, HgTe, HgₓCd₁₋ₓTe wherein x is a real number strictly included between 0 and 1, Bi₂S₃, Bi₂Se₃, Bi₂Te₃, SnS, SnS₂, SnTe, SnSe, Sb₂S₃, Sb₂Se₃, Sb₂Te₃, or alloys, or mixture thereof.

According to one embodiment, the metal chalcogenide nanocrystals are core/shell nanocrystals, wherein the core and the shell are composed of the same material.

According to one embodiment, the metal chalcogenide nanocrystals are core/shell nanocrystals, wherein the core and the shell are composed of at least two different materials.

According to one embodiment, the metal chalcogenide nanocrystals are undoped nanocrystals.

According to one embodiment, the metal chalcogenide nanocrystals are doped nanocrystals.

According to one embodiment, the metal chalcogenide nanocrystals are intrinsic semiconductor nanocrystals.

According to one embodiment, the metal chalcogenide nanocrystals are extrinsic semiconductor nanocrystals.

According to one embodiment, the metal chalcogenide nanocrystals comprise at least one additional element in minor quantities. The term “minor quantities” refers herein to quantities ranging from 0.0001% to 10% molar, preferably from 0.001% to 10% molar.

According to one embodiment, the metal chalcogenide nanocrystals comprise at least one transition metal or lanthanide in minor quantities. The term “minor quantities” refers herein to quantities ranging from 0.0001% to 10% molar, preferably from 0.001% to 10% molar.

According to one embodiment, the metal chalcogenide nanocrystals comprise in minor quantities at least one element inducing an excess or a defect of electrons compared to the sole nanocrystal. The term “minor quantities” refers herein to quantities ranging from 0.0001% to 10% molar, preferably from 0.001% to 10% molar.

According to one embodiment, the metal chalcogenide nanocrystals comprise in minor quantities at least one element inducing a modification of the optical properties compared to the sole nanocrystal. The term “minor quantities” refers herein to quantities ranging from 0.0001% to 10% molar, preferably from 0.001% to 10% molar.

According to one embodiment, examples of additional element include but are not limited to: Ag⁺, Cu⁺and Bi³⁺.

According to one embodiment, the doping is induced by surface effect.

According to one embodiment, the doping is induced by the reduction of the metal chalcogenide nanocrystals by their environment.

According to one embodiment, the doping is induced by the reduction of the metal chalcogenide nanocrystals by water.

According to one embodiment, the doping of the metal chalcogenide nanocrystals is a n-type doping.

According to one embodiment, the metal chalcogenide nanocrystals are doped by electrochemistry.

According to one embodiment, the doping magnitude can be controlled by changing the capping ligands.

According to one embodiment, the doping magnitude depends on the surface dipole associated with the molecule at the metal chalcogenide nanocrystal surface.

According to one embodiment, the doping is induced by non-stoichiometry of said metal chalcogenide nanocrystals.

According to one embodiment, the doping is induced by impurity or impurities.

According to one embodiment, the doping can be tuned while tuning the surface chemistry.

According to one embodiment, the doping can be tuned using electrochemistry.

According to one embodiment, the doping can be tuned by a gate.

According to one embodiment, the doping of the metal chalcogenide nanocrystals is between 0 and 2 electrons per nanocrystal.

According to one embodiment, the doping of the metal chalcogenide nanocrystals is between 0 and 1000 electrons per nanocrystal, preferably between 0.01 and 100 electrons per nanocrystal, more preferably between 0.1 and 50 electrons per nanocrystal.

According to one embodiment, each the metal chalcogenide nanocrystal comprises less than 100 dopants, preferably less than 10 dopants per nanocrystal.

According to one embodiment, the doping level ranges from 10⁻¹⁵ cm⁻³ and 10⁻²¹ cm⁻³, preferably between 10⁻¹⁷ cm⁻³ and 10⁻²⁰ cm⁻³, more preferably 10⁻¹⁸ cm⁻³ and 10⁻²⁰ cm⁻³.

According to one embodiment, the metal chalcogenide nanocrystals comprise a doped semiconductor material.

According to one embodiment, the metal chalcogenide nanocrystals comprise a doped semiconductor material such as for example Indium Tin Oxide (ITO), Aluminium Zinc Oxide (AZO), or Fluorine Tin Oxide (FTO).

According to one embodiment, the metal chalcogenide nanocrystals are coated with ligands. In this embodiment, ligands may be inorganic ligands and/or organic ligands.

According to one embodiment, the ligand density of the nanocrystal surface ranging from 0.01 ligand.nm⁻² to 100 ligands.nm⁻², preferably from 0.1 ligand.nm⁻² to 10 ligands.nm⁻².

According to one embodiment, the ratio between organic ligands and inorganic ligands of the nanocrystal surface is ranging from 0.001 to 0.25, preferably from 0.001 to 0.2, more preferably from 0.001 to 0.1 or even more preferably from 0.001 to 0.01.

According to one embodiment, the metal chalcogenide nanocrystals are coated with inorganic ligands.

According to one embodiment, the metal chalcogenide nanocrystals are coated with at least one inorganic ligand.

According to one embodiment, examples of inorganic ligands include but are not limited to: S²⁻, HS⁻, Se²⁻, Te²⁻, OH⁻, BF₄⁻, PF₆⁻, Cl⁻, Br⁻, I⁻, As₂S₃, As₂Se₃, Sb₂S₃, As₂Te₃, Sb₂S₃, Sb₂Se₃, Sb₂Te₃, CdSe, CdTe SnS₂, AsS³⁺, LiS₂, FeS₂, Cu₂S or a mixture thereof.

According to one embodiment, the inorganic ligand is As₂Se₃.

According to one embodiment, the metal chalcogenide nanocrystals do not comprise HgTe nanocrystals coated with As₂S₃.

According to one embodiment, the metal chalcogenide nanocrystals do consist in HgTe nanocrystals coated with As₂S₃.

According to one embodiment, the inorganic ligand density of the nanocrystal surface ranges from 0.01 ligand.nm⁻² to 100 ligands.nm⁻², preferably from 0.1 ligand.nm⁻² to 10 ligands.nm⁻².

According to one embodiment, the metal chalcogenide nanocrystals are coated with organic ligands.

According to one embodiment, the metal chalcogenide nanocrystals are coated with at least one organic ligand.

According to one embodiment, the metal chalcogenide nanocrystals are coated with an organic shell. In this embodiment, the organic shell may be made of organic ligands.

According to one embodiment, examples of organic ligands include but are not limited to: thiol, amine, carboxylic acid, phosphine, phosphine oxide, or mixture thereof.

According to one embodiment, examples of thiol include but are not limited to: methanethiol, ethanedithiol, propanethiol, octanethiol, dodecanethiol, octadecanethiol, decanethiol, or mixture thereof.

According to one embodiment, examples of amine include but are not limited to: propylamine, butylamine, heptadiamine, octylamine, oleylamine, dodecylamine, octadecylamine, tetradecylamine, aniline, 1,6-hexanediamine, or mixture thereof.

According to one embodiment, examples of carboxylic acid include but are not limited to: oleic acid, myristic acid, octanoic acid, 4-mercaptobenzoic acid, stearic acid, arachidic acid. Decanoic acid, butyric acid, ethanoic acid, methanoic acid, or mixture thereof.

According to one embodiment, examples of phosphine include but are not limited to: tributylphosphine, trioctylphosphine, phenylphosphine, diphenylphosphine or mixture thereof.

According to one embodiment, examples of phosphine oxide include but are not limited to: trioctylphosphine oxide.

According to one embodiment, the organic ligand density of the nanocrystal surface ranges from 0.01 ligand.nm⁻² to 100 ligands.nm⁻², preferably from 0.1 ligand.nm⁻² to 10 ligands.nm⁻².

According to one embodiment, the metal chalcogenide nanocrystals have optical absorption features in the visible, near IR, mid IR, far IR, and/or THz.

According to one embodiment, the metal chalcogenide nanocrystals have optical absorption features in the SWIR (Short-Wavelength InfraRed), MWIR (Mid-Wavelength

InfraRed), LWIR (Long-Wavelength InfraRed), VLWIR (Very Long-Wavelength InfraRed) and/or THz range of wavelengths.

FIG. 3 illustrates the cut off wavelength of the interband transition as a function of the nanocrystals size comparing nanocrystals of the present invention and nanocrystals of prior arts (Kovalenko et al., Journal of the American Chemical Society, Vol. 128(11), pp. 3516-3517; Lhuillier et al., Nano Letters, Vol. 16(2), pp. 1282-1286). Nanocrystals from the invention have optical absorption features in the SWIR (Short-Wavelength InfraRed), MWIR (Mid-Wavelength InfraRed), LWIR (Long-Wavelength InfraRed), VLWIR (Very Long-Wavelength InfraRed) and THz range, whereas nanocrystals from prior arts only exhibit absorption features from SWIR to VLWIR.

According to one embodiment, the metal chalcogenide nanocrystals have optical absorption features coming from interband transition.

According to one embodiment, the metal chalcogenide nanocrystals have optical absorption features coming from intraband transition.

According to one embodiment, the metal chalcogenide nanocrystals have optical absorption features coming from plasmonic effect.

According to one embodiment, the absorption is a combination of interband, intraband and/or plasmonic effect.

According to one embodiment as illustrated in FIG. 2A-B, the metal chalcogenide nanocrystals have optical absorption features from 400 nm to 3000 μm, preferably from 2 μm to 200 μm, more preferably from 50 μm to 200 μm.

According to one embodiment, the metal chalcogenide nanocrystals have optical absorption features from 1 μm to 3 μm.

According to one embodiment, the metal chalcogenide nanocrystals have optical absorption features from 3 μm to 5 μm.

According to one embodiment, the metal chalcogenide nanocrystals have optical absorption features from 3 μm to 8 μm.

According to one embodiment, the metal chalcogenide nanocrystals have optical absorption features from 8 μm to 15 μm.

According to one embodiment, the metal chalcogenide nanocrystals have optical absorption features from 8 μm to 12 μm.

According to one embodiment, the metal chalcogenide nanocrystals have optical absorption features from 12 μm to 30 μm.

According to one embodiment, the metal chalcogenide nanocrystals have optical absorption features from 30 μm to 300 μm.

According to one embodiment, the metal chalcogenide nanocrystals have optical absorption features from 50 μm to 300 μm.

According to one embodiment, the metal chalcogenide nanocrystals have optical absorption features above 50 μm.

According to one embodiment, the metal chalcogenide nanocrystals only have optical absorption features strictly above 50 μm. In this embodiment, the metal chalcogenide nanocrystals do not have optical absorption features at wavelengths shorter than or equal to 50 μm.

According to one embodiment, the metal chalcogenide nanocrystals have optical absorption features at wavelengths shorter than or equal to 50 μm and at wavelengths above 50 μm.

According to one embodiment, the metal chalcogenide nanocrystals only have optical absorption features above 50 μm, i.e. at wavelengths superior or equal to 50 μm. In this embodiment, the metal chalcogenide nanocrystals do not have optical absorption features at wavelengths shorter than 50 μm.

According to one embodiment, the metal chalcogenide nanocrystals have optical absorption features above 400 nm, 450 nm, 500 nm, 550 nm, 600 nm, 650 nm, 700 nm, 750 nm, 800 nm, 850 nm, 900 nm, 950 nm, 1 μm, 2 μm, 3 μm, 4 μm, 5 μm, 6 μm, 7 μm, 8 μm, 9 μm, 10 μm, 11 μm, 12 μm, 13 μm, 14 μm, 15 μm, 16 μm, 17 μm, 18 μm, 19 μm, 20 μm, 25 μm, 30 μm, 35 μm, 40 μm, 45 μm, 50 μm, 55 μm, 60 μm, 65 μm, 70 μm, 75 μm, 80 μm, 85 μm, 90 μm, 95 μm, 100 μm, 150 μm 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, 1000 μm, 1100 μm, 1200 μm, 1300 μm, 1400 μm, 1500 μm, 1600 μm, 1700 μm, 1800 μm, 1900 μm, 2000 μm, 2100 μm, 2200 μm, 2300 μm, 2400 μm, 2500 μm, 2600 μm, 2700 μm, 2800 μm, or 2900 μm.

According to one embodiment, the metal chalcogenide nanocrystals exhibit an optical absorption peak at a wavelength in a range from 1 μm to 2 μm, 3 μm, 4 μm, 5 μm, 6 μm, 7 μm, 8 μm, 9 μm, 10 μm, 11 μm, 12 μm, 13 μm, 14 μm, 15 μm, 16 μm, 17 μm, 18 μm, 19 μm, 20 μm, 21 μm, 22 μm, 23 μm, 24 μm, 25 μm, 26 μm, 27 μm, 28 μm, 29 μm, 30 μm, 31 μm, 32 μm, 33 μm, 34 μm, 35 μm, 36 μm, 37 μm, 38 μm, 39 μm, 40 μm, 41 μm, 42 μm, 43 μm, 44 μm, 45 μm, 46 μm, 47 μm, 48 μm, 49 μm, 50 μm, 55 μm, 60 μm, 65 μm, 70 μm, 75 μm, 80 μm, 85 μm, 90 μm, 95 μm, 100μm, 150 μm 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, 1000 μm, 1100 μm, 1200 μm, 1300 μm, 1400 μm, 1500 μm, 1600 μm, 1700 μm, 1800 μm, 1900 μm, 2000 μm, 2100 μm, 2200 μm, 2300 μm, 2400 μm, 2500 μm, 2600 μm, 2700 μm, 2800 μm, or 2900 μm.

According to one embodiment, the metal chalcogenide nanocrystals have optical absorption features due to interband transition up to 5 μm.

According to one embodiment, the metal chalcogenide nanocrystals have optical absorption features due to interband transition up to 12 μm.

According to one embodiment, the metal chalcogenide nanocrystals have optical absorption features due to interband transition up to 30 μm.

According to one embodiment, the metal chalcogenide nanocrystals have optical absorption features due to interband transition up to 50 μm.

According to one embodiment, the metal chalcogenide nanocrystals have optical absorption features due to intraband transition which is peaked between 3 μm and 80 μm.

According to one embodiment, the metal chalcogenide nanocrystals have optical absorption features due to intraband transition which is peaked between 3 μm and 6 μm.

According to one embodiment, the metal chalcogenide nanocrystals have optical absorption features due to intraband transition which is peaked between 8 μm and 12 μm.

According to one embodiment, the metal chalcogenide nanocrystals have optical absorption features due to intraband transition which is peaked between 12 μm and 80 μm.

According to one embodiment, the metal chalcogenide nanocrystals have optical absorption features due to intraband transition with a full width at half maximum of less than 2000 cm⁻¹, 1900 cm⁻¹, 1800 cm⁻¹, 1700 cm⁻¹, 1600 cm⁻¹, 1500 cm⁻¹, 1400 cm⁻¹, 1300 cm⁻¹, 1200 cm⁻¹, 1100 cm⁻¹, 1000 cm⁻¹, 900 cm⁻¹, 800 cm⁻¹, 700 cm⁻¹, 600 cm⁻¹, 500 cm⁻¹, 400 cm⁻¹, 300 cm⁻¹, 200 cm⁻¹, or 100 cm⁻¹.

According to one embodiment, the metal chalcogenide nanocrystals have optical absorption features due to plasmonic absorption which is peaked between 3 μm and 80 μm.

According to one embodiment, the metal chalcogenide nanocrystals have optical absorption features due to plasmonic absorption which is peaked between 3 μm and 6 nm.

According to one embodiment, the metal chalcogenide nanocrystals have optical absorption features due to plasmonic absorption which is peaked between 6 μm and 12 nm.

According to one embodiment, the metal chalcogenide nanocrystals have optical absorption features due to plasmonic absorption which is peaked between 12 μm and 80 μm.

According to one embodiment, the metal chalcogenide nanocrystals have optical absorption features due to plasmonic absorption with a full width at half maximum of less than 2000 cm⁻¹, 1900 cm⁻¹, 1800 cm⁻¹, 1700 cm⁻¹, 1600 cm⁻¹, 1500 cm⁻¹, 1400 cm⁻¹, 1300 cm⁻¹, 1200 cm⁻¹, 1100 cm⁻¹, 1000 cm⁻¹, 900 cm⁻¹, 800 cm⁻¹, 700 cm⁻¹, 600 cm⁻¹, 500 cm⁻¹, 400 cm⁻¹, 300 cm⁻¹, 200 cm⁻¹, 100 cm⁻¹, or 50 cm⁻¹.

According to one embodiment, the width at half maximum of the absorption peak in the mid or far IR is less than 100%, 90%, 80%, 70%, 60%, 50%, 40%, 30%, 25%, 20%, 15%, 10%, 5%, 4%, 3%, 2%, or 1% in energy of the peak energy.

According to one embodiment, the width at half maximum of the absorption peak in the mid or far IR is less 200 meV, 190 meV, 180 meV, 170 meV, 160 meV, 150 meV, 140 meV, 130 meV, 120 meV, 110 meV, 100 meV, 90 meV, 80 meV, 70 meV, 60 meV, or 50 meV.

According to one embodiment, the metal chalcogenide nanocrystals have optical absorption depth from 1 nm to 100 nm, preferably from 100 nm to 10 nm.

According to one embodiment, the metal chalcogenide nanocrystals have an absorption coefficient ranging from 100 cm⁻¹ to 5×10⁵ cm⁻¹ at the first optical feature, preferably from 500 cm⁻¹ to 10⁵ cm⁻¹, more preferably from 1000 cm⁻¹ to 10⁴ cm⁻¹.

According to one embodiment, the absorption of the organic ligands relative to the absorption of metal chalcogenide nanocrystals is lower than 50%, 40%, 30%, 25%, 20%, 15%, 10%, 5%, 4%, 3%, 2%, or 1%.

According to one embodiment, the absorption of the organic ligands relative to the absorption of the interband peak or the intraband peak of metal chalcogenide nanocrystals is lower than 50%, 40%, 30%, 25%, 20%, 15%, 10%, 5%, 4%, 3%, 2%, or 1%.

According to one embodiment wherein the metal chalcogenide nanocrystal is doped or self-doped, such as for instance for HgSe or HgS, the absorption of the organic ligands relative to the absorption of the intraband peak of metal chalcogenide nanocrystals is lower than 50%, 40%, 30%, 25%, 20%, 15%, 10%, 5%, 4%, 3%, 2%, or 1%.

According to one embodiment wherein the metal chalcogenide nanocrystal is non-doped, such as for instance for HgTe, PbTe, PbSe or PbS, the absorption of the organic ligands relative to the absorption of the interband peak of metal chalcogenide nanocrystals is lower than 50%, 40%, 30%, 25%, 20%, 15%, 10%, 5%, 4%, 3%, 2%, or 1%.

According to one embodiment, the absorption of the organic ligands refers herein to the absorption of the C—H bonds of the organic ligands.

According to one embodiment, the organic ligands absorption, especially the C-H absorption, in optical density is weaker than the absorption relative to the intraband feature of the nanocrystals.

According to one embodiment, the ratio of the organic ligands absorption, especially the C—H absorption, relative to the absorption of the intraband feature of the nanocrystals is less than 100%, 90%, 80%, 70%, 60%, 50%, 40%, 30%, 25%, 20%, 15%, 10%, 5%, 4%, 3%, 2%, or 1%.

According to one embodiment, the metal chalcogenide nanocrystals exhibit a photoluminescence peak at a wavelength in a range from 1 μm to 50 μm or from 1 μm to 300 μm.

According to one embodiment, the metal chalcogenide nanocrystals exhibit a photoluminescence peak at a wavelength in a range from 1 μm, 2 μm, 3 μm, 4 μm, 5 μm, 6 μm, 7 μm, 8 μm, 9 μm, 10 μm, 11μm, 12μm, 13 μm, 14 μm, 15 μm, 16 μm, 17 μm, 18 μm, 19 μm, 20 μm, 21 μm, 22 μm, 23 μm, 24 μm, 25 μm, 26 μm, 27 μm, 28 μm, 29 μm, 30 μm, 31 μm, 32 μm, 33 μm, 34 μm, 35 μm, 36 μm, 37 μm, 38 μm, 39 μm, 40 μm, 41 μm, 42 μm, 43 μm, 44 μm, 45 μm, 46 μm, 47 μm, 48 μm, 49 μm, 50 μm, 51 μm, 52 μm, 53 μm, 54 μm, 55 μm, 56 μm, 57 μm, 58 μm, 59 μm, 60 μm, 61 μm, 62 μm, 63 μm, 64 μm, 65 μm, 66 μm, 67 μm, 68 μm, 69 μm, 70 μm, 71 μm, 72 μm, 73 μm, 74 μm, 75 μm, 76 μm, 77 μm, 78 μm, 79 μm, 80 μm, 81 μm, 82 μm, 83 μm, 84 μm, 85 μm, 86 μm, 87 μm, 88 μm, 89 μm, 90 μm, 91 μm, 92 μm, 93 μm, 94 μm, 95 μm, 96 μm, 97 μm, 98 μm, 99 μm, 100 μm, 200 μm, 250 μm or 300 μm.

According to one embodiment, the metal chalcogenide nanocrystals exhibit emission spectra with at least one emission peak having a full width at half maximum of less than 2000 cm⁻¹, 1900 cm⁻¹, 1800 cm⁻¹, 1700 cm⁻¹, 1600 cm⁻¹, 1500 cm⁻¹, 1400 cm⁻¹, 1300 cm⁻¹, 1200 cm⁻¹, 1100 cm⁻¹, 1000 cm⁻¹, 900 cm⁻¹, 800 cm⁻¹, 700 cm⁻¹, 600 cm⁻¹, 500 cm⁻¹, 400 cm⁻¹, 300 cm⁻¹, 200 cm⁻¹, 100 cm⁻¹ or 50 cm⁻¹.

In a second aspect, the present invention also relates to a method for manufacturing a plurality of metal chalcogenide nanocrystals disclosed herein.

The method comprises the following steps:
(a) heating a previously degassed solution of coordinating solvent at a temperature ranging from 0 to 400° C.;
(b) providing a solution comprising at least one precursor AYₚ and at least one precursor of the chalcogen X, wherein Y is Cl, Br or I;
(c) swiftly injecting the solution obtained at step (b) in the degassed solution of coordinating solvent at a temperature ranging from 0 to 400° C.;
(d) isolating the metal chalcogenide nanocrystals.
   wherein said metal A is selected from Hg, Pb, Ag, Bi, Cd, Sn, Sb or a mixture thereof;
   wherein said chalcogen X is selected from S, Se, Te or a mixture thereof; and
   wherein n and m are independently a decimal number from 0 to 5 and are not simultaneously equal to 0;
   wherein p is a decimal number from 0 to 5.

A and X are as described hereabove.

The advantage of the step of swiftly injecting the solution is to avoid the unintentional starting of the chemical reaction at room temperature.

According to one embodiment, the isolation step is followed by a selective precipitation procedure to sort the nanocrystal by size.

The shape and size may depend on the chosen A precursor (FIG. 4, 6-7), reaction temperature (FIG. 4) and/or reaction time.

As illustrated in FIG. 6-7, ACl₂ precursor leads to larger nanocrystals than ABr₂ or AI₂ precursors; and Al₂ precursor leads to more faceted nanocrystals than ABr₂ or ACl₂ precursors.

The solution of coordinating solvent is degassed to prevent introduction of O₂ in the metal chalcogenide nanocrystals.

According to one embodiment, the at least one precursor AYₚ is a halide precursor of A, wherein p is a decimal number from 0 to 5. This embodiment is advantageous as halide precursors are less toxic and less expensive than other precursors of A.

According to one embodiment, examples of coordinating solvent include but are not limited to amine such as oleylamine, hexadecylamine, octadecylamine, carboxylic acid such as oleic acid, or thiol such as dodecanthiol, or a mixture thereof.

According to one embodiment, the at least one precursor of mercury HgY₂ includes but is not limited to: HgCl₂, HgBr₂, HgI₂ or a mixture thereof.

According to an alternative embodiment, the at least one precursor of mercury AYₚ may be replaced by a precursor selected in the group including but not limited to: mercury acetate, mercury acetylacetonate, mercury perchlorate, mercury oleate, mercury benzoate or mixture thereof.

According to one embodiment, the at least one precursor of selenium includes but is not limited to: solid selenium; reduced selenium either by NaBH₄ or thiol such as dodecanethiol; selenourea; selenourea derivative; tri-n-alkylphosphine selenide such as for example tri-n-butylphosphine selenide or tri-n-octylphosphine selenide; selenium disulfide SeS₂; selenium oxide SeO₂; hydrogen selenide H₂Se; diethylselenide; methylallylselenide; salts such as for example magnesium selenide, calcium selenide, sodium selenide, potassium selenide; or a mixture thereof.

According to one embodiment, the at least one precursor of sulfur includes but is not limited to: solid sulfur; thioacetamide; thioacetamide derivative; sulfur oxides; tri-n-alkylphosphine sulfide such as for example tri-n-butylphosphine sulfide or tri-n-octylphosphine sulfide; hydrogen sulfide H₂S; thiols such as for example n-butanethiol, n-octanethiol or n-dodecanethiol; diethylsulfide; methylallylsulfide; salts such as for example magnesium sulfide, calcium sulfide, sodium sulfide, potassium sulfide; or a mixture thereof.

According to one embodiment, the at least one precursor of tellurium includes but is not limited to: solid tellurium; trioctylphosphine telluride; NaHTe; H₂Te; bis-(trimethylsilyl)telluride or a mixture thereof.

According to one embodiment, the at least one precursor of the chalcogen X is selected in the group of solid Se; solid S; solid Te or a mixture thereof.

According to one embodiment, the at least one precursor of the chalcogen X comprise solid Se; solid S; solid Te or a mixture thereof dissolved in oleylamine in presence of NaBH₄ or thiol such as dodecanethiol.

According to one embodiment, the solution comprising at least one precursor AYₚ and at least one precursor of the chalcogen X is homogeneous. In this embodiment, precursors of elements A and X are well mixed together.

According to one embodiment, the at least one precursor AYₚ and the at least one precursor of the chalcogen X are mixed in a stoichiometric ratio (FIG. 5). The ratio between the at least one precursor AYₚ and the at least one precursor of the chalcogen X may influence the size and shape of resulting nanocrystals.

According to one embodiment, the at least one precursor AYₚ is mixed with the at least one precursor of the chalcogen X in excess compared to said at least one precursor of the chalcogen X by a factor not exceeding 10 times, 9 times, 8 times, 7 times, 6 times, 5 times, 4 times, 3 times, or 2 times.

According to one embodiment, the at least one precursor of the chalcogen X is mixed with the at least one precursor AYₚ in excess compared to said at least one precursor AYₚ by a factor not exceeding 10 times, 9 times, 8 times, 7 times, 6 times, 5 times, 4 times, 3 times, or 2 times.

According to one embodiment, the solution obtained at step (c) is maintained at a temperature ranging from 0° C. to 400° C. during a predetermined duration of at least 1 sec, 2 sec, 3 sec, 4 sec, 5 sec, 6 sec, 7 sec, 8 sec, 9 sec, 10 sec, 15 sec, 20 sec, 25 sec, 30 sec, 35 sec, 40 sec, 45 sec, 50 sec, 55 sec, 60 sec, 1.5 min, 2 min, 2.5 min, 3 min, 3.5 min, 4 min, 4.5 min, 5 min, 5.5 min, 6 min, 6.5 min, 7 min, 7.5 min, 8 min, 8.5 min, 9 min, 9.5 min, 10 min, 11 min, 12 min, 13 min, 14 min, 15 min, 16 min, 17 min, 18 min, 19 min, or 20 min after injection of the precursor solution, i.e. solution obtained at step (b), in the degassed solution of coordinating solvent.

According to one embodiment, the temperature of reaction is at least 0° C., 10° C., 20° C., 30° C., 40° C., 50° C., 60° C., 70° C., 80° C., 90° C., 100° C., 110° C., 120° C., 130° C., 140° C., 150° C., 160° C., 170° C., 180° C., 190° C., 200° C., 210° C., 220° C., 230° C., 240° C., 250° C., 260° C., 270° C., 280° C., 290° C., 300° C., 310° C., 320° C., 330° C., 340° C., 350° C., 360° C., 370° C., 380° C., 390° C. or 400° C.

According to one embodiment, the temperature of reaction ranges from 0 to 400° C., preferably from 60 to 350° C., more preferably from 120 to 300° C.

According to one embodiment, the method is performed in a flask which volume is at least 10 mL, 20 mL, 30 mL, 40 mL, 50 mL, 60 mL, 70 mL, 80 mL, 90 mL, 100 mL, 150 mL, 200 mL, 250 mL, 300 mL, 350 mL, 400 mL, 450 mL, 500 mL, 650 mL, 700 mL, 750 mL, 800 mL, 850 mL, 900 mL, 950 mL, or 1 L.

According to one embodiment, the method is performed in an automated setup which volume is between 10 mL, 20 mL, 30 mL, 40 mL, 50 mL, 60 mL, 70 mL, 80 mL, 90 mL, 100 mL, 150 mL, 200 mL, 250 mL, 300 mL, 350 mL, 400 mL, 450 mL, 500 mL, 650 mL, 700 mL, 750 mL, 800 mL, 850 mL, 900 mL, 950 mL, 1 L, 2 L, 3 L, 4 L, 5 L, 10 L, 20 L, 30 L, 40 L, 50 L, 60 L, 70 L, 80 L, 90 L, or 100 L.

According to one embodiment, the method is performed in a continuous flow reactor.

According to one embodiment, the method is performed under inert gas such as Ar, or N₂.

According to one embodiment, the isolating step (d) comprises admixing a thiol and/or a phosphine with the solution obtained at step (c), thereby forming a quenched mixture; and extracting the nanocrystals from the quenched mixture. The thiol can be an alkane thiol, having between 6 and 30 carbon atoms such as for example, hexane thiol, octane thiol, decane thiol, dodecane thiol, hexadecane thiol, or a mixture thereof.

According to one embodiment, the isolating step (d) comprises admixing the solution obtained at step (c) with a precipitating agent such as a solvent in which the nanoparticles are insoluble or sparingly soluble, acetonitrile, acetone, alcohols such as for example ethanol, methanol, isopropanol, 1-butanol; and extracting the nanocrystals from the quenched mixture.

According to one embodiment, the extraction of nanocrystals from the quenched mixture comprise centrifuging said quenched mixture.

According to one embodiment, the isolated nanocrystals are suspended in water or in an aqueous solution.

According to one embodiment, the isolated nanocrystals are suspended in an organic solvent, wherein said organic solvent includes but is not limited to: hexane, heptane, pentane, toluene, tetrahydrofuran, chloroform, acetone, acetic acid, n-methylformamide, n,n-dimethylformamide, dimethylsulfoxide, octadecene, squalene, amines such as for example tri-n-octylamine, 1,3-diaminopropane, oleylamine, hexadecylamine, octadecylamine, squalene, alcohols such as for example ethanol, methanol, isopropanol, 1-butanol, 1-hexanol, 1-decanol, propane-2-ol, ethanediol, 1,2-propanediol or a mixture thereof.

According to one embodiment, the method of the invention further comprises a step for coating the isolated metal chalcogenide nanocrystals with at least one organic ligand and/or at least one inorganic ligand. Said ligands are as described hereabove.

According to one embodiment, examples of ligands include but are not limited to: S²⁻, HS⁻, Se²⁻, Te²⁻, OH⁻, BF₄⁻, PF₆⁻, Cl⁻, Br⁻, I⁻, As₂S₃, As₂Se₃, Sb₂S₃, As₂Te₃, Sb₂S₃, Sb₂Se₃, Sb₂Te₃, CdSe, CdTe SnS₂, AsS³⁺, LiS₂, FeS₂, Cu₂S, thiol, amine, carboxylic acid, phosphine, phosphine oxide, or mixture thereof.

According to one embodiment, the method of the invention further comprises a ligand exchanging step.

According to one embodiment, the ligand exchanging step comprises the removal of the initial organic ligand and capping of the nanocrystals with at least one inorganic ligand and/or at least one another organic ligand.

According to one embodiment, the ligand exchanging step comprises a solid state approach such as on film ligand exchange.

According to one embodiment, the ligand exchanging step comprises a liquid phase approach.

According to one embodiment, the ligand exchanging step comprises a liquid phase transfer method such as a solution ligand exchange.

According to one embodiment, the ligand exchanging step comprises a reduction of the absorption relative to the organic ligands initially at the nanocrystal surface, especially a reduction of the absorption relative to the C—H bond of the organic ligands.

According to one embodiment, the ligand exchange leads to a reduction of the absorption relative to the organic ligands which is higher than 50% of the absorption of the metal chalcogenide nanocrystals, preferably higher than 60%, 70%, 75%, 80%, 90% or 95% of the absorption of the metal chalcogenide nanocrystals.

According to one embodiment, the step to exchange ligand comes with a reduction of the C—H absorption, by at least 20% of its initial value, preferably by 50%, more preferably by 80%, even more preferably by more than 90%.

According to one embodiment, the ligand exchange leads to a reduction of the absorption relative to the organic ligands which is higher than 50% of the absorption of the interband peak or the intraband peak of metal chalcogenide nanocrystals, preferably higher than 60%, 70%, 75%, 80%, 90% or 95% of the absorption of the interband peak or the intraband peak of metal chalcogenide nanocrystals.

According to one embodiment wherein the metal chalcogenide nanocrystal is doped or self-doped, such as for instance for HgSe or HgS, the ligand exchange leads to a reduction of the absorption relative to the organic ligands which is higher than 50% of the absorption of the intraband peak of metal chalcogenide nanocrystals, preferably higher than 60%, 70%, 75%, 80%, 90% or 95% of the absorption of the intraband peak of metal chalcogenide nanocrystals.

According to one embodiment wherein the metal chalcogenide nanocrystal is non-doped, such as for instance for HgTe, PbTe, PbSe or PbS, the ligand exchange leads to a reduction of the absorption relative to the organic ligands which is higher than 50% of the absorption of the interband peak of metal chalcogenide nanocrystals, preferably higher than 60%, 70%, 75%, 80%, 90% or 95% of the absorption of the interband peak of metal chalcogenide nanocrystals.

According to one embodiment, the method of the invention further comprises a step of growing a shell comprising a material of formula AₙXₘ on the metal chalcogenide nanocrystals. In this embodiment, the metal chalcogenide nanocrystals are hetero structures.

According to one embodiment, in the step of growing a shell on the metal chalcogenide nanocrystals, said metal chalcogenide nanocrystals act as seeds for the growth of said shell.

According to one embodiment, the step of growing a shell comprising a material of formula AₙXₘ on the nanocrystals comprises the following steps:
(a) preparing a solution comprising at least one precursor of A and at least one precursor of X;
(b) degassing the solution obtained at step (a);
(c) adding the solution obtained at step (b) in a previously degassed solution comprising metal chalcogenide nanocrystals in a coordinating solvent at a temperature ranging from 0° C. to 350° C.;
(d) isolating the core/shell metal chalcogenide nanocrystals.

According to one embodiment, the step of growing a shell comprising a material of formula AₙXₘ on the nanocrystals comprises the following steps:
(a) preparing a solution comprising at least one precursor of X;
(b) degassing the solution obtained at step (a);
(c) adding the solution obtained at step (b) in a previously degassed solution comprising metal chalcogenide nanocrystals and at least one precursor of A in a coordinating solvent at a temperature ranging from 0° C. to 350° C.;
(d) isolating the core/shell metal chalcogenide nanocrystals;

wherein said metal A is selected from Hg, Pb, Ag, Bi, Cd, Sn, Sb or a mixture thereof;

wherein said chalcogen X is selected from S, Se, Te or a mixture thereof; and

wherein n and m are independently a decimal number from 0 to 5 and are not simultaneously equal to 0.

A and X are as described hereabove.

In this embodiment, the step for isolating the core/shell metal chalcogenide nanocrystals is as described hereabove, and the at least precursor of X is as described hereabove.

According to one embodiment, the at least one precursor of A includes but is not limited to: precursors of Hg, precursors of Pb, precursors of Bi, precursors of Ag, precursors of Cd, precursors of Sn, precursors of Sb or a mixture thereof.

According to one embodiment, the at least one precursor of Hg includes but is not limited to: HgO, HgCl₂, HgBr₂, HgI₂, mercury acetate, mercury acetylacetonate, mercury perchlorate, mercury oleate, mercury benzoate, mercury acetylacetonate or mixture thereof.

According to one embodiment, the at least one precursor of cadmium includes but is not limited to: cadmium carboxylates Cd(R—COO)₂, wherein R is a linear alkyl chain comprising a range of 1 to 25 carbon atoms; cadmium oxide CdO; cadmium sulfate Cd(SO₄); cadmium nitrate Cd(NO₃)₂.4H₂O; cadmium acetate (CH₃COO)₂Cd.2H₂O; cadmium chloride CdCl₂.2.5H₂O; dimethylcadmium; dineopentylcadmium; bis(3-diethylaminopropyl)cadmium; (2,2′-bipyridine)dimethylcadmium; cadmium ethylxanthate; cysteine or a mixture thereof.

According to one embodiment, the at least one precursor of Pb includes but is not limited to: PbO, PbCl₂, PbBr₂, PbI₂, lead nitrate, lead acetate, lead perchlorate, lead acetylacetonate.

According to one embodiment, the at least one precursor of Ag includes but is not limited to silver nitrate, silver oxide or silver acetate.

According to one embodiment, the at least one precursor of Bi includes but is not limited to: bismuth acetate, bismuth chloride, bismuth bromide, bismuth iodide, bismuth fluoride, bismuth oxide, bismuth nitrate.

According to one embodiment, the at least one precursor of Sn includes but is not limited tin acetate, tin chloride, tin bromide, tin fluoride, tin oxide, tin acetylacetonate.

According to one embodiment, the at least one precursor of Sb includes but is not limited to: antimony acetate, antimony chloride, antimony bromide, antimony iodide, antimony fluoride, antimony oxide.

The invention also relates to a mixture comprising a plurality of metal chalcogenide nanocrystals of the invention.

According to one embodiment, the mixture further comprises at least one particle having optical absorption features at wavelengths shorter than the optical absorption features of the metal chalcogenide nanocrystals of the invention.

According to one embodiment, the mixture further comprises a solvent such as for example hexane, octane, hexane-octane mixture, toluene, chloroform, tetrachloroethylene, or a mixture thereof.

According to one embodiment, the mixture is free of oxygen. According to one embodiment, the mixture is free of water.

According to one embodiment, the mixture further comprises at least one host material.

According to one embodiment, the at least one host material is free of oxygen.

According to one embodiment, the at least one host material is free of water.

According to one embodiment, the at least one host material is optically transparent.

According to one embodiment, the at least one host material is optically transparent at wavelengths where the nanocrystal is absorbing.

According to one embodiment, the at least one host material is optically transparent at wavelengths from 1 μm to 300 μm, preferably from 3 μm to 200 μm.

According to one embodiment, the at least one host material is optically transparent at wavelengths from 5 μm to 300 μm, preferably from 50 μm to 200 μm.

According to one embodiment, the at least one host material is a polymeric host material.

According to one embodiment, the polymeric host material is a fluorinated polymer layer, such as PVDF or a derivative of PVDF.

According to one embodiment, the polymeric host material is a fluorinated polymer layer, such as an amorphous fluoropolymer. The advantage of the amorphous fluoropolymer said capping layer is the transparency and the low refractive index. According to one embodiment, the amorphous fluoropolymer is a CYTOP™.

According to one embodiment, the polymeric host material may be a polymerized solid made from alpha-olefins, dienes such as butadiene and chloroprene; styrene, alpha-methyl styrene, and the like; heteroatom substituted alpha-olefins, for example, vinyl acetate, vinyl alkyl ethers for example, ethyl vinyl ether, vinyltrimethylsilane, vinyl chloride, tetrafluoroethylene, chlorotrifiuoroethylene, cyclic and polycyclic olefin compounds for example, cyclopentene, cyclohexene, cycloheptene, cyclooctene, and cyclic derivatives up to C20; polycyclic derivates for example, norbornene, and similar derivatives up to C20; cyclic vinyl ethers for example, 2,3-dihydrofuran, 3,4-dihydropyran, and similar derivatives; allylic alcohol derivatives for example, vinylethylene carbonate, disubstituted olefins such as maleic and fumaric compounds for example, maleic anhydride, diethylfumarate, and the like, and mixture thereof.

According to one embodiment, the polymeric host material may be PMMA, Poly(lauryl methacrylate), glycolized poly(ethylene terephthalate), Poly(maleic anhydride altoctadecene), or mixture thereof.

According to one embodiment, examples of polymeric host material include but are not limited to: silicon based polymer, PET or PVA.

According to one embodiment, the at least one host material is an inorganic host material.

According to one embodiment, examples of inorganic host material include but are not limited to: metals, halides, chalcogenides, phosphides, sulfides, metalloids, metallic alloys, ceramics such as for example oxides, carbides, or nitrides.

According to one embodiment, a chalcogenide is a chemical compound consisting of at least one chalcogen anion selected in the group of O, S, Se, Te, Po, and at least one or more electropositive element.

According to one embodiment, the metallic host material is selected in the group of gold, silver, copper, vanadium, platinum, palladium, ruthenium, rhenium, yttrium, mercury, cadmium, osmium, chromium, tantalum, manganese, zinc, zirconium, niobium, molybdenum, rhodium, tungsten, iridium, nickel, iron, or cobalt.

According to one embodiment, examples of carbide host material include but are not limited to: SiC, WC, BC, MoC, TiC, Al₄C₃, LaC₂, FeC, CoC, HfC, SiₓC_{y}, WₓC_{y}, BₓC_{y}, MoₓC_{y}, TiₓC_{y}, AlₓC_{y}, LaₓC_{y}, FeₓC_{y}, CoₓC_{y}, HfₓC_{y}, or a mixture thereof; x and y are independently a decimal number from 0 to 5, at the condition that when x is 0, y is not 0, when y is 0, x is not 0.

According to one embodiment, examples of oxide host material include but are not limited to: SiO₂, Al₂O₃, TiO₂, ZrO₂, ZnO, MgO, SnO₂, Nb₂O₅, CeO₂, BeO, IrO₂, CaO, Sc₂O₃, NiO, Na₂O, BaO, K₂O, PbO, Ag₂O, V₂O₅, TeO₂, MnO, B₂O₃, P₂O₅, P₂O₃, P₄O₇, P₄O₈, P₄O₉, P₂O₆, PO, GeO₂, As₂O₃, Fe₂O₃, Fe₃O₄, Ta₂O₅, Li₂O, SrO, Y₂O₃, HfO₂, WO₂, MoO₂, Cr₂O₃, Tc₂O₇, ReO₂, RuO₂, Co₃O₄, OsO, RhO₂, Rh₂O₃, PtO, PdO, CuO, Cu₂O, Au₂O₃, CdO, HgO, Tl₂O, Ga₂O₃, In₂O₃, Bi₂O₃, Sb₂O₃, PoO₂, SeO₂, Cs₂O, La₂O₃, Pr₆O₁₁, Nd₂O₃, La₂O₃, Sm₂O₃, Eu₂O₃, Tb₄O₇, Dy₂O₃, Ho₂O₃, Er₂O₃, Tm₂O₃, Yb₂O₃, Lu₂O₃, Gd₂O₃, or a mixture thereof.

According to one embodiment, examples of oxide host material include but are not limited to: silicon oxide, aluminium oxide, titanium oxide, copper oxide, iron oxide, silver oxide, lead oxide, calcium oxide, magnesium oxide, zinc oxide, tin oxide, beryllium oxide, zirconium oxide, niobium oxide, cerium oxide, iridium oxide, scandium oxide, nickel oxide, sodium oxide, barium oxide, potassium oxide, vanadium oxide, tellurium oxide, manganese oxide, boron oxide, phosphorus oxide, germanium oxide, osmium oxide, rhenium oxide, platinum oxide, arsenic oxide, tantalum oxide, lithium oxide, strontium oxide, yttrium oxide, hafnium oxide, tungsten oxide, molybdenum oxide, chromium oxide, technetium oxide, rhodium oxide, ruthenium oxide, cobalt oxide, palladium oxide, gold oxide, cadmium oxide, mercury oxide, thallium oxide, gallium oxide, indium oxide, bismuth oxide, antimony oxide, polonium oxide, selenium oxide, cesium oxide, lanthanum oxide, praseodymium oxide, neodymium oxide, samarium oxide, europium oxide, terbium oxide, dysprosium oxide, erbium oxide, holmium oxide, thulium oxide, ytterbium oxide, lutetium oxide, gadolinium oxide, mixed oxides, mixed oxides thereof or a mixture thereof.

According to one embodiment, examples of nitride host material include but are not limited to: TiN, Si₃N₄, MoN, VN, TaN, Zr₃N₄, HfN, FeN, NbN, GaN, CrN, AlN, InN, TiₓN_{y}, SiₓN_{y}, MoₓN_{y}, VₓN_{y}, TaₓN_{y}, ZrₓN_{y}, HfₓN_{y}, FeₓN_{y}, NbₓN_{y}, GaₓN_{y}, CrₓN_{y}, AlₓN_{y}, InₓN_{y}, or a mixture thereof; x and y are independently a decimal number from 0 to 5, at the condition that when x is 0, y is not 0, when y is 0, x is not 0.

According to one embodiment, examples of sulfide host material include but are not limited to: Si_{y}Sₓ, Al_{y}Sₓ, Ti_{y}Sₓ, Zr_{y}Sₓ, Zn_{y}Sₓ, Mg_{y}Sₓ, Sn_{y}Sₓ, Nb_{y}Sₓ, Ce_{y}Sₓ, Be_{y}Sₓ, Ir_{y}Sₓ, Ca_{y}Sₓ, SC_{y}Sₓ, N1_{y}Sₓ, Na_{y}Sₓ, Ba_{y}Sₓ, K_{y}Sₓ, Pb_{y}Sₓ, Ag_{y}Sₓ, V_{y}Sₓ, Te_{y}Sₓ, Mn_{y}Sₓ, B_{y}Sₓ, P_{y}Sₓ, Ge_{y}Sₓ, AS_{y}Sₓ, Fe_{y}Sₓ, Ta_{y}Sₓ, Li_{y}Sₓ, Sr_{y}Sₓ, Y_{y}Sₓ, Hf_{y}Sₓ, W_{y}Sₓ, MO_{y}Sₓ, Cr_{y}Sₓ, TC_{y}Sₓ, Re_{y}Sₓ, Ru_{y}Sₓ, Co_{y}Sₓ, Os_{y}Sₓ, Rh_{y}Sₓ, Pt_{y}Sₓ, Pd_{y}Sₓ, Cu_{y}Sₓ, Au_{y}Sₓ, Cd_{y}Sₓ, Hg_{y}Sₓ, Tl_{y}Sₓ, Ga_{y}Sₓ, In_{y}Sₓ, Bi_{y}Sₓ, Sb_{y}Sₓ, Po_{y}Sₓ, Se_{y}Sₓ, Cs_{y}Sₓ, mixed sulfides, mixed sulfides thereof or a mixture thereof; x and y are independently a decimal number from 0 to 10, at the condition that when x is 0, y is not 0, when y is 0, x is not 0.

According to one embodiment, examples of halide host material include but are not limited to: BaF₂, LaF₃, CeF₃, YF₃, CaF₂, MgF₂, PrF₃, AgCl, MnC1₂, NiCl₂, Hg₂Cl₂, CaCl₂, CsPbCl₃, AgBr, PbBr₃, CsPbBr₃, AgI, CuI, PbI, HgI₂, BiI₃, CH₃NH₃PbI₃, CsPbI₃, FAPbBr₃ (with FA formamidinium), or a mixture thereof.

According to one embodiment, examples of chalcogenide host material include but are not limited to: CdO, CdS, CdSe, CdTe, ZnO, ZnS, ZnSe, ZnTe, HgO, HgS, HgSe, HgTe, CuO, Cu₂O, CuS, Cu₂S, CuSe, CuTe, Ag₂O, Ag₂S, Ag₂Se, Ag₂Te, Au₂O₃, Au₂S, PdO, PdS, Pd₄S, PdSe, PdTe, PtO, PtS, PtS₂, PtSe, PtTe, RhO₂, Rh₂O₃, RhS₂, Rh₂S₃, RhSe₂, Rh₂Se₃, RhTe₂, IrO₂, IrS₂, Ir2S₃, IrSe₂, IrTe₂, RuO₂, RuS₂, OsO, OsS, OsSe, OsTe, MnO, MnS, MnSe, MnTe, ReO₂, ReS₂, Cr₂O₃, Cr₂S₃, MoO₂, MoS₂, MoSe₂, MoTe₂, WO₂, WS₂, WSe₂, V₂O₅, V₂S₃, Nb₂O₅, NbS₂, NbSe₂, HfO₂, HfS₂, TiO₂, ZrO₂, ZrS₂, ZrSe₂, ZrTe₂, Sc₂O₃, Y₂O₃, Y₂S₃, SiO₂, GeO₂, GeS, GeS₂, GeSe, GeSe₂, GeTe, SnO₂, SnS, SnS₂, SnSe, SnSe₂, SnTe, PbO, PbS, PbSe, PbTe, MgO, MgS, MgSe, MgTe, CaO, CaS, SrO, Al₂O₃, Ga₂O₃, Ga₂S₃, Ga₂Se₃, In₂O₃, In₂S₃, In₂Se₃, In₂Te₃, La₂O₃, La₂S₃, CeO₂, CeS₂, Pr₆O₁₁, Nd₂O₃, NdS₂, La₂O₃, Tl₂O, Sna₂O₃, SmS₂, Eu₂O₃, EuS₂, Bi₂O₃, Sb₂O₃, PoO₂, SeO₂, Cs₂O, Tb₄O₇, TbS₂, Dy₂O₃, Ho₂O₃, Er₂O₃, ErS₂, Tm₂O₃, Yb₂O₃, Lu₂O₃, CuInS₂, CuInSe₂, AgInS₂, AgInSe₂, Fe₂O₃, Fe₃O₄, FeS, FeS₂, Co₃S₄, CoSe, Co₃O₄, NiO, NiSe₂, NiSe, Ni₃Se₄, Gd₂O₃, BeO, TeO₂, Na₂O, BaO, K₂O, Ta₂O₅, Li₂O, Tc₂O₇, As₂O₃, B₂O₃, P₂O₅, P₂O₃, P₄O₇, P₄O₈, P₄O₉, P₂O₆, PO, or a mixture thereof.

According to one embodiment, examples of phosphide host material include but are not limited to: InP, Cd₃P₂, Zn₃P₂, AlP, GaP, TlP, or a mixture thereof.

According to one embodiment, examples of metalloid host material include but are not limited to: Si, B, Ge, As, Sb, Te, or a mixture thereof.

According to one embodiment, examples of metallic alloy host material include but are not limited to: Au—Pd, Au—Ag, Au—Cu, Pt—Pd, Pt—Ni, Cu—Ag, Cu—Sn, Ru—Pt, Rh—Pt, Cu—Pt, Ni—Au, Pt—Sn, Pd—V, Ir—Pt, Au—Pt, Pd—Ag, Cu—Zn, Cr—Ni, Fe—Co, Co—Ni, Fe—Ni or a mixture thereof.

According to one embodiment, the host material comprises garnets.

According to one embodiment, examples of garnets include but are not limited to: Y₃Al₅O₁₂, Y₃Fe₂(FeO₄)₃, Y₃Fe₅O₁₂, Y₄Al₂O₉, YAlO₃, Fe₃Al₂(SiO₄)₃, Mg₃Al₂(SiO₄)₃, Mn₃Al₂(SiO₄)₃, Ca₃Fe₂(SiO₄)₃, Ca₃Al₂(SiO₄)₃, Ca₃Cr₂(SiO₄)₃, Al₅Lu₃O₁₂, GAL, GaYAG, or a mixture thereof.

According to one embodiment, the host material comprises or consists of a thermal conductive material wherein said thermal conductive material includes but is not limited to: Al_{y}Oₓ, Ag_{y}Oₓ, Cu_{y}Oₓ, Fe_{y}Oₓ, Si_{y}Oₓ, Pb_{y}Oₓ, Ca_{y}Oₓ, Mg_{y}Oₓ, Zn_{y}Oₓ, Sn_{y}Oₓ, Ti_{y}Oₓ, Be_{y}Oₓ, CdS, ZnS, ZnSe, CdZnS, CdZnSe, Au, Na, Fe, Cu, Al, Ag, Mg, mixed oxides, mixed oxides thereof or a mixture thereof; x and y are independently a decimal number from 0 to 10, at the condition that when x is 0, y is not 0, when y is 0, x is not 0.

According to one embodiment, the host material comprises or consists of a thermal conductive material wherein said thermal conductive material includes but is not limited to: Al₂O₃, Ag₂O, Cu₂O, CuO, Fe₃O₄, FeO, SiO₂, PbO, CaO, MgO, ZnO, SnO₂, TiO₂, BeO, CdS, ZnS, ZnSe, CdZnS, CdZnSe, Au, Na, Fe, Cu, Al, Ag, Mg, mixed oxides, mixed oxides thereof or a mixture thereof.

According to one embodiment, the host material comprises or consists of a thermal conductive material wherein said thermal conductive material includes but is not limited to: aluminium oxide, silver oxide, copper oxide, iron oxide, silicon oxide, lead oxide, calcium oxide, magnesium oxide, zinc oxide, tin oxide, titanium oxide, beryllium oxide, zinc sulfide, cadmium sulfide, zinc selenium, cadmium zinc selenium, cadmium zinc sulfide, gold, sodium, iron, copper, aluminium, silver, magnesium, mixed oxides, mixed oxides thereof or a mixture thereof.

According to one embodiment, examples of inorganic host material include but are not limited to: ZnO, ZnS, ZnSe, Al₂O₃, SiO₂, TiO₂, ZrO₂, MgO, SnO₂, IrO₂, As₂S₃, As₂Se₃, or a mixture thereof.

According to one embodiment, the host material comprises organic molecules in small amounts of 0 mole %, 1 mole %, 5 mole %, 10 mole %, 15 mole %, 20 mole %, 25 mole%, 30 mole %, 35 mole %, 40 mole %, 45 mole %, 50 mole %, 55 mole %, 60 mole%, 65 mole %, 70 mole %, 75 mole %, 80 mole% relative to the majority element of said host material.

According to one embodiment, the host material comprises a polymeric host material as described hereabove, an inorganic host material as described hereabove, or a mixture thereof.

According to one embodiment, the mixture comprises at least two host materials. In this embodiment, the host materials can be identical or different from each other.

According to one embodiment, the mixture comprises a plurality of host materials. In this embodiment, the host materials can be identical or different from each other.

According to one embodiment, the mixture comprising a plurality of metal chalcogenide nanocrystals is prepared by dropcasting, spincoating, dipcoating of a solution of said nanocrystals on a substrate.

According to one embodiment, the substrate comprises glass, CaF₂, undoped Si, undoped Ge, ZnSe, ZnS, KBr, LiF, Al₂O₃, KCl, BaF₂, CdTe, NaCl, KRS-5, a stack thereof or a mixture thereof.

In one embodiment, the mixture has a shape of a film, or a bead.

In one embodiment, the mixture is a film.

In one embodiment, the mixture is a photoabsorptive film as described hereafter.

The invention also relates to a photoabsorptive film comprising a plurality of metal chalcogenide nanocrystals of the invention.

According to one embodiment, the photoabsorptive film comprises a mixture as described hereabove.

According to one embodiment, the photoabsorptive film comprises at least one material as described herebelow.

According to one embodiment, the photoabsorptive film has an absorption coefficient ranging from 100 cm⁻¹ to 5×10⁵ cm⁻¹ at the first optical feature and preferably from 500 cm⁻¹ to 10⁵ cm⁻¹, more preferably from 1000 cm⁻¹ to 10⁴ cm⁻¹.

According to one embodiment, the photoabsorptive film has a thickness from 3 nm to 1 mm, preferably from 30 nm to 10 μm, more preferably from 50 nm to 1 μm.

According to one embodiment, the photoabsorptive film has a thickness of at least 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 30 nm, 40 nm, 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm

According to one embodiment, the photoabsorptive film has an area from 100 nm² to 1 m², preferably from 1 μm² to 10 cm², more preferably from 50 μm² to 1 cm².

According to one embodiment, the photoabsorptive film has an area of at least 100 nm², 200 nm², 300 nm², 400 nm², 500 nm², 600 nm², 700 nm², 800 nm², 900 nm², 1000 nm², 2000 nm², 3000 nm², 4000 nm², 5000 nm², 6000 nm², 7000 nm², 8000 nm², 9000 nm², 10000 nm², 20000 nm², 30000 nm², 40000 nm², 50000 nm², 60000 nm², 70000 nm², 80000 nm², 90000 nm², 100000 nm², 200000 nm², 300000 nm², 400000 nm², 500000 nm², 600000 nm², 700000 nm², 800000 nm², 900000 nm², 1 nm², 2 nm², 3 nm², 4 nm², 5 nm², 6 nm², 7 nm², 8 nm², 9 nm², 10 nm², 20 nm², 30 nm², 40 nm², 50 nm², 60 nm², 70 nm², 80 nm², 90 nm², 100 nm², 200 nm², 300 nm², 400 nm², 500 nm², 600 nm², 700 nm², 800 nm², 900 nm², 1000 nm², 2000 nm², 3000 nm², 4000 nm², 5000 nm², 6000 nm², 7000 nm², 8000 nm², 9000 nm², 10000 nm², 20000 nm², 30000 nm², 40000 nm², 50000 nm², 60000 nm², 70000 nm², 80000 nm², 90000 nm², 100000 nm², 200000 nm², 300000 nm², 400000 nm², 500000 nm², 600000 nm², 700000 nm², 800000 nm², 900000 nm², 1000000 nm², 2000000 nm², 3000000 nm², 4000000 nm², 5000000 nm², 6000000 nm², 7000000 nm², 8000000 nm², 9000000 nm², 10000000 nm², 20000000 nm², 3000000 nm², 4000000 nm², 5000000 nm², 6000000 nm², 7000000 nm², 8000000 nm², 9000000 nm², 1 cm², 2 cm², 3 cm², 4 cm², 5 cm², 6 cm², 7 cm², 8 cm², 9 cm², 10 cm², 20 cm², 30 cm², 40 cm², 50 cm², 60 cm², 70 cm², 80 cm², 90 cm², 100 cm², 200 cm², 300 cm², 400 cm², 500 cm², 600 cm², 700 cm², 800 cm², 900 cm², 1000 cm², 2000 cm², 3000 cm², 4000 cm², 5000 cm², 6000 cm², 7000 cm², 8000 cm², 9000 cm², or 1 m².

According to one embodiment, the photoabsorptive film comprising a plurality of metal chalcogenide nanocrystals is prepared by dropcasting, spincoating, dipcoating, electrophoretic deposition, doctor blading, a Langmuir blodget method, an electrophoretic procedure, or any method known by the skilled artisan.

According to one embodiment, the photoabsorptive film comprising a plurality of metal chalcogenide nanocrystals is prepared by dropcasting, spincoating, dipcoating of a solution of said nanocrystals on a substrate.

According to one embodiment, the substrate comprises glass, CaF₂, undoped Si, undoped Ge, ZnSe, ZnS, KBr, LiF, Al₂O₃, KCl, BaF₂, CdTe, NaCl, KRS-5, a stack thereof or a mixture thereof.

According to one embodiment, the photoabsorptive film comprising a plurality of metal chalcogenide nanocrystals is prepared by dropcasting of a solution of said nanocrystals dispersed in hexane, octane, hexane-octane mixture, toluene, chloroform, tetrachloroethylene, or a mixture thereof.

According to one embodiment, the photoabsorptive film is annealed at a temperature ranging from 0° C. to 900° C., preferably between 40° C. and 400° C., more preferably between 50° C. and 200° C. In this embodiment, the time of annealing ranges from is to 3600 s.

According to one embodiment, the photoabsorptive film has an absorption coefficient ranging from 100 cm⁻¹ to 5×10⁵ cm⁻¹ at the first optical feature, preferably from 500 cm⁻¹ to 10⁵ cm⁻¹, more preferably from 1000 cm⁻¹ to 10⁴ cm⁻¹.

According to one embodiment, the photoabsorptive film is further protected by at least one capping layer. In this embodiment, the capping layer protects said photoabsorptive film from oxygen, water and/or high temperature.

According to one embodiment, the capping layer is an O₂ insulating layer.

According to one embodiment, the capping layer is a H₂O insulating layer.

According to one embodiment, the capping layer is free of oxygen.

According to one embodiment, the capping layer is free of water.

According to one embodiment, the capping layer is configured to ensure the thermal management of the nanocrystals temperature.

According to one embodiment, the capping layer is an inorganic layer.

According to one embodiment, examples of inorganic layer include but are not limited to: ZnO, ZnS, ZnSe, Al₂O₃, SiO₂, TiO₂, ZrO₂, MgO, SnO₂, IrO₂, As₂S₃, As₂Se₃, or a mixture thereof.

According to one embodiment, examples of inorganic layer include but are not limited to: metals, halides, chalcogenides, phosphides, sulfides, metalloids, metallic alloys, ceramics such as for example oxides, carbides, or nitrides.

According to one embodiment, the capping layer is a polymer layer.

According to one embodiment, the capping layer is a fluorinated polymer layer, such as PVDF or a derivative of PVDF.

According to one embodiment, the capping layer is a fluorinated polymer layer, such as an amorphous fluoropolymer. The advantage of the amorphous fluoropolymer said capping layer is the transparency and the low refractive index. According to one embodiment, the amorphous fluoropolymer is a CYTOP™.

According to one embodiment, the polymer layer may be a polymerized solid made from alpha-olefins, dienes such as butadiene and chloroprene; styrene, alpha-methyl styrene, and the like; heteroatom substituted alpha-olefins, for example, vinyl acetate, vinyl alkyl ethers for example, ethyl vinyl ether, vinyltrimethylsilane, vinyl chloride, tetrafluoroethylene, chlorotrifiuoroethylene, cyclic and polycyclic olefin compounds for example, cyclopentene, cyclohexene, cycloheptene, cyclooctene, and cyclic derivatives up to C20; polycyclic derivates for example, norbornene, and similar derivatives up to C20; cyclic vinyl ethers for example, 2,3-dihydrofuran, 3,4-dihydropyran, and similar derivatives; allylic alcohol derivatives for example, vinylethylene carbonate, disubstituted olefins such as maleic and fumaric compounds for example, maleic anhydride, diethylfumarate, and the like, and mixture thereof.

According to one embodiment, the polymer may be PMMA, Poly(lauryl methacrylate), glycolized poly(ethylene terephthalate), Poly(maleic anhydride altoctadecene), or mixture thereof.

According to one embodiment, examples of polymer layer include but are not limited to: silicon based polymer, PET or PVA.

According to one embodiment, the capping layer is optically transparent.

According to one embodiment, the capping layer is optically transparent at wavelengths where the nanocrystal is absorbing.

According to one embodiment, the capping layer is optically transparent at wavelengths from 1 μm to 300 μm, preferably from 3 μm to 200 μm.

According to one embodiment, the capping layer is optically transparent at wavelengths from 5 μm to 300 μm, preferably from 50 μm to 200 μm.

According to one embodiment, the capping layer has a thickness from 1 nm to 10 mm, preferably from 10 nm to 10 μm and more preferably from 20 nm to 1 μm.

According to one embodiment, the capping layer has a thickness of 20 μm, 21 μm, 22 μm, 23 μm, 24 μm, 25 μm, 26 μm, 27 μm, 28 μm, 29 μm, 30 μm, 31 μm, 32 μm, 33 μm, 34 μm, 35 μm, 36 μm, 37 μm, 38 μm, 39 μm, 40 μm, 41 μm, 42 μm, 43 μm, 44 μm, 45 μm, 46 μm, 47 μm, 48 μm, 49 μm, 50 μm, 51 μm, 52 μm, 53 μm, 54 μm, 55 μm, 56 μm, 57 μm, 58 μm, 59 μm, 60 μm, 61 μm, 62 μm, 63 μm, 64 μm, 65 μm, 66 μm, 67 μm, 68 μm, 69 μm, 70 μm, 71 μm, 72 μm, 73 μm, 74 μm, 75 μm, 76 μm, 77 μm, 78 μm, 79 μm, 80 μm, 81 μm, 8.2 μm, 83 μm, 84 μm, 85 μm, 86 μm, 87 μm, 88 μm, 89 μm, 90 μm, 91 μm, 92 μm, 93 μm, 94 μm, 95 μm, 96 μm, 97 μm, 98 μm, 99 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm or 1000 μm.

According to one embodiment, the capping layer covers partially or totally the photoabsorptive film.

According to one embodiment, the capping layer covers and surrounds partially or totally the photoabsorptive film.

According to one embodiment, the capping layer is deposited on the photoabsorptive film by atomic layer deposition, chemical bath deposition, or any other method known by the skilled artisan.

The invention also relates to a photoconductor, photodetector, photodiode or phototransistor comprising:
a photoabsorptive layer comprising a photoabsorptive film comprising a plurality of metal chalcogenide nanocrystals or a plurality of metal chalcogenide nanocrystals manufactured according to the method of the invention; and
a first plurality of electrical connections bridging the photoabsorptive layer; wherein the plurality of metal chalcogenide nanocrystals is positioned such that there is an increased conductivity between the electrical connections and across the photoabsorptive layer, in response to illumination of the photoabsortive layer with light at a wavelength ranging above 50 pm.

The invention also relates to an apparatus comprising:
a photoabsorptive layer comprising a photoabsorptive film as described hereabove or at least one material as described herebelow; and
a first plurality of electrical connections bridging the photoabsorptive layer;

wherein the photoabsorptive layer is positioned such that there is an increased conductivity between the electrical connections and across the photoabsorptive layer, in response to illumination of the photoabsortive layer with light at a wavelength ranging above 1.7 μm,

wherein said apparatus is a photoconductor, photodetector, photodiode or phototransistor.

According to one embodiment, the photoabsorptive film is as described hereabove.

According to one embodiment, the photoabsorptive layer has a thickness from 3 nm to 1 mm, preferably from 30 nm to 10 μm, more preferably from 50 nm to 1 μm.

According to one embodiment, the photoabsorptive layer has a thickness of at least 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 30 nm, 40 nm, 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm

According to one embodiment, the photoabsorptive layer has an area from 100 nm² to 1 m², preferably from 1 μm² to 10 cm², more preferably from 50 μm² to 1 cm².

According to one embodiment, the photoabsorptive layer has an area of at least 100 nm², 200 nm², 300 nm², 400 nm², 500 nm², 600 nm², 700 nm², 800 nm², 900 nm², 1000 nm², 2000 nm², 3000 nm², 4000 nm², 5000 nm², 6000 nm², 7000 nm², 8000 nm², 9000 nm², 10000 nm², 20000 nm², 30000 nm², 40000 nm², 50000 nm², 60000 nm², 70000 nm², 80000 nm², 90000 nm², 100000 nm², 200000 nm², 300000 nm², 400000 nm², 500000 nm², 600000 nm², 700000 nm², 800000 nm², 900000 nm², 1 μm², 2 μm², 3 μm², 4 μm², 5 μm², 6 μm², 7 μm², 8 μm², 9 μm², 10 μm², 20 μm², 30 μm², 40 μm², 50 μm², 60 μtm², 70 μm², 80 μm², 90 μm², 100 μm², 200 μm², 300 μm², 400 μm², 500 μm², 600 μm, 700 μm², 800 μm², 900 μm², 1000 μm², 2000 μm², 3000 μm², 4000 μm, 5000 μm², 6000 μm², 7000 μm², 8000 μm², 9000 μm², 10000 μm², 20000 μm², 30000 μm², 40000 μm², 50000 μm², 60000 μm², 70000 μm², 80000 μm², 90000 μm², 100000 μm², 200000 μm², 300000 μm², 400000 μm², 500000 μm², 600000 μm², 700000 μm², 800000 μm², 900000 μm², 1000000 μm², 2000000 μm², 3000000 μm², 4000000 μm², 5000000 μm², 6000000 μm², 7000000 μm², 8000000 μm², 9000000 μm², 10000000 μm², 20000000 μm², 3000000 μm², 4000000 μm², 5000000 μm², 6000000 μm², 7000000 μm², 8000000 μm², 9000000 μm², 1 cm², 2 cm², 3 cm², 4 cm², 5 cm², 6 cm², 7 cm², 8 cm², 9 cm², 10 cm², 20 cm², 30 cm², 40 cm², 50 cm², 60 cm², 70 cm², 80 cm², 90 cm², 100 cm², 200 cm², 300 cm², 400 cm², 500 cm², 600 cm², 700 cm², 800 cm², 900 cm², 1000 cm², 2000 cm², 3000 cm², 4000 cm², 5000 cm², 6000 cm², 7000 cm², 8000 cm², 9000 cm², or 1 m².

According to one embodiment, the photoabsorptive layer is prepared by dropcasting, spincoating, dipcoating, electrophoretic deposition, doctor blading, a Langmuir blodget method, an electrophoretic procedure, or any method known by the skilled artisan.

According to one embodiment, the photoabsorptive layer is prepared by dropcasting, spincoating, dipcoating of a solution of said nanocrystals on a substrate.

According to one embodiment, the substrate is as described hereabove.

According to one embodiment, the photoabsorptive layer is further protected by at least one capping layer.

According to one embodiment, the capping layer is as described hereabove.

According to one embodiment, the photoabsorptive layer has an absorption coefficient ranging from 100 cm⁻⁻to 5×10⁵ cm⁻¹ at the first optical feature, preferably from 500 cm⁻¹ to 10⁵ cm⁻¹, more preferably from 1000 cm⁻¹ to 10⁴ cm⁻¹.

According to one embodiment, the photoabsorptive layer is an active layer of the photoconductor, photodetector, photodiode or phototransistor.

According to one embodiment, the photoconductor, photodetector, photodiode or phototransistor can be selected in the group of a charge-coupled device (CCD), a luminescent probe, a laser, a thermal imager, a night-vision system and a photodetector.

According to one embodiment, the photoconductor, photodetector, photodiode or phototransistor has a high carrier mobility.

According to one embodiment, the photoconductor, photodetector, photodiode or phototransistor has a carrier mobility higher than 1 cm²V⁻¹s⁻¹, preferably higher than 5 cm²V⁻¹s⁻¹, more preferably higher than 10 cm²V⁻¹s⁻¹.

According to one embodiment, the carrier mobility is not less than 1 cm²V⁻¹s⁻¹, preferably more than 10 cm²V⁻¹s⁻¹, more preferably higher than 50 cm²V⁻¹s⁻¹.

According to one embodiment, the photoconductor, photodetector, photodiode or phototransistor of the invention comprises a first cathode, the first cathode being electronically coupled to a first photoabsorptive layer as described hereabove or a plurality of metal chalcogenide nanocrystals manufactured according to the method of the invention, the first photoabsorptive layer being coupled to a first anode.

According to one embodiment, the photoconductor, photodetector, photodiode or phototransistor comprises a plurality of electrodes, said electrodes comprising at least one cathode and one anode.

According to one embodiment, the photoabsorptive layer is connected to at least two electrodes.

According to one embodiment, the photoabsorptive layer is connected to three electrodes, wherein one of them is used as a gate electrode.

According to one embodiment, the photoabsorptive layer is connected to an array of electrodes.

According to one embodiment, the electrodes are fabricated using a shadow mask.

According to one embodiment, the electrodes are fabricated by standard lithography methods or any methods known by those skilled in the art.

According to one embodiment illustrated in FIG. 8, the transistor may be a dual (bottom and electrolytic) gated transistor comprising a thin HgSe nanocrystals photoabsorptive film 2 on a support; electrodes such as a drain electrode 22, a source electrode 21 and a top gate electrode 24; and an electrolyte 23. In this embodiment, the HgSe nanocrystals photoabsorptive film 2 is deposited on top of a support and connected to the source and the drain electrodes (21, 22); the electrolyte 23 is deposited on top of said film 2 and the top gate 24 is on top of the electrolyte 23. The support may be a doped Si substrate 25.

According to one embodiment, the photoconductor, photodetector, photodiode or phototransistor comprises an electrolyte 23.

According to one embodiment, the nanocrystals based is coupled to an ion gel gating such as LiClO₄.

In one embodiment, the electrolyte 23 comprises a matrix and ions. In one embodiment, the electrolyte 23 comprises a polymer matrix.

In one embodiment the polymer matrix of the electrolyte 23 comprises polystyrene, poly(N-isopropyl acrylamide), polyethylene glycol, polyethylene, polybutadiene, polyisoprene, polyethylene oxide, polyethyleneimine, polymethylmethacrylate, polyethylacrylate, polyvinylpyrrolidone, polypropylene glycol, polydimethylsiloxane, polyisobutylene, or a blend/multiblocks polymer thereof.

In one embodiment, the electrolyte 23 comprises at least one ion salt. In one embodiment, the electrolyte 23 comprises ions salts. In one embodiment, the polymer matrix is doped with ions salts. In one embodiment, examples of ions salts include but are not limited to: LiCl, LiBr, LiI, LiSCN, LiClO₄, KClO₄, NaClO₄, ZnCl₃⁻, ZnCl₄²⁻, ZnBr₂, LiCF₃SO₃, NaCl, NaI, NaBr, NaSCN, KC1, KBr, KI, KSCN, LIN(CF₃O₂)₂ or a mixture thereof.

FIG. 9 illustrates transfer curves (current as a function of gate bias) for HgTe nanocrystals.

FIG. 9A illustrates transfer curves (current as a function of gate bias) for HgTe nanocrystals with an excitonic feature at 4000 cm⁻¹.

FIG. 9B illustrates transfer curves (current as a function of gate bias) for HgTe nanocrystals with a cut off at 2000 cm⁻¹.

FIG. 9C illustrates transfer curves (current as a function of gate bias) for HgTe nanocrystals with a plasmonic feature at 450 cm⁻¹.

According to one embodiment, the photoabsorptive layer exhibits a spectrum which is tuned by electrochemistry.

According to one embodiment, the photoabsorptive layer is connected to a read out circuit.

According to one embodiment, the photoabsorptive layer is not directly connected to the electrodes.

According to one embodiment, the photoabsorptive layer is spaced from the electrodes by a unipolar barrier which band alignment with respect to the photoabsorptive layer only favors the transfer of one carrier (electron or hole) to the electrode.

According to one embodiment, the optically active layer is spaced from the electrodes by a unipolar barrier which band alignment with respect to the optically active layer only favors the transfer of one carrier (electron or hole) from the electrode.

According to one embodiment, the unipolar barrier is a hole blocking layer.

According to one embodiment, the unipolar barrier is an electron blocking layer.

According to one embodiment, the unipolar barrier is used to reduce the dark current.

According to one embodiment, the unipolar barrier is used to reduce the majority carrier current.

According to one embodiment, the photoabsorptive layer is cooled down by a Peltier device.

According to one embodiment, the photoabsorptive layer is cooled down by a cryogenic cooler.

According to one embodiment, the photoabsorptive layer is cooled down using liquid nitrogen.

According to one embodiment, the photoabsorptive layer is cooled down using liquid helium.

According to one embodiment, the photoabsorptive layer is operated from 1.5K to 350K, preferably from 4K to 310K, more preferably from 70K to 300K.

According to one embodiment, the photoabsorptive layer is illuminated by the front side.

According to one embodiment, the photoabsorptive layer is illuminated by the back side (through a transparent substrate).

According to one embodiment, the photoabsorptive layer is used as an infrared emitting layer.

According to one embodiment, the photoabsorptive layer has a photo response ranging from 1 μA.W⁻¹ to 1 kA.W⁻¹, from 1 mA.W⁻¹ to 50 A.W⁻¹, or from 10 mA.W⁻¹ to 10 A.W⁻¹.

According to one embodiment, the photoabsorptive layer has a noise current density limited by 1/f noise.

According to one embodiment, the photoabsorptive layer has a noise current density limited by Johnson noise.

According to one embodiment, the photoabsorptive layer has a specific detectivity ranging from 10⁶ to 10¹⁴ jones, from 10⁷ to 10¹³ jones, or from 10⁸ to 5×10¹² jones.

According to one embodiment, the photoabsorptive layer has a bandwidth of at least 1 Hz, 2 Hz, 3 Hz, 4 Hz, 5 Hz, 6 Hz, 7 Hz, 8 Hz, 9 Hz, 10 Hz, 11 Hz, 12 Hz, 13 Hz, 14 Hz, 15 Hz, 16 Hz, 17 Hz, 18 Hz, 19 Hz, 20 Hz, 30 Hz, 40 Hz, 50 Hz, 60 Hz, 70 Hz, 80 Hz, 100 Hz, 110 Hz, 120 Hz, 130 Hz, 140 Hz, 150 Hz, 160 Hz, 170 Hz, 180 Hz, 190 Hz, 200 Hz, 210 Hz, 220 Hz, 230 Hz, 240 Hz, 250 Hz, 260 Hz, 270 Hz, 280 Hz, 290 Hz, 300 Hz, 350 Hz, 400 Hz, 450 Hz, 500 Hz, 550 Hz, 600 Hz, 650 Hz, 700 Hz, 750 Hz, 800 Hz, 850 Hz, 900 Hz, 950 Hz, 1 kHz, 5 kHz, 10 kHz, 20 kHz, 25 kHz, 30 kHz, 35 kHz, 40 kHz, 45 kHz, 50 kHz, 55 kHz, 60 kHz, 65 kHz, 70 kHz, 75 kHz, 80 kHz, 85 kHz, 90 kHz, 95 kHz, 100 kHz, 200 kHz, 250 kHz, 300 kHz, 350 kHz, 400 kHz, 450 kHz, 500 kHz, 550 kHz, 600 kHz, 650 kHz, 700 kHz, 750 kHz, 800 kHz, 850 kHz, 900 kHz, 950 kHz, 1 MHz, 5 MHz, 10 MHz, 15 MHz, 20 MHz, 25 MHz, 30 MHz, 35 MHz, 40 MHz, 45 MHz, 50 MHz, 55 MHz, 60 MHz, 65 MHz, 70 MHz, 75 MHz, 80 MHz, 85 MHz, 90 MHz, 95 MHz, 100 MHz, 200 MHz, 250 MHz, 300 MHz, 350 MHz, 400 MHz, 450 MHz, 500 MHz, 550 MHz, 600 MHz, 650 MHz, 700 MHz, 750 MHz, 800 MHz, 850 MHz, 900 MHz, 950 MHz, or 1 GHz.

According to one embodiment, the time response of the photoabsorptive layer or film under a pulse of light is smaller than 1 ms, preferably smaller than 100 μs, more preferably smaller than 10 μs and even more preferably smaller than 1 μs.

According to one embodiment, the time response of the photoabsorptive layer or film under a pulse of light is smaller than 1 μs, preferably smaller than 100 ns, more preferably smaller than 10 ns and even more preferably smaller than 1 ns.

According to one embodiment, the time response of the photoabsorptive layer or film under a pulse of light is smaller than 1 ns, preferably smaller than 100 ps, more preferably smaller than 10 ps and even more preferably smaller than 1 ps.

According to one embodiment, the magnitude and sign of the photoresponse of the photoabsorptive layer or film is tuned or controlled by a gate bias

According to one embodiment, the magnitude and sign of the photoresponse of the photoabsorptive layer or film is tuned with the incident wavelength of the light.

According to one embodiment, the time response of the photoconductor, photodetector, photodiode or phototransistor is fastened by reducing the spacing between electrodes.

According to one embodiment, the time response of the photoconductor, photodetector, photodiode or phototransistor is fastened by using a nanotrench geometry compared to micrometer spaced electrodes.

According to one embodiment, the time response of the photoconductor, photodetector, photodiode or phototransistor is tuned or controlled with a gate bias.

According to one embodiment, the time response of the photoconductor, photodetector, photodiode or phototransistor depends on the incident wavelength of the light.

According to one embodiment, the time response of the photoconductor, photodetector, photodiode or phototransistor is smaller than 1 s, preferably smaller than 100 ms, more preferably smaller than 10 ms and even more preferably smaller than 1 ms.

According to one embodiment, the magnitude, sign and duration of the photoresponse of the photodetector is tuned or controlled by a gate bias.

According to one embodiment, the magnitude, sign and duration of the photoresponse of the photodetector depends on the incident wavelength.

According to one embodiment, the photoabsorptive layer exhibits an infrared spectrum which is tuned by changing the surface chemistry.

According to one embodiment, the carrier density of the photoabsorptive layer is tuned using a gate.

According to one embodiment, the carrier density of the photoabsorptive layer is tuned using a back gate.

According to one embodiment, the carrier density of the photoabsorptive layer is tuned using a top gate.

According to one embodiment, the carrier density of the photoabsorptive layer is tuned using an electrochemical gate.

According to one embodiment, the carrier density of the photoabsorptive layer is tuned using a liquid electrochemical gate.

According to one embodiment, the carrier density of the photoabsorptive layer is tuned using a solid electrochemical gate.

According to one embodiment, the photodetector is used as a flame detector.

According to one embodiment, the photodetector allows bicolor detection.

According to one embodiment, the photodetector allows bicolor detection and one of the wavelengths is centered around the CO₂ absorption at 4.2 μm.

According to one embodiment, the photodetector allows bicolor detection and one of the wavelengths is centered around the CH absorption at 3.3 μm.

According to one embodiment, the photodetector allows bicolor detection and one of the wavelengths is centered around the H₂O absorption at 3 μm.

According to one embodiment, the photodetector allows bicolor detection and one of the wavelengths is centered from 3 μm to 4.2 μm.

According to one embodiment, the photodetector allows bicolor detection and one of the wavelengths is centered around 1.3 μm.

According to one embodiment, the photodetector allows bicolor detection and one of the wavelengths is centered around 1.55 μm.

According to one embodiment, the photodetector allows bicolor detection and one of the wavelengths is centered from 3 μm to 5 μm.

According to one embodiment, the photodetector allows bicolor detection and one of the wavelengths is centered from 8 μm to 12 μm.

According to one embodiment, the photodetector allows multicolor detection.

According to one embodiment, the photoconductor, photodetector, photodiode or phototransistor comprises at least one pixel comprising the photoabsorptive layer as described hereabove.

According to one embodiment, the photoconductor, photodetector, photodiode or phototransistor comprises only one pixel. In this embodiment, the photoconductor, photodetector, photodiode or phototransistor is a single pixel device.

According to one embodiment, the photoconductor, photodetector, photodiode or phototransistor comprises a plurality of pixels, each pixel comprising the photoabsorptive layer as described hereabove.

According to one embodiment, the photoconductor, photodetector, photodiode or phototransistor comprises at least 1, 2, 3, 4, 5, 6, 7, 8, 9, 10 pixels.

According to one embodiment, the pixels form an array of pixels.

According to one embodiment, an array of pixel comprises at least 4×4 pixels, 16×16 pixels, 32×32 pixels, 50×50 pixels, 64×64 pixels, 128×128 pixels, 256×256 pixels, 512×512 pixels or 1024×1024 pixels.

In one embodiment, the size of the array of pixels has a VGA format.

According to one embodiment, an array of pixel comprises at least 2500, 3000, 4000, 5000, 6000, 7000, 8000, 9000, 10000, 20000, 30000, 40000, 50000, 60000, 65536, 70000, 80000, 90000, 100000, 200000, 262144, 300000, 400000, 500000, 600000, 700000, 800000, 900000, 1000000, or 1048576 pixels.

According to one embodiment, pixels of the array of pixels are separated by a pixel pitch.

According to one embodiment, the pixel pitch is at least 0.1 μm, 0.2 μm, 0.3 μm, 0.4 μm, 0.5 μm, 0.6 μm, 0.7 μm, 0.8 μm, 0.9 μm, 1 μm, 2 μm, 3 μm, 4 μm, 5 μm, 6 μm, 7 μm, 8 μm, 9 μm, 10 μm, 11 μm, 12 μm, 13 μm, 14 μm, 15 μm, 16 μm, 17 μm, 18 μm, 19 μm, 20 μm, 21 μm, 22 μm, 23 μm, 24 μm, 25 μm, 26 μm, 27 μm, 28 μm, 29 μm, 30 μm, 31 μm, 32 μm, 33 μm, 34 μm, 35 μm, 36 μm, 37 μm, 38 μm, 39 μm, 40 μm, 41 μm, 42 μm, 43 μm, 44 μm, 45 μm, 46 μm, 47 μm, 48 μm, 49 μm, 50 μm, 51 μm, 52 μm, 53 μm, 54 μm, 55 μm, 56 μm, 57 μm, 58 μm, 59 μm, 60 μm, 61 μm, 62 μm, 63 μm, 64 μm, 65 μm, 66 μm, 67 μm, 68 μm, 69 μm, 70 μm, 71 μm, 72 μm, 73 μm, 74 μm, 75 μm, 76 μm, 77 μm, 78 μm, 79 μm, 80 μm, 81 μm, 8.2 μm, 83 μm, 84 μm, 85 μm, 86 μm, 87 μm, 88 μm, 89 μm, 90 μm, 91 μm, 92 μm, 93 μm, 94 μm, 95 μm, 96 μm, 97 μm, 98 μm, 99 μm, 100μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, 1 mm, 50 mm, 100 mm, 200 mm, 300 mm, 400 mm, 500 mm, 600 mm, 700 mm, 800 mm, 900 mm, 1 mm, 1.1 mm, 1.2 mm, 1.3 mm, 1.4 mm, 1.5 mm, 1.6 mm, 1.7 mm, 1.8 mm, 1.9 mm, 2 mm, 2.1 mm, 2.2 mm, 2.3 mm, 2.4 mm, 2.5 mm, 2.6 mm, 2.7 mm, 2.8 mm, 2.9 mm, 3 mm, 3.1 mm, 3.2 mm, 3.3 mm, 3.4 mm, 3.5 mm, 3.6 mm, 3.7 mm, 3.8 mm, 3.9 mm, 4 mm, 4.1 mm, 4.2 mm, 4.3 mm, 4.4 mm, 4.5 mm, 4.6 mm, 4.7 mm, 4.8 mm, 4.9 mm, 5 mm, 5.1 mm, 5.2 mm, 5.3 mm, 5.4 mm, 5.5 mm, 5.6 mm, 5.7 mm, 5.8 mm, 5.9 mm, 6 mm, 6.1 mm, 6.2 mm, 6.3 mm, 6.4 mm, 6.5 mm, 6.6 mm, 6.7 mm, 6.8 mm, 6.9 mm, 7 mm, 7.1 mm, 7.2 mm, 7.3 mm, 7.4 mm, 7.5 mm, 7.6 mm, 7.7 mm, 7.8 mm, 7.9 mm, 8 mm, 8.1 mm, 8.2 mm, 8.3 mm, 8.4 mm, 8.5 mm, 8.6 mm, 8.7 mm, 8.8 mm, 8.9 mm, 9 mm, 9.1 mm, 9.2 mm, 9.3 mm, 9.4 mm, 9.5 mm, 9.6 mm, 9.7 mm, 9.8 mm, 9.9 mm, 1 cm, 1.1 cm, 1.2 cm, 1.3 cm, 1.4 cm, 1.5 cm, 1.6 cm, 1.7 cm, 1.8 cm, 1.9 cm, 2 cm, 2.1 cm, 2.2 cm, 2.3 cm, 2.4 cm, 2.5 cm, 2.6 cm, 2.7 cm, 2.8 cm, 2.9 cm, 3 cm, 3.1 cm, 3.2 cm, 3.3 cm, 3.4 cm, 3.5 cm, 3.6 cm, 3.7 cm, 3.8 cm, 3.9 cm, 4 cm, 4.1 cm, 4.2 cm, 4.3 cm, 4.4 cm, 4.5 cm, 4.6 cm, 4.7 cm, 4.8 cm, 4.9 cm, 5 cm, 5.1 cm, 5.2 cm, 5.3 cm, 5.4 cm, 5.5 cm, 5.6 cm, 5.7 cm, 5.8 cm, 5.9 cm, 6 cm, 6.1 cm, 6.2 cm, 6.3 cm, 6.4 cm, 6.5 cm, 6.6 cm, 6.7 cm, 6.8 cm, 6.9 cm, 7 cm, 7.1 cm, 7.2 cm, 7.3 cm, 7.4 cm, 7.5 cm, 7.6 cm, 7.7 cm, 7.8 cm, 7.9 cm, 8 cm, 8.1 cm, 8.2 cm, 8.3 cm, 8.4 cm, 8.5 cm, 8.6 cm, 8.7 cm, 8.8 cm, 8.9 cm, 9 cm, 9.1 cm, 9.2 cm, 9.3 cm, 9.4 cm, 9.5 cm, 9.6 cm, 9.7 cm, 9.8 cm, 9.9 cm, or 10 cm.

According to one embodiment, the pixel size is at least 1 μm, 2 μm, 3 μm, 4 μm, 5 μm, 6 μm, 7 μm, 8 μm, 9 μm, 10 μm, 11 μm, 12 μm, 13 μm, 14 μm, 15 μm, 16 μm, 17 μm, 18 μm, 19 μm, 20 μm, 21 μm, 22 μm, 23 μm, 24 μm, 25 μm, 26 μm, 27 μm, 28 μm, 29 μm, 30 μm, 31 μm, 32 μm, 33 μm, 34 μm, 35 μm, 36 μm, 37 μm, 38 μm, 39 μm, 40 μm, 41 μm, 42 μm, 43 μm, 44 μm, 45 μm, 46 μm, 47 μm, 48 μm, 49 μm, 50 μm, 51 μm, 52 μm, 53 μm, 54 μm, 55 μm, 56 μm, 57 μm, 58 μm, 59 μm, 60 μm, 61 μm, 62 μm, 63 μm, 64 μm, 65 μm, 66 μm, 67 μm, 68 μm, 69 μm, 70 μm, 71 μm, 72 μm, 73 μm, 74 μm, 75 μm, 76 μm, 77 μm, 78 μm, 79 μm, 80 μm, 81 μm, 8.2 μm, 83 μm, 84 μm, 85 μm, 86 μm, 87 μm, 88 μm, 89 μm, 90 μm, 91 μm, 92 μm, 93 μm, 94 μm, 95 μm, 96 μm, 97 μm, 98 μm, 99 μm, 100μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, 1 mm, 1.1 mm, 1.2 mm, 1.3 mm, 1.4 mm, 1.5 mm, 1.6 mm, 1.7 mm, 1.8 mm, 1.9 mm, 2 mm, 2.1 mm, 2.2 mm, 2.3 mm, 2.4 mm, 2.5 mm, 2.6 mm, 2.7 mm, 2.8 mm, 2.9 mm, 3 mm, 3.1 mm, 3.2 mm, 3.3 mm, 3.4 mm, 3.5 mm, 3.6 mm, 3.7 mm, 3.8 mm, 3.9 mm, 4 mm, 4.1 mm, 4.2 mm, 4.3 mm, 4.4 mm, 4.5 mm, 4.6 mm, 4.7 mm, 4.8 mm, 4.9 mm, 5 mm, 5.1 mm, 5.2 mm, 5.3 mm, 5.4 mm, 5.5 mm, 5.6 mm, 5.7 mm, 5.8 mm, 5.9 mm, 6 mm, 6.1 mm, 6.2 mm, 6.3 mm, 6.4 mm, 6.5 mm, 6.6 mm, 6.7 mm, 6.8 mm, 6.9 mm, 7 mm, 7.1 mm, 7.2 mm, 7.3 mm, 7.4 mm, 7.5 mm, 7.6 mm, 7.7 mm, 7.8 mm, 7.9 mm, 8 mm, 8.1 mm, 8.2 mm, 8.3 mm, 8.4 mm, 8.5 mm, 8.6 mm, 8.7 mm, 8.8 mm, 8.9 mm, 9 mm, 9.1 mm, 9.2 mm, 9.3 mm, 9.4 mm, 9.5 mm, 9.6 mm, 9.7 mm, 9.8 mm, 9.9 mm, 1 cm, 1.1 cm, 1.2 cm, 1.3 cm, 1.4 cm, 1.5 cm, 1.6 cm, 1.7 cm, 1.8 cm, 1.9 cm, 2 cm, 2.1 cm, 2.2 cm, 2.3 cm, 2.4 cm, 2.5 cm, 2.6 cm, 2.7 cm, 2.8 cm, 2.9 cm, 3 cm, 3.1 cm, 3.2 cm, 3.3 cm, 3.4 cm, 3.5 cm, 3.6 cm, 3.7 cm, 3.8 cm, 3.9 cm, 4 cm, 4.1 cm, 4.2 cm, 4.3 cm, 4.4 cm, 4.5 cm, 4.6 cm, 4.7 cm, 4.8 cm, 4.9 cm, 5 cm, 5.1 cm, 5.2 cm, 5.3 cm, 5.4 cm, 5.5 cm, 5.6 cm, 5.7 cm, 5.8 cm, 5.9 cm, 6 cm, 6.1 cm, 6.2 cm, 6.3 cm, 6.4 cm, 6.5 cm, 6.6 cm, 6.7 cm, 6.8 cm, 6.9 cm, 7 cm, 7.1 cm, 7.2 cm, 7.3 cm, 7.4 cm, 7.5 cm, 7.6 cm, 7.7 cm, 7.8 cm, 7.9 cm, 8 cm, 8.1 cm, 8.2 cm, 8.3 cm, 8.4 cm, 8.5 cm, 8.6 cm, 8.7 cm, 8.8 cm, 8.9 cm, 9 cm, 9.1 cm, 9.2 cm, 9.3 cm, 9.4 cm, 9.5 cm, 9.6 cm, 9.7 cm, 9.8 cm, 9.9 cm, or 10 cm.

According to one embodiment, the pixel pitch is inferior to the pixel size.

According to one embodiment, the pixel pitch is 50%, 40%, 30%, 20%, 10%, or 5% of the pixel size.

According to one embodiment, pixels do not touch.

According to one embodiment, pixels do not overlap.

According to one embodiment, the array of pixels is a megapixel array of pixels.

According to one embodiment, the array of pixels comprises more than one megapixel array of pixels, more than 2 megapixels, more than 4 megapixels, more than 8 megapixels, more than 10 megapixels or more than 50 megapixels.

According to one embodiment, the array of pixels has a filling factor of at least 40%, 40%, 45%, 50%, 55%, 60%, 65%, 70%, 75%, 80%, 85%, 90%, 95%, or 100%. The filling factor refers to the area of the total array of pixels made of pixels.

According to one embodiment, each pixel is connected to a read out circuit.

According to one embodiment, each pixel is connected to a read out circuit in a planar geometry.

According to one embodiment, each pixel is connected to a read out circuit in a vertical geometry.

According to one embodiment, the array of pixels is connected to a read out circuit.

According to one embodiment, the array of pixels is connected to a read out circuit in a planar geometry.

According to one embodiment, the array of pixels is connected to a read out circuit in a vertical geometry.

According to one embodiment, the plurality of metal chalcogenide nanocrystals manufactured according to the method of the invention comprised in the photoconductor, photodetector, photodiode or phototransistor is an array of pixels comprising said metal chalcogenide nanocrystals.

According to one embodiment, the photodetector is a 1D (line) detector.

According to one embodiment, the photodetector is a 2D (line) detector.

The invention also relates to a device, preferably a photoconductor device, comprising:
a plurality of photoconductors, photodetectors, photodiodes or phototransistors as described hereabove; and
a readout circuit electrically connected to the plurality of photoconductors, photodetectors photodiodes or phototransistors.

Another object of the invention relates to the use of metal chalcogenide nanocrystals of the invention, the material of the invention, or at least one film of the invention.

According to one embodiment, the metal chalcogenide nanocrystals of the invention, the material of the invention, or at least one film of the invention are used for their spectral selective properties.

According to one embodiment, the metal chalcogenide nanocrystals of the invention, the material of the invention, or at least one film of the invention are used for their spectral selective properties in the mid infrared.

According to one embodiment, the metal chalcogenide nanocrystals of the invention, the material of the invention, or at least one film of the invention are used for their spectral selective properties in the THz range of wavelengths.

According to one embodiment, the metal chalcogenide nanocrystals of the invention and/or the photoabsorptive film 2 as described hereabove, or the material of the invention, are comprised in an optical filter operating.

According to one embodiment, the plurality of metal chalcogenide nanocrystals of the invention, the material of the invention, or at least one film of the invention are used for optical filtering.

According to one embodiment, the metal chalcogenide nanocrystals of the invention and/or the photoabsorptive film 2 as described hereabove, or the material of the invention are used as an optical filter operating in transmission mode.

According to one embodiment, the metal chalcogenide nanocrystals of the invention and/or the photoabsorptive film 2 as described hereabove, or the material of the invention are used in an optical filter operating in transmission mode.

According to one embodiment, the metal chalcogenide nanocrystals of the invention and/or the photoabsorptive film 2 as described hereabove, or the material of the invention are used as an optical filter operating in reflexion mode.

According to one embodiment, the metal chalcogenide nanocrystals of the invention and/or the photoabsorptive film 2 as described hereabove, or the material of the invention are used in an optical filter operating in reflexion mode.

According to one embodiment, the metal chalcogenide nanocrystals of the invention and/or the photoabsorptive film 2 as described hereabove, or the material of the invention are used as a high pass filter.

According to one embodiment, the metal chalcogenide nanocrystals of the invention and/or the photoabsorptive film 2 as described hereabove, or the material of the invention are used as a low pass filter

According to one embodiment, the metal chalcogenide nanocrystals of the invention and/or the photoabsorptive film 2 as described hereabove, or the material of the invention are used as a band pass filter.

According to one embodiment, the metal chalcogenide nanocrystals of the invention, the material of the invention, or at least one film of the invention are used in paint. In this embodiment, the metal chalcogenide nanocrystals of the invention may be used in paint for buildings, planes, vehicles or any other object.

According to one embodiment, the metal chalcogenide nanocrystals of the invention, or the material of the invention are used in ink.

According to one embodiment, the metal chalcogenide nanocrystals of the invention and/or the photoabsorptive film 2 as described hereabove, or the material of the invention are deposited on a bolometer. In this embodiment, the metal chalcogenide nanocrystals of the invention and/or the photoabsorptive film 2 as described hereabove may tune the spectral response of said bolometer, such as for example enhancing the infrared absorption of said bolometer.

According to one embodiment, the metal chalcogenide nanocrystals of the invention and/or the photoabsorptive film 2 as described hereabove, or the material of the invention are comprised in a bolometer.

According to one embodiment, the metal chalcogenide nanocrystals of the invention and/or the photoabsorptive film 2 as described hereabove, or the material of the invention are deposited on a membrane. In this embodiment, membrane refers to for example silicone membrane, silica membrane, VOx membrane, or any membrane known from those skilled in the art. The advantage of said membrane is to be used as a bolometer. Indeed the spectral or magnitude response can be improved though the deposition of nanoparticles as described above.

According to one embodiment, the metal chalcogenide nanocrystals of the invention and/or the photoabsorptive film 2 as described hereabove, or the material of the invention are comprised in an IR-absorbing coating.

According to one embodiment, the metal chalcogenide nanocrystals of the invention and/or the photoabsorptive film 2 as described hereabove, or the material of the invention are comprised in a pyrometer.

According to one embodiment, the metal chalcogenide nanocrystals of the invention and/or the photoabsorptive film 2 as described hereabove, or the material of the invention are comprised in a conductor preferably a photoconductor, a diode preferably a photodiode, a photovoltaic device, a detector preferably a photodetector or a transistor preferably a phototransistor.

According to one embodiment, the metal chalcogenide nanocrystals of the invention and/or the photoabsorptive film 2 as described hereabove, or the material of the invention are used as an active layer in a photoconductor, a photovoltaic device, or a phototransistor.

According to one embodiment, the metal chalcogenide nanocrystals of the invention and/or the photoabsorptive film 2 as described hereabove, or the material of the invention are used as an active layer in a photodetector.

According to one embodiment, the metal chalcogenide nanocrystals of the invention and/or the photoabsorptive film 2 as described hereabove, or the material of the invention are comprised in an infrared camera.

According to one embodiment, the metal chalcogenide nanocrystals of the invention and/or the photoabsorptive film 2 as described hereabove, or the material of the invention are used as the absorbing layer of an infrared camera.

According to one embodiment, the metal chalcogenide nanocrystals of the invention and/or the photoabsorptive film 2 as described hereabove, or the material of the invention are used to render an object undetectable, preferably undetectable for IR camera.

In another aspect, the present invention also relates to a material comprising:
a first optically active region comprising a first material presenting an intraband absorption feature, said first optically active region being a nanocrystal;
a second optically inactive region comprising a semiconductor material having a bandgap superior to the energy of the intraband absorption feature of the first optically active region; and

wherein said material presents an intraband absorption feature.

According to one embodiment, the first material is doped.

According to one embodiment, the doping of the first material ranges from 0.01 carrier to 100 carriers per nanocrystal, more preferably from 0.2 to 10 carriers per nanocrystal and even more preferably from 1 to 8 carriers per nanocrystal.

According to one embodiment, the doping level of the first material is above 10¹⁷ cm⁻³ and preferably above 10¹⁸ cm⁻³.

According to one embodiment, the doping level of the first material is below 10²² cm⁻³ and preferably below 5×10²⁰ cm⁻³.

According to one embodiment, the first material is doped by at least one electron. According to one embodiment, the first material is doped by at least one hole.

According to one embodiment, the doping of the first material is a n-type doping.

According to one embodiment, the doping of the first material is a p-type doping.

According to one embodiment, the first material is self-doped.

According to one embodiment, the doping is induced by impurity or impurities.

According to one embodiment, the first material is doped by the introduction of extrinsic impurities.

According to one embodiment, the doping is induced by non-stoichiometry of said first material.

According to one embodiment, the first material is doped by optical pumping.

According to one embodiment, the first material is doped by a gate effect.

According to one embodiment, the first material is doped by electrochemical pumping.

According to one embodiment, the first material is doped by electrochemistry.

According to one embodiment, the doping magnitude can be controlled by changing the capping ligands on the nanocrystal

According to one embodiment, the doping magnitude depends on the surface dipole associated with the molecule at the nanocrystal surface.

According to one embodiment, the doping is induced by surface effect.

According to one embodiment, the doping can be tuned while tuning the surface chemistry.

According to one embodiment, the doping can be tuned using electrochemistry.

According to one embodiment, the doping can be tuned by a gate.

According to one embodiment, the doping of the first material is stable in air.

According to one embodiment, the doping of the first material is stable at room temperature.

According to one embodiment, the doping of the first material is stable over a range of temperature between 1K and 400K, preferably between 4K and 330K.

According to one embodiment, the first material comprises at least one additional element in minor quantities. The term “minor quantities” refers herein to quantities ranging from 0.0001% to 10% molar, preferably from 0.001% to 10% molar.

According to one embodiment, the first material comprises at least one transition metal or lanthanide in minor quantities. The term “minor quantities” refers herein to quantities ranging from 0.0001% to 10% molar, preferably from 0.001% to 10% molar.

According to one embodiment, the first material comprises in minor quantities at least one element inducing an excess or a defect of electrons compared to the sole first material. The term “minor quantities” refers herein to quantities ranging from 0.0001% to 10% molar, preferably from 0.001% to 10% molar.

According to one embodiment, the first material comprises in minor quantities at least one element inducing a modification of the optical properties compared to the sole first material. The term “minor quantities” refers herein to quantities ranging from 0.0001% to 10% molar, preferably from 0.001% to 10% molar.

According to one embodiment, examples of additional element include but are not limited to: Ag⁺, Cu⁺ and Bi³⁺.

According to one embodiment, the first material is a narrow bandgap semiconductor material.

According to one embodiment, the first material has an intraband absorption feature ranging from 1.2 eV to 50 meV and more preferably from 0.8 eV to 0.1 eV.

According to one embodiment, the first material has an intraband absorption feature ranging from 10 000 cm⁻¹ to 500 cm⁻¹, preferably from 8 000 cm⁻¹ to 800 cm⁻¹ and more preferably from 6000 cm⁻¹ to 1000 cm⁻¹.

According to one embodiment, the first material has an intraband absorption feature ranging from 1 μm to 20 μm and more preferably ranging from 1.8 μm to 12 μm.

According to one embodiment, the first material is selected from MxEm, wherein M is a metal selected from Hg, Pb, Ag, Bi, Sn, Sb, Zn, In or a mixture thereof, and E is a chalcogen selected from S, Se, Te, O or a mixture thereof, and wherein x and m are independently a decimal number from 0 to 5 and are not simultaneously equal to 0; doped metal oxides; doped silicon; doped germanium; or a mixture thereof.

According to one embodiment, M is selected from the group consisting of Ia, Ha, IVa, IVb, IV, Va, Vb, V, or a mixture thereof.

According to one embodiment, E is selected from the group consisting of Va, VIa, or a mixture thereof.

According to one embodiment, the first material MₓEₘ comprises a semiconductor material selected from the group consisting of group IV, group IIIA-VA, group IIA-VIA, group IIIA-VIA, group IA-IIIA-VIA, group IIA-VA, group IVA-VIA, group VIB-VIA, group VB-VIA, group IVB-VIA or a mixture thereof.

According to one embodiment, the first material is selected from metal chalcogenides, doped metal oxide, doped silicon, doped germanium, or a mixture thereof.

According to one embodiment, examples of metal chalcogenides include but are not limited to: mercury chalcogenides, tin chalcogenides, silver chalcogenides, lead chalcogenides, bismuth chalcogenides, antimony chalcogenides, or a mixture thereof.

According to one embodiment, examples of mercury chalcogenides include but are not limited to: HgS, HgTe, HgSe, HgₓCd₁₋ₓTe wherein x is a real number strictly included between 0 and 1, or a mixture thereof.

According to one embodiment, the first material comprises HgSe.

According to one embodiment, the first material consists of HgSe.

According to one embodiment, examples of tin chalcogenides include but are not limited to SnTe, SnS, SnS₂, SnSe, or a mixture thereof.

According to one embodiment, examples of silver chalcogenides include but are not limited to: Ag₂S, Ag₂Se, Ag₂Te, or a mixture thereof.

According to one embodiment, examples of lead chalcogenides include but are not limited to: PbS, PbSe, PbTe, or a mixture thereof.

According to one embodiment, examples of bismuth chalcogenides include but are not limited to: Bi₂S₃, Bi₂Se₃, Bi₂Te₃, or a mixture thereof.

According to one embodiment, examples of antimony chalcogenides include but are not limited to: Sb₂S₃, Sb₂Se₃, Sb₂Te₃, or a mixture thereof.

According to one embodiment, M is selected from the group consisting of Hg or a mixture of Hg and at least one of Pb, Ag, Sn, Cd, Bi, or Sb.

According to one embodiment, examples of metal chalcogenides include but are not limited to: HgS, HgSe, HgTe, HgₓCd₁₋ₓTe wherein x is a real number strictly included between 0 and 1, PbS, PbSe, PbTe, Bi₂S₃, Bi₂Se₃, Bi₂Te₃, SnS, SnS₂, SnTe, SnSe, Sb₂S₃, Sb₂Se₃, Sb₂Te₃, Ag₂S, Ag₂Se, Ag₂Te or alloys, or mixture thereof.

According to one embodiment, doped silicon refers to silicon doped with atoms such as for example boron or nitrogen

According to one embodiment, examples of metal oxides include but are not limited to: zinc oxide ZnO, Indium oxide In₂O₃, or a mixture thereof.

According to one embodiment, doped metal oxides refers to metal oxides doped with Ga, Al, or a mixture thereof.

According to one embodiment, examples of first material include but are not limited to: HgS, HgSe, HgTe, HgₓCd₁₋ₓTe wherein x is a real number strictly included between 0 and 1, PbS, PbSe, PbTe, Bi₂S₃, Bi₂Se₃, Bi₂Te₃, SnS, SnS₂, SnTe, SnSe, Sb₂S₃, Sb₂Se₃, Sb₂Te₃, Ag₂S, Ag₂Se, Ag₂Te or alloys, doped silicon, doped germanium, doped ZnO, doped In₂O₃, or a mixture thereof.

According to one embodiment, the first optically active region presents exclusively an intraband absorption feature.

According to one embodiment, the first optically active region does not present a plasmonic absorption feature.

According to one embodiment, the shape of the intraband absorption feature follows a Gaussian shape.

Intraband absorption feature refers herein to intraband and/or plasmonic absorption feature.

According to one embodiment, the shape of the intraband absorption feature follows a Lorentzian shape.

According to one embodiment, the first optically active region presents an intraband absorption feature ranging from 1.7 to 12 μm.

According to one embodiment, the first optically active region presents an intraband absorption feature in the near infrared range.

According to one embodiment, the first optically active region presents an intraband absorption feature in the short wave infrared range, i.e. from 0.8 to 2.5 μm.

According to one embodiment, the first optically active region presents an intraband absorption feature in the mid wave infrared range, i.e. from 3 to 5 μm.

According to one embodiment, the first optically active region presents an intraband absorption feature in the long wave infrared range, i.e. from 8 to 12 μm.

According to one embodiment, the first optically active region presents an intraband absorption feature in the mid infrared, i.e. from 2.5 to 15 μm.

According to one embodiment, the first optically active region presents an intraband absorption feature in the far infrared, i.e. above 15 μm.

According to one embodiment, the first optically active region presents an intraband absorption feature in THz range, i.e. above 30 μm.

According to one embodiment, the first optically active region presents an intraband absorption feature above 400 nm, 450 nm, 500 nm, 550 nm, 600 nm, 650 nm, 700 nm, 750 nm, 800 nm, 850 nm, 900 nm, 950 nm, 1 μm, 2 μm, 3 μm, 4 μm, 5 μm, 6 μm, 7 μm, 8 μm, 9 μm, 10 μm, 11μm, 12μm, 13 μm, 14 μm, 15 μm, 16 μm, 17 μm, 18 μm, 19 μm, 20 μm, 25 μm, or 30 μm.

According to one embodiment, the first optically active region presents an optical absorption peak at a wavelength in a range from 1 μm to 2 μm, 3 μm, 4 μm, 5 μm, 6 μm, 7 μm, 8 μm, 9 μm, 10 μm, 11 μm, 12 μm, 13 μm, 14 μm, 15 μm, 16 μm, 17 μm, 18 μm, 19 μm, 20 μm, 21 μm, 22 μm, 23 μm, 24 μm, 25 μm, 26 μm, 27 μm, 28 μm, 29 μm, or 30 μm.

According to one embodiment, the first optically active region presents an intraband absorption feature peaked between 1 μm and 3 μm.

According to one embodiment, the first optically active region presents an intraband absorption feature peaked between 3 μm and 6 μm.

According to one embodiment, the first optically active region presents an intraband absorption feature peaked between 8 μm and 12μm.

According to one embodiment, the first optically active region presents an intraband absorption feature with a full width at half maximum of less than 2000 cm⁻¹, 1900 cm⁻¹, 1800 cm⁻¹, 1700 cm⁻¹, 1600 cm⁻¹, 1500 cm⁻¹, 1400 cm⁻¹, 1300 cm⁻¹, 1200 cm⁻¹, 1100 cm⁻¹, 1000 cm⁻¹, 900 cm⁻¹, 800 cm⁻¹, 700 cm⁻¹, 600 cm⁻¹, 500 cm⁻¹, 400 cm⁻¹, 300 cm⁻¹, 200 cm⁻¹, 100 cm⁻¹, or 50 cm⁻¹.

According to one embodiment, the first optically active region has an absorption coefficient between 100 and 500 000 cm⁻¹, preferably between 1000 and 10 000 cm⁻¹.

According to one embodiment, the intraband absorption feature has an energy between 1.2 eV and 50 meV, preferably 0.8 eV and 100 meV, more preferably between 0.5 eV and 50 meV.

According to one embodiment, the intraband absorption feature presents a linewidth below 5000 cm⁻¹, preferably below 3000 cm⁻¹, more preferably below 1500 cm⁻¹.

According to one embodiment, the intraband absorption feature presents a ratio of the linewidth over the energy of the intraband transition below 200%, preferably below 100%, more preferably below 50%.

According to one embodiment, the first optically active region presents a photoluminescence peak at a wavelength in a range from 1 μm to 30 μm.

According to one embodiment, the first optically active region presents a photoluminescence peak at a wavelength in a range from 1 μm, 2 μm, 3 μm, 4 μm, 5 μm, 6 μm, 7 μm, 8 μm, 9 μm, 10 μm, 11μm, 12μm, 13 μm, 14 μm, 15 μm, 16 μm, 17 μm, 18 μm, 19 μm, 20 μm, 21 μm, 22 μm, 23 μm, 24 μm, 25 μm, 26 μm, 27 μm, 28 μm, 29 μm, or 30 μm.

According to one embodiment, the first optically active region presents emission spectra with at least one emission peak having a full width at half maximum of less than 2000 cm⁻¹, 1900 cm⁻¹, 1800 cm⁻¹, 1700 cm⁻¹, 1600 cm⁻¹, 1500 cm⁻¹, 1400 cm⁻¹, 1300 cm⁻¹, 1200 cm⁻¹, 1100 cm⁻¹, 1000 cm⁻¹, 900 cm⁻¹, 800 cm⁻¹, 700 cm⁻¹, 600 cm⁻¹, 500 cm⁻¹, 400 cm⁻¹, 300 cm⁻¹, 200 cm⁻¹, 100 cm⁻¹ or 50 cm⁻¹.

The first optically active region being a nanocrystal will be referred as the first optically active nanocrystal hereafter.

According to one embodiment, the first optically active region is a colloidal nanocrystal.

According to one embodiment, the first optically active nanocrystal has a cation rich surface.

According to one embodiment, the first optically active nanocrystal has an anion rich surface.

According to one embodiment, said first optically active nanocrystal has an average size ranging from 1 nm to 1 μm, preferably between 3 nm to 50 nm, more preferably between 3 nm and 20 nm.

According to one embodiment, the first optically active nanocrystal has an average size of at least 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 55 nm, 60 nm, 65 nm, 70 nm, 75 nm, 80 nm, 85 nm, 90 nm, 95 nm, 100 nm, 105 nm, 110 nm, 115 nm, 120 nm, 125 nm, 130 nm, 135 nm, 140 nm, 145 nm, 150 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, or 1 μm.

According to one embodiment, the largest dimension of the first optically active nanocrystal is at least 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 105 nm, 110 nm, 115 nm, 120 nm, 125 nm, 130 nm, 135 nm, 140 nm, 145 nm, 150 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, or 1 μm.

According to one embodiment, the smallest dimension of the first optically active nanocrystal is at least 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 30 nm, 40 nm, 50 nm, 60 nm, 70 nm, 80 nm, 90 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, or 1 μm.

According to one embodiment, the smallest dimension of the first optically active nanocrystal is smaller than the largest dimension of said nanocrystals by a factor (aspect ratio) of at least 1.5; at least 2; at least 2.5; at least 3; at least 3.5; at least 4; at least 4.5; at least 5; at least 5.5; at least 6; at least 6.5; at least 7; at least 7.5; at least 8; at least 8.5; at least 9; at least 9.5; at least 10; at least 10.5; at least 11; at least 11.5; at least 12; at least 12.5; at least 13; at least 13.5; at least 14; at least 14.5; at least 15; at least 15.5; at least 16; at least 16.5; at least 17; at least 17.5; at least 18; at least 18.5; at least 19; at least 19.5; at least 20; at least 25; at least 30; at least 35; at least 40; at least 45; at least 50; at least 55; at least 60; at least 65; at least 70; at least 75; at least 80; at least 85; at least 90; at least 95; at least 100, at least 150, at least 200, at least 250, at least 300, at least 350, at least 400, at least 450, at least 500, at least 550, at least 600, at least 650, at least 700, at least 750, at least 800, at least 850, at least 900, at least 950, or at least 1000.

According to one embodiment, in a statistical set of first optically active nanocrystals, said nanocrystals are polydisperse.

According to one embodiment, in a statistical set of first optically active nanocrystals, said nanocrystals are monodisperse.

According to one embodiment, in a statistical set of first optically active nanocrystals, said nanocrystals have a narrow size distribution.

According to one embodiment, the size distribution for the average size of a statistical set of first optically active nanocrystals is inferior than 1%, 2%, 3%, 4%, 5%, 6%, 7%, 8%, 9%, 10%, 15%, 20%, 25%, 30%, 35%, or 40% of said average size.

According to one embodiment, the size distribution for the smallest dimension of a statistical set of first optically active nanocrystals is inferior than 1%, 2%, 3%, 4%, 5%, 6%, 7%, 8%, 9%, 10%, 15%, 20%, 25%, 30%, 35%, or 40% of said smallest dimension.

According to one embodiment, the size distribution for the largest dimension of a statistical set of first optically active nanocrystals inferior than 1%, 2%, 3%, 4%, 5%, 6%, 7%, 8%, 9%, 10%, 15%, 20%, 25%, 30%, 35%, or 40% of said largest dimension.

According to one embodiment, the first optically active nanocrystal has an isotropic shape.

According to one embodiment, the first optically active nanocrystal has an anisotropic shape.

According to one embodiment, the first optically active nanocrystal has a 0D, 1D or 2D dimension.

In one embodiment, examples of shape of first optically active nanocrystal include but are not limited to: quantum dots, sheet, rod, platelet, plate, prism, wall, disk, nanoparticle, wire, tube, tetrapod, ribbon, belt, needle, cube, ball, coil, cone, piller, flower, sphere, faceted sphere, polyhedron, bar, monopod, bipod, tripod, star, octopod, snowflake, thorn, hemisphere, urchin, filamentous nanoparticle, biconcave discoid, worm, tree, dendrite, necklace, chain, plate triangle, square, pentagon, hexagon, ring, tetrahedron, truncated tetrahedron, or combination thereof.

According to one embodiment, the first optically active nanocrystal is a quantum dot.

According to one embodiment, the first optically active nanocrystal has a spherical shape.

According to one embodiment, the first optically active nanocrystal has a diameter ranging from 20 nm to 10 μm, preferably between 20 nm to 2 μm, more preferably between 20 nm and 1 μm.

According to one embodiment, the first optically active nanocrystal have a diameter of at least 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 30 nm, 40 nm, 50 nm, 60 nm, 70 nm, 80 nm, 90 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.1 μm, 1.2 μm, 1.3 μm, 1.4 μm, 1.5 μm, 1.6 μm, 1.7 μm, 1.8 μm, 1.9 μm, 2 μm, 2.1 μm, 2.2 μm, 2.3 μm, 2.4 μm, 2.5 μm, 2.6 μm, 2.7 μm, 2.8 μm, 2.9 μm, 3 μm, 3.1 μm, 3.2 μm, 3.3 μm, 3.4 μm, 3.5 μm, 3.6 μm, 3.7 μm, 3.8 μm, 3.9 μm, 4 μm, 4.1 μm, 4.2 μm, 4.3 μm, 4.4 μm, 4.5 μm, 4.6 μm, 4.7 μm, 4.8 μm, 4.9 μm, 5 μm, 5.1μm, 5.2 μm, 5.3 μm, 5.4 μm, 5.5 μm, 5.6 μm, 5.7 μm, 5.8 μm, 5.9 μm, 6 μm, 6.1 μm, 6.2 μm, 6.3 μm, 6.4 μm, 6.5 μm, 6.6 μm, 6.7 μm, 6.8 μm, 6.9 μm, 7 μm, 7.1 μm, 7.2 μm, 7.3 μm, 7.4 μm, 7.5 μm, 7.6 μm, 7.7 μm, 7.8 μm, 7.9 μm, 8 μm, 8.1 μm, 8.2 μm, 8.3 μm, 8.4 μm, 8.5 μm, 8.6 μm, 8.7 μm, 8.8 μm, 8.9 μm, 9 μm, 9.1 μm, 9.2 μm, 9.3 μm, 9.4 μm, 9.5 μm, 9.6 μm, 9.7 μm, 9.8 μm, 9.9 μm, or 10 μm.

According to one embodiment, the first optically active nanocrystal is faceted.

According to one embodiment, the first optically active nanocrystal comprises at least one facet.

According to one embodiment, the first optically active nanocrystal is not faceted.

According to one embodiment, in a statistical set of first optically active nanocrystals, said nanocrystals are not aggregated. This embodiment prevents the loss of colloidal stability.

According to one embodiment, in a statistical set of first optically active nanocrystals, said nanocrystals are aggregated.

According to one embodiment, the first optically active nanocrystal is a crystalline nanoparticle.

According to one embodiment, the semiconductor material has a doping level below 10¹⁸ cm⁻³.

According to one embodiment, the semiconductor material has a doping level below 10¹⁷ cm⁻³.

According to one embodiment, the semiconductor material has a doping level inferior to the doping level of the first material.

According to one embodiment, the semiconductor material is doped by the introduction of extrinsic impurities.

According to one embodiment, the doping of the semiconductor material can be tuned while tuning the surface chemistry.

According to one embodiment, the semiconductor material is not doped.

According to one embodiment, the semiconductor material is a narrow bandgap semiconductor material.

According to one embodiment, the semiconductor material is selected from N_{y}Zₙ, wherein N is a metal selected from Hg, Pb, Ag, Bi, Sn, Ga, In, Cd, Zn, Sb or a mixture thereof, and Z is selected from S, Se, Te, O, As, P or a mixture thereof, and wherein y and n are independently a decimal number from 0 to 5 and are not simultaneously equal to 0; metal oxides; silicon; germanium; perovskites; hybrid organic-inorganic perovskites; or a mixture thereof.

According to one embodiment, the semiconductor material is selected from N_{y}Zₙ, wherein N is a metal selected from Hg, Pb, Ag, Bi, Sn, Ga, In, Zn, Sb or a mixture thereof, and Z is selected from S, Se, Te, O, As, P or a mixture thereof, and wherein y and n are independently a decimal number from 0 to 5 and are not simultaneously equal to 0; metal oxides; silicon; germanium; perovskites; hybrid organic-inorganic perovskites; or a mixture thereof.

According to one embodiment, N is selected from the group consisting of Ia, IIa, IIIa, IVa, IVb, IV, Va, Vb, V, or a mixture thereof.

According to one embodiment, A is selected from the group consisting of Va, VIa, or a mixture thereof.

According to one embodiment, the semiconductor material N_{y}Zₙ is selected from the group consisting of group IV, group IIIA-VA, group IIA-VIA, group IIIA-VIA, group IA-IIIA-VIA, group IIA-VA, group IVA-VIA, group VIB-VIA, group VB-VIA, group IVB-VIA or a mixture thereof.

According to one embodiment, the semiconductor material is selected from metal chalcogenide, metal oxide, silicon, germanium, perovskite, hybrid organic-inorganic perovskite, or a mixture thereof.

According to one embodiment, examples of metal chalcogenides include but are not limited to: mercury chalcogenides, zinc chalcogenides, tin chalcogenides, silver chalcogenides, lead chalcogenides, bismuth chalcogenides, antimony chalcogenides, cadmium chalcogenides or a mixture thereof.

According to one embodiment, examples of metal chalcogenides include but are not limited to: mercury chalcogenides, zinc chalcogenides, tin chalcogenides, silver chalcogenides, lead chalcogenides, bismuth chalcogenides, antimony chalcogenides, or a mixture thereof.

According to one embodiment, examples of mercury chalcogenides include but are not limited to: HgS, HgSe, HgTe, HgₓCd₁₋ₓTe wherein x is a real number strictly included between 0 and 1, or a mixture thereof.

According to one embodiment, the semiconductor material comprises HgTe. According to one embodiment, the semiconductor material consists of HgTe.

According to one embodiment, examples of zinc chalcogenides include but are not limited to: ZnS, ZnSe, or a mixture thereof.

According to one embodiment, examples of tin chalcogenides include but are not limited to SnTe, SnS, SnS₂, SnSe, or a mixture thereof.

According to one embodiment, examples of silver chalcogenides include but are not limited to: Ag₂S, Ag₂Se, Ag₂Te, or a mixture thereof.

According to one embodiment, examples of lead chalcogenides include but are not limited to: PbS, PbSe, PbTe, or a mixture thereof.

According to one embodiment, examples of bismuth chalcogenides include but are not limited to: Bi₂S₃, Bi₂Se₃, Bi₂Te₃, or a mixture thereof.

According to one embodiment, examples of antimony chalcogenides include but are not limited to: Sb₂S₃, Sb₂Se₃, Sb₂Te₃, or a mixture thereof.

According to one embodiment, examples of cadmium chalcogenides include but are not limited to: CdS, CdSe, CdTe, or a mixture thereof.

According to one embodiment, the semiconductor material comprises InP, GaAs, or a mixture thereof.

According to one embodiment, N is selected from the group consisting of Hg or a mixture of Hg and at least one of Pb, Ag, Sn, Cd, Bi, or Sb.

According to one embodiment, examples of metal chalcogenides include but are not limited to: HgS, HgSe, HgTe, HgₓCd₁₋ₓTe wherein x is a real number strictly included between 0 and 1, PbS, PbSe, PbTe, ZnS, ZnSe, CdS, CdSe, CdTe, Bi₂S₃, Bi₂Se₃, Bi₂Te₃, SnS, SnS₂, SnTe, SnSe, Sb₂S₃, Sb₂Se₃, Sb₂Te₃, Ag₂S, Ag₂Se, Ag₂Te or alloys, or mixture thereof.

According to one embodiment, examples of metal chalcogenides include but are not limited to: HgS, HgSe, HgTe, HgₓCd₁₋ₓTe wherein x is a real number strictly included between 0 and 1, PbS, PbSe, PbTe, ZnS, ZnSe, Bi₂S₃, Bi₂Se₃, Bi₂Te₃, SnS, SnS₂, SnTe, SnSe, Sb₂S₃, Sb₂Se₃, Sb₂Te₃, Ag₂S, Ag₂Se, Ag₂Te or alloys, or mixture thereof.

According to one embodiment, examples of metal oxides include but are not limited to: zinc oxide ZnO, Indium oxide In₂O₃, or a mixture thereof.

According to one embodiment, examples of perovskites include but are not limited to: CsPbBr₃, CsPbCl₃, CsPbI₃, or a mixture thereof.

According to one embodiment, examples of semiconductor material include but are not limited to: HgS, HgSe, HgTe, HgₓCd₁₋ₓTe wherein x is a real number strictly included between 0 and 1, ZnS, ZnSe, SnTe, SnS, SnS₂, SnSe, Ag₂S, Ag₂Se, Ag₂Te, PbS, PbSe, PbTe, Bi₂S₃, Bi₂Se₃, Bi₂Te₃, Sb₂S₃, Sb₂Se₃, Sb₂Te₃, CdS, CdSe, CdTe, InP, GaAs, ZnO, In₂O₃, CsPbBr₃, CsPbCl₃, CsPbI₃, silicon, germanium, alloys, or a mixture thereof.

According to one embodiment, the semiconductor material does not comprise CdSe, CdS, CdTe, or a mixture thereof.

According to one embodiment, examples of semiconductor material include but are not limited to: HgS, HgSe, HgTe, HgₓCd₁₋ₓTe wherein x is a real number strictly included between 0 and 1, ZnS, ZnSe, SnTe, SnS, SnS₂, SnSe, Ag₂S, Ag₂Se, Ag₂Te, PbS, PbSe, PbTe, Bi₂S₃, Bi₂Se₃, Bi₂Te₃, Sb₂S₃, Sb₂Se₃, Sb₂Te₃, InP, GaAs, ZnO, In2O₃, CsPbBr₃, CsPbCl₃, CsPbI₃, silicon, germanium, alloys, or a mixture thereof.

According to one embodiment, the semiconductor material is not a carbon derivative

According to one embodiment, the semiconductor material is a carbon derivative such as graphene

According to one embodiment, the semiconductor material is a 2D transistion metal dichalcogenides such as MoS₂.

According to one embodiment, the semiconductor material is a transport material.

According to one embodiment, the absorption of the second optically inactive region is a combination of interband, intraband and/or plasmonic effect.

According to one embodiment, the second optically inactive region presents an interband absorption feature.

According to one embodiment, the second optically inactive region presents an interband edge with a higher energy that the intraband absorption feature of the first optically active region.

FIG. 18 illustrates the ratio of the electronic mobility over the hole mobility for HgSe/HgTe heterostructure with different amount of the two materials.

According to one embodiment, the second optically inactive region presents an interband absorption feature ranging from 1.7 to 12 μm.

According to one embodiment, the second optically inactive region presents an interband absorption feature in the near infrared range.

According to one embodiment, the second optically inactive region presents an interband absorption feature in the short wave infrared range, i.e. from 0.8 to 2.5 μm.

According to one embodiment, the second optically inactive region presents an interband absorption feature in the mid wave infrared range, i.e. from 3 to 5 μm.

According to one embodiment, the second optically inactive region presents an interband absorption feature in the long wave infrared range, i.e. from 8 to 12 μm.

According to one embodiment, the second optically inactive region presents an interband absorption feature in the mid infrared, i.e. from 2.5 to 15 μm.

According to one embodiment, the second optically inactive region presents an interband absorption feature in the far infrared, i.e. above 15 μm.

According to one embodiment, the second optically inactive region presents an interband absorption feature in THz range, i.e. above 30 μm.

According to one embodiment, the second optically inactive region presents an interband absorption feature above 400 nm, 450 nm, 500 nm, 550 nm, 600 nm, 650 nm, 700 nm, 750 nm, 800 nm, 850 nm, 900 nm, 950 nm, 1 μm, 2 μm, 3 μm, 4 μm, 5 μm, 6 μm, 7 μm, 8 μm, 9 μm, 10 μm, 11 μm, 12 μm, 13 μm, 14 μm, 15 μm, 16 μm, 17 μm, 18 μm, 19 μm, 20 μm, 25 μm, or 30 μm.

According to one embodiment, the second optically inactive region presents an optical absorption peak at a wavelength in a range from 1 μm to 2 μm, 3 μm, 4 μm, 5 μm, 6 μm, 7 μm, 8 μm, 9 μm, 10 μm, 11 μm, 12 μm, 13 μm, 14 μm, 15 μm, 16 μm, 17 μm, 18 μm, 19 μm, 20 μm, 21 μm, 22 μm, 23 μm, 24 μm, 25 μm, 26 μm, 27 μm, 28 μm, 29 μm, or 30 μm.

According to one embodiment, the second optically inactive region presents an interband absorption feature peaked between 1 μm and 3 μm.

According to one embodiment, the second optically inactive region presents an interband absorption feature peaked between 3 μm and 6 μm.

According to one embodiment, the second optically inactive region presents an interband absorption feature peaked between 8 μm and 12μm.

According to one embodiment, the second optically inactive region presents an interband absorption feature with a full width at half maximum of less than 2000 cm⁻¹, 1900 cm⁻¹, 1800 cm⁻¹, 1700 cm⁻¹, 1600 cm⁻¹, 1500 cm⁻¹, 1400 cm⁻¹, 1300 cm⁻¹, 1200 cm⁻¹, 1100 cm⁻¹, 1000 cm⁻¹, 900 cm⁻¹, 800 cm⁻¹, 700 cm⁻¹, 600 cm⁻¹, 500 cm⁻¹, 400 cm⁻¹, 300 cm⁻¹, 200 cm⁻¹, 100 cm⁻¹, or 50 cm⁻¹.

According to one embodiment, the second optically inactive region has an absorption coefficient between 100 and 500 000 cm⁻¹, preferably between 1000 and 10 000 cm⁻¹.

According to one embodiment, the interband absorption feature presents a linewidth below 5000 cm⁻¹, preferably below 3000 cm⁻¹, more preferably below 1500 cm⁻¹.

According to one embodiment, the second optically inactive region presents a photoluminescence peak at a wavelength in a range from 1 μm to 30 μm.

According to one embodiment, the second optically inactive region presents a photoluminescence peak at a wavelength in a range from 1 μm, 2 μm, 3 μm, 4 μm, 5 μm, 6 μm, 7 μm, 8 μm, 9 μm, 10 μm, 11μm, 12μm, 13 μm, 14 μm, 15 μm, 16 μm, 17 μm, 18 μm, 19 μm, 20 μm, 21 μm, 22 μm, 23 μm, 24 μm, 25 μm, 26 μm, 27 μm, 28 μm, 29 μm, or 30 μm.

According to one embodiment, the second optically inactive region presents emission spectra with at least one emission peak having a full width at half maximum of less than 2000 cm⁻¹, 1900 cm⁻¹, 1800 cm⁻¹, 1700 cm⁻¹, 1600 cm⁻¹, 1500 cm⁻¹, 1400 cm⁻¹, 1300 cm⁻¹, 1200 cm⁻¹, 1100 cm⁻¹, 1000 cm⁻¹, 900 cm⁻¹, 800 cm⁻¹, 700 cm⁻¹, 600 cm⁻¹, 500 cm⁻¹, 400 cm⁻¹, 300 cm⁻¹, 200 cm⁻¹, 100 cm⁻¹ or 50 cm⁻¹.

According to one embodiment, the semiconductor material has higher carrier mobility than the first material.

According to one embodiment, the semiconductor material has a carrier mobility above 10⁻⁶ cm²V⁻¹s⁻¹, preferably above 10⁻³ cm²V⁻¹s⁻¹, more preferably above 10⁻¹ cm²V⁻¹s⁻¹.

According to one embodiment, the semiconductor material has a carrier mobility above 10⁻⁴ cm²V⁻¹s⁻¹, preferably above 10⁻² cm²V⁻¹s⁻¹, more preferably above 1 cm²V⁻¹s⁻¹.

According to one embodiment, the semiconductor material has a carrier mobility above 1 cm²V⁻¹s⁻¹, preferably above 10 cm²V⁻¹s⁻¹, more preferably above 100 cm²V⁻¹s⁻¹.

In one embodiment illustrated in FIG. 16A-B and FIG. 17A-F, the semiconductor material has a ratio of electron to hole mobility smaller than the one of the first material.

In one embodiment illustrated in FIG. 20, the semiconductor material has a transport activation energy higher that the one of the first material.

In one embodiment, the semiconductor material has a transport activation energy higher than 50 meV, preferably above 75 meV, more preferably above 100 meV.

In one embodiment, the semiconductor material has a transport activation energy as large as half its interband gap.

In one embodiment, the semiconductor material has a transport activation energy larger than the intraband transition energy of the first material.

In one embodiment illustrated in FIG. 14A-E, the semiconductor material has a type I band alignment with respect to the first material.

In one embodiment illustrated in FIG. 14A-E, the semiconductor material has a quasi type II band alignment with respect to the first material.

In one embodiment illustrated in FIG. 14A-E, the semiconductor material has a type II band alignment with respect to the first material.

In one embodiment, the semiconductor material has a type III band alignment with respect to the first material.

According to one embodiment, the second optically inactive region is a nanocrystal, it will be referred as the second optically inactive nanocrystal hereafter.

According to one embodiment, the second optically inactive region comprises a plurality of nanocrystals.

According to one embodiment, the second optically inactive region comprises a colloidal nanocrystal.

According to one embodiment, the second optically inactive nanocrystal has a cation rich surface.

According to one embodiment, the second optically inactive nanocrystal has an anion rich surface.

According to one embodiment, said second optically inactive nanocrystal has an average size ranging from 1 nm to 1 μm, preferably between 3 nm to 50 nm, more preferably between 3 nm and 20 nm.

According to one embodiment, the second optically inactive nanocrystal has an average size of at least 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 55 nm, 60 nm, 65 nm, 70 nm, 75 nm, 80 nm, 85 nm, 90 nm, 95 nm, 100 nm, 105 nm, 110 nm, 115 nm, 120 nm, 125 nm, 130 nm, 135 nm, 140 nm, 145 nm, 150 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, or 1 μm.

According to one embodiment, the largest dimension of the second optically inactive nanocrystal is at least 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 105 nm, 110 nm, 115 nm, 120 nm, 125 nm, 130 nm, 135 nm, 140 nm, 145 nm, 150 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, or 1 μm.

According to one embodiment, the smallest dimension of the second optically inactive nanocrystal is at least 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 30 nm, 40 nm, 50 nm, 60 nm, 70 nm, 80 nm, 90 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, or 1 μm.

According to one embodiment, the smallest dimension of the second optically inactive nanocrystal is smaller than the largest dimension of said nanocrystals by a factor (aspect ratio) of at least 1.5; at least 2; at least 2.5; at least 3; at least 3.5; at least 4; at least 4.5; at least 5; at least 5.5; at least 6; at least 6.5; at least 7; at least 7.5; at least 8; at least 8.5; at least 9; at least 9.5; at least 10; at least 10.5; at least 11; at least 11.5; at least 12; at least 12.5; at least 13; at least 13.5; at least 14; at least 14.5; at least 15; at least 15.5; at least 16; at least 16.5; at least 17; at least 17.5; at least 18; at least 18.5; at least 19; at least 19.5; at least 20; at least 25; at least 30; at least 35; at least 40; at least 45; at least 50; at least 55; at least 60; at least 65; at least 70; at least 75; at least 80; at least 85; at least 90; at least 95; at least 100, at least 150, at least 200, at least 250, at least 300, at least 350, at least 400, at least 450, at least 500, at least 550, at least 600, at least 650, at least 700, at least 750, at least 800, at least 850, at least 900, at least 950, or at least 1000.

According to one embodiment, in a statistical set of second optically inactive nanocrystals, said nanocrystals are polydisperse.

According to one embodiment, in a statistical set of second optically inactive nanocrystals, said nanocrystals are monodisperse.

According to one embodiment, in a statistical set of second optically inactive nanocrystals, said nanocrystals have a narrow size distribution.

According to one embodiment, the size distribution for the average size of a statistical set of second optically inactive nanocrystals is inferior than 1%, 2%, 3%, 4%, 5%, 6%, 7%, 8%, 9%, 10%, 15%, 20%, 25%, 30%, 35%, or 40% of said average size.

According to one embodiment, the size distribution for the smallest dimension of a statistical set of second optically inactive nanocrystals is inferior than 1%, 2%, 3%, 4%, 5%, 6%, 7%, 8%, 9%, 10%, 15%, 20%, 25%, 30%, 35%, or 40% of said smallest dimension.

According to one embodiment, the size distribution for the largest dimension of a statistical set of second optically inactive nanocrystals inferior than 1%, 2%, 3%, 4%, 5%, 6%, 7%, 8%, 9%, 10%, 15%, 20%, 25%, 30%, 35%, or 40% of said largest dimension.

According to one embodiment, the second optically inactive nanocrystal has an isotropic shape.

According to one embodiment, the second optically inactive nanocrystal has an anisotropic shape.

According to one embodiment, the second optically inactive nanocrystal has a 0D, 1D or 2D dimension.

In one embodiment, examples of shape of second optically inactive nanocrystal include but are not limited to: quantum dots, sheet, rod, platelet, plate, prism, wall, disk, nanoparticle, wire, tube, tetrapod, ribbon, belt, needle, cube, ball, coil, cone, piller, flower, sphere, faceted sphere, polyhedron, bar, monopod, bipod, tripod, star, octopod, snowflake, thorn, hemisphere, urchin, filamentous nanoparticle, biconcave discoid, worm, tree, dendrite, necklace, chain, plate triangle, square, pentagon, hexagon, ring, tetrahedron, truncated tetrahedron, or combination thereof.

According to one embodiment, the second optically inactive nanocrystal is a quantum dot.

According to one embodiment, the second optically inactive nanocrystal has a spherical shape.

According to one embodiment, the second optically inactive nanocrystal has a diameter ranging from 20 nm to 10 μm, preferably between 20 nm to 2 μm, more preferably between 20 nm and 1 μm.

According to one embodiment, the second optically inactive nanocrystal have a diameter of at least 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 30 nm, 40 nm, 50 nm, 60 nm, 70 nm, 80 nm, 90 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.1 μm, 1.2 μm, 1.3 μm, 1.4 μm, 1.5 μm, 1.6 μm, 1.7 μm, 1.8 μm, 1.9 μm, 2 μm, 2.1 μm, 2.2 μm, 2.3 μm, 2.4 μm, 2.5 μm, 2.6 μm, 2.7 μm, 2.8 μm, 2.9 μm, 3 μm, 3.1 μm, 3.2 μm, 3.3 μm, 3.4 μm, 3.5 μm, 3.6 μm, 3.7 μm, 3.8 μm, 3.9 μm, 4 μm, 4.1 μm, 4.2 μm, 4.3 μm, 4.4 μm, 4.5 μm, 4.6 μm, 4.7 μm, 4.8 μm, 4.9 μm, 5 μm, 5.1μm, 5.2 μm, 5.3 μm, 5.4 μm, 5.5 μm, 5.6 μm, 5.7 μm, 5.8 μm, 5.9 μm, 6 μm, 6.1 μm, 6.2 μm, 6.3 μm, 6.4 μm, 6.5 μm, 6.6 μm, 6.7 μm, 6.8 μm, 6.9 μm, 7 μm, 7.1 μm, 7.2 μm, 7.3 μm, 7.4 μm, 7.5 μm, 7.6 μm, 7.7 μm, 7.8 μm, 7.9 μm, 8 μm, 8.1 μm, 8.2 μm, 8.3 μm, 8.4 μm, 8.5 μm, 8.6 μm, 8.7 μm, 8.8 μm, 8.9 μm, 9 μm, 9.1 μm, 9.2 μm, 9.3 μm, 9.4 μm, 9.5 μm, 9.6 μm, 9.7 μm, 9.8 μm, 9.9 μm, or 10 μm.

According to one embodiment, the second optically inactive nanocrystal is faceted.

According to one embodiment, the second optically inactive nanocrystal comprises at least one facet.

According to one embodiment, the second optically inactive nanocrystal is not faceted.

According to one embodiment, in a statistical set of second optically inactive nanocrystals, said nanocrystals are not aggregated. This embodiment prevents the loss of colloidal stability.

According to one embodiment, in a statistical set of second optically inactive nanocrystals, said nanocrystals are aggregated.

According to one embodiment, the second optically inactive nanocrystal is a crystalline nanoparticle.

According to one embodiment, the second optically inactive region is a matrix surrounding partially or totally the first optically active region.

According to one embodiment, the second optically inactive region is a film, referred hereafter as the second optically inactive film.

According to one embodiment, the second optically inactive film has a thickness from 1 nm to 1 mm, preferably from 3 nm to 100 μm, more preferably from 10 nm to 1 μm.

According to one embodiment, the second optically inactive film has a thickness of at least 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 30 nm, 40 nm, 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm

According to one embodiment, the second optically inactive film has an area from 100 nm² to 1 m², preferably from 1 μm² to 10 cm², more preferably from 50 μm² to 1 cm².

According to one embodiment, the second optically inactive film has an area of at least 100 nm², 200 nm², 300 nm², 400 nm², 500 nm², 600 nm², 700 nm², 800 nm², 900 nm², 1000 nm², 2000 nm², 3000 nm², 4000 nm², 5000 nm², 6000 nm², 7000 nm², 8000 nm², 9000 nm², 10000 nm², 20000 nm², 30000 nm², 40000 nm², 50000 nm², 60000 nm², 70000 nm², 80000 nm², 90000 nm², 100000 nm², 200000 nm², 300000 nm², 400000 nm², 500000 nm², 600000 nm², 700000 nm², 800000 nm², 900000 nm², 1 μm², 2 μm², 3μm², 4 μm², 5 μm², 6 μm², 7 μm², 8 μm², 9 μm², 10 μm², 20 μm², 30 μm², 40 μm², 50 μm², 60 μm², 70 μm², 80 μm², 90 μm², 100 μm², 200 μm², 300 μm², 400 μm², 500 μm², 600 μm², 700 μm², 800 μm², 900 μm², 1000 μm², 2000 μm², 3000 μm², 4000 μm², 5000 μm², 6000 μm², 7000 μm², 8000 μm², 9000 μm², 10000 μm², 20000 μm², 30000 μm², 40000 μm², 50000 μm², 60000 μm², 70000 μm², 80000 μm², 90000 μm², 100000 μm², 200000 μm², 300000 μm², 400000 μm², 500000 μm², 600000 μm², 700000 μm², 800000 μm², 900000 μm², 1000000 μm², 2000000 μm², 3000000 μm², 4000000 μm², 5000000 μm², 6000000 μm², 7000000 μm², 8000000 μm², 9000000 μm², 10000000 μm², 20000000 μm², 3000000 μm², 4000000 μm², 5000000 μm², 6000000 μm², 7000000 m², 8000000 m², 9000000 μm², 1 cm², 2 cm², 3 cm², 4 cm², 5 cm², 6 cm², 7 cm², 8 cm², 9 cm², 10 cm², 20 cm², 30 cm², 40 cm², 50 cm², 60 cm², 70 cm², 80 cm², 90 cm², 100 cm², 200 cm², 300 cm², 400 cm², 500 cm², 600 cm², 700 cm², 800 cm², 900 cm², 1000 cm², 2000 cm², 3000 cm², 4000 cm², 5000 cm², 6000 cm², 7000 cm², 8000 cm², 9000 cm², or 1 m².

According to one embodiment, the material is selected from HgSe/HgTe; HgS/HgTe; Ag₂Se/HgTe; Ag₂Se/PbS; Ag₂Se/PbSe; HgSe/PbS; HgS/PbS; HgSe/PbSe; HgS/PbSe; HgSe/CsPbI₃; HgSe/CsPbCl₃; HgSe/CsPbBr₃; HgS/CsPbI₃; HgS/CsPbCl₃; HgS/CsPbBr₃; Ag₂Se/CsPbI₃; Ag₂Se/CsPbCl₃; Ag₂Se/CsPbBr₃; HgS/CdS; HgSe/CdSe; doped Si/HgTe; doped Ge/HgTe; doped Si/PbS; doped Ge/PbS; doped ZnO/HgTe; doped ZnO/PbS; doped ZnO/ZnO; doped In2O3/HgTe; doped In2O3/PbS; doped Si/Si; doped Ge/Ge; doped ZnO/Si; doped In₂O₃/Si; doped Si/ZnO; or a mixture thereof.

According to one embodiment, the material is selected from HgSe/HgTe; HgS/HgTe; Ag₂Se/HgTe; Ag₂Se/PbS; Ag₂Se/PbSe; HgSe/PbS; HgS/PbS; HgSe/PbSe; HgS/PbSe; HgSe/CsPbI₃; HgSe/CsPbCl₃; HgSe/CsPbBr₃; HgS/CsPbI₃; HgS/CsPbCl₃; HgS/CsPbBr₃; Ag₂Se/CsPbI₃; Ag₂Se/CsPbCl₃; Ag₂Se/CsPbBr₃; doped Si/HgTe; doped Ge/HgTe; doped Si/PbS; doped Ge/PbS; doped ZnO/HgTe; doped ZnO/PbS; doped ZnO/ZnO; doped In₂O₃/HgTe; doped In₂O₃/PbS; doped Si/Si; doped Ge/Ge; doped ZnO/Si; doped In₂O₃/Si; doped Si/ZnO; or a mixture thereof.

According to one embodiment, the material does not comprise or does not consist of HgTe/HgSe.

According to one embodiment, the material does not comprise cadmium.

According to one embodiment, the material comprises 40% in weight of the semiconductor material of the second optically inactive region.

According to one embodiment, the material comprises above 50% in weight of the semiconductor material of the second optically inactive region.

According to one embodiment, the material comprises above 60% in weight of the semiconductor material of the second optically inactive region.

According to one embodiment, the material comprises above 70% in weight of the semiconductor material of the second optically inactive region.

According to one embodiment, the material comprises above 80% in weight of the semiconductor material of the second optically inactive region.

According to one embodiment, the material comprises above 90% in weight of the semiconductor material of the second optically inactive region.

According to one embodiment illustrated in FIG. 19A-C and FIG. 20, the material is less doped than the first material.

According to one embodiment illustrated in FIG. 21, the material has a transport activation energy higher than the one obtained from the first material.

According to one embodiment illustrated in FIG. 22A-C, the material has a photoconduction time response shorter than the one obtained from the first material.

According to one embodiment, the material presents exclusively an intraband absorption feature.

According to one embodiment, the material further presents an interband absorption feature.

According to one embodiment, the material does not present a plasmonic absorption feature.

According to one embodiment, the shape of the intraband absorption feature follows a Gaussian shape.

According to one embodiment, the shape of the intraband absorption feature follows a Lorentzian shape.

According to one embodiment, the material presents an intraband absorption feature in a range from 0.4 μm to 50 μm, or from 0.8 μm to 50 μm.

According to one embodiment, the material presents an intraband absorption feature in a range from 0.4 μm to 30 μm, or from 0.8 μm to 30 μm.

According to one embodiment, the material presents an intraband absorption feature in a range from 0.8 μm to 12 μm.

According to one embodiment, the material presents an intraband absorption feature in a range from 1.7 μm to 12 μm.

According to one embodiment, the material further presents an interband absorption feature in a range from 1.7 μm to 12 μm.

According to one embodiment, the material presents an absorption feature in the near infrared range.

According to one embodiment, the material presents an absorption feature in the short wave infrared range, i.e. from 0.8 to 2.5 μm.

According to one embodiment, the material presents an absorption feature in the mid wave infrared range, i.e. from 3 to 5 μm.

According to one embodiment, the material presents an absorption feature in the long wave infrared range, i.e. from 8 to 12 μm.

According to one embodiment, the material presents an absorption feature in the mid infrared, i.e. from 2.5 to 15 μm.

According to one embodiment, the material presents an absorption feature in the far infrared, i.e. above 15 μm.

According to one embodiment, the material presents an absorption feature in THz range, i.e. above 30 μm.

According to one embodiment, the material presents an absorption feature above 400 nm, 450 nm, 500 nm, 550 nm, 600 nm, 650 nm, 700 nm, 750 nm, 800 nm, 850 nm, 900 nm, 950 nm, 1 μm, 2 μm, 3 μm, 4 μm, 5 μm, 6 μm, 7 μm, 8 μm, 9 μm, 10 μm, 11 μm, 12 μm, 13 μm, 14 μm, 15 μm, 16 μm, 17 μm, 18 μm, 19 μm, 20 μm, 25 μm, or 30 μm.

According to one embodiment, the material presents an optical absorption peak at a wavelength in a range from 1 μm to 2 μm, 3 μm, 4 μm, 5 μm, 6 μm, 7 μm, 8 μm, 9 μm, 10 μm, 11 μm, 12 μm, 13 μm, 14 μm, 15 μm, 16 μm, 17 μm, 18 μm, 19 μm, 20 μm, 21 μm, 22 μm, 23 μm, 24 μm, 25 μm, 26 μm, 27 μm, 28 μm, 29 μm, or 30 μm.

According to one embodiment, the material presents an absorption feature peaked between 1 μm and 3 μm.

According to one embodiment, the material presents an absorption feature peaked between 3 μm and 6 μm.

According to one embodiment, the material presents an absorption feature peaked between 8 μm and 12 μm.

According to one embodiment, the material presents an absorption feature with a full width at half maximum of less than 2000 cm⁻¹, 1900 cm⁻¹, 1800 cm⁻¹, 1700 cm⁻¹, 1600 cm⁻¹, 1500 cm⁻¹, 1400 cm⁻¹, 1300 cm⁻¹, 1200 cm⁻¹, 1100 cm⁻¹, 1000 cm⁻¹, 900 cm⁻¹, 800 cm⁻¹, 700 cm⁻¹, 600 cm⁻¹, 500 cm⁻¹, 400 cm⁻¹, 300 cm⁻¹, 200 cm⁻¹, 100 cm⁻¹, or 50 cm⁻¹.

According to one embodiment, the material has an absorption coefficient between 100 and 500 000 cm⁻¹, preferably between 1000 and 10 000 cm⁻¹.

According to one embodiment, the absorption feature of the material has an energy between 1.2 eV and 50 meV, preferably 0.8 eV and 100 meV, more preferably between 0.5 eV and 50 meV.

According to one embodiment, the absorption feature of the material presents a linewidth below 5000 cm⁻¹, preferably below 3000 cm⁻¹, more preferably below 1500 cm⁻¹.

According to one embodiment, the intraband absorption feature of the material presents a ratio of the linewidth over the energy of the intraband transition below 200%, preferably below 100%, more preferably below 50%.

According to one embodiment, the material presents a photoluminescence peak at a wavelength in a range from 1 μm to 30 μm.

According to one embodiment, the material presents a photoluminescence peak at a wavelength in a range from 1 μm, 2 μm, 3 μm, 4 μm, 5 μm, 6 μm, 7 μm, 8 μm, 9 μm, 10 μm, 11 μm, 12 μm, 13 μm, 14 μm, 15 μm, 16 μm, 17 μm, 18 μm, 19 μm, 20 μm, 21 μm, 22 μm, 23 μm, 24 μm, 25 μm, 26 μm, 27 μm, 28 μm, 29 μm, or 30 μm.

According to one embodiment, the material presents emission spectra with at least one emission peak having a full width at half maximum of less than 2000 cm⁻¹, 1900 cm⁻¹, 1800 cm⁻¹, 1700 cm⁻¹, 1600 cm⁻¹, 1500 cm⁻¹, 1400 cm⁻¹, 1300 cm⁻¹, 1200 cm⁻¹, 1100 cm⁻¹, 1000 cm⁻¹, 900 cm⁻¹, 800 cm⁻¹, 700 cm⁻¹, 600 cm⁻¹, 500 cm⁻¹, 400 cm⁻¹, 300 cm¹, 200 cm¹, 100 cm¹ or 50 cm¹.

According to one embodiment, the material is a heterostructure.

According to one embodiment illustrated in FIG. 12A-C and FIG. 15A-C, the material is a colloidal heterostructure.

According to one embodiment, the second optically inactive region is epitaxially connected to the first optically active region.

According to one embodiment, the second optically inactive region is not epitaxially connected to the first optically active region.

According to one embodiment, the second optically inactive region is not epitaxially connected to the first optically active region, however the distance between both regions is short enough to allow energy transfer.

According to one embodiment, the second optically inactive region is not epitaxially connected to the first optically active region, however the distance between both regions is short enough to allow energy transfer through dipole dipole interaction.

According to one embodiment, the second optically inactive region is not epitaxially connected to the first optically active region, however the distance between both regions is short enough to allow charge transfer.

According to one embodiment, the second optically inactive region is not epitaxially connected to the first optically active region, however a post synthesis step is conducted to increase their coupling.

According to one embodiment, the second optically inactive region is not epitaxially connected to the first optically active region, however a ligand exchange step is conducted to increase their coupling.

According to one embodiment, the material has a core/shell geometry. According to one embodiment, the material does not have a core/shell geometry. According to one embodiment, the material has a core/shell geometry, wherein the core is the first optically active region.

According to one embodiment, the material has a core/shell geometry, wherein the shell is the second optically inactive region.

According to one embodiment, the material has a core/shell geometry, wherein the core is the first optically active region and the shell is the second optically inactive region.

According to one embodiment, the material has a core/shell geometry, wherein the core is the second optically inactive region.

According to one embodiment, the material has a core/shell geometry, wherein the shell is the first optically active region.

According to one embodiment, the material has a core/shell geometry, wherein the core is the second optically inactive region and the shell is the first optically active region.

According to one embodiment, the material has a janus geometry, i.e. two epitaxially connected nanoparticles touching each other.

According to one embodiment, the material comprises at least one first optically active nanocrystal and at least one second optically inactive nanocrystal.

According to one embodiment, the material is a mixture of colloidal nanocrystals, i.e. a mixture of at least one first optically active nanocrystal and at least one second optically inactive nanocrystal.

According to one embodiment, the at least one first optically active nanocrystal and the at least one second optically inactive nanocrystal are in contact.

According to one embodiment, the at least one first optically active nanocrystal and the at least one second optically inactive nanocrystal are connected.

According to one embodiment, the material comprises second optically inactive nanocrystals at a level above 40% in number of the total nanocrystals.

According to one embodiment, the material comprises second optically inactive nanocrystals at a level above 50% in number of the total nanocrystals.

According to one embodiment, the material comprises second optically inactive nanocrystals at a level above 60% in number of the total nanocrystals.

According to one embodiment, the material comprises second optically inactive nanocrystals at a level above 70% in number of the total nanocrystals.

According to one embodiment, the material comprises second optically inactive nanocrystals at a level above 80% in number of the total nanocrystals.

According to one embodiment, the material comprises second optically inactive nanocrystals at a level above 90% in number of the total nanocrystals.

According to one embodiment, the material comprises second optically inactive nanocrystals at a level below 99% in number of the total nanocrystals.

According to one embodiment, the material is coated with ligands. In this embodiment, ligands may be inorganic ligands and/or organic ligands.

According to one embodiment, the ligand density of the material surface ranging from 0.01 ligand.nm⁻² to 100 ligands.nm⁻², preferably from 0.1 ligand.nm⁻² to 10 ligands.nm⁻².

According to one embodiment, the ratio between organic ligands and inorganic ligands of the material surface is ranging from 0.001 to 0.25, preferably from 0.001 to 0.2, more preferably from 0.001 to 0.1 or even more preferably from 0.001 to 0.01.

According to one embodiment, the material is coated with inorganic ligands.

According to one embodiment, the material is coated with at least one inorganic ligand.

According to one embodiment, examples of inorganic ligands include but are not limited to: S²⁻, HS⁻, Se²⁻, Te²⁻, OH⁻, BF₄⁻, PF₆⁻, Cl⁻, Br⁻, I⁻, As₂S₃, As₂Se₃, Sb₂S₃, As₂Te₃, Sb₂S₃, Sb₂Se₃, Sb₂Te₃, CdSe, CdTe SnS₂, AsS³⁺, LiS₂, FeS₂, Cu₂S or a mixture thereof.

According to one embodiment, the inorganic ligand is As₂Se₃.

According to one embodiment, the inorganic ligand density of the material surface ranges from 0.01 ligand.nm⁻² to 100 ligands.nm⁻², preferably from 0.1 ligand.nm⁻² to 10 ligands.nm⁻².

According to one embodiment, the material is coated with organic ligands.

According to one embodiment, the material is coated with at least one organic ligand.

According to one embodiment, the material is coated with an organic shell. In this embodiment, the organic shell may be made of organic ligands.

According to one embodiment, examples of organic ligands include but are not limited to: thiol, amine, carboxylic acid, phosphine, phosphine oxide, or mixture thereof.

According to one embodiment, examples of thiol include but are not limited to: methanethiol, ethanedithiol, propanethiol, octanethiol, dodecanethiol, octadecanethiol, decanethiol, or mixture thereof.

According to one embodiment, examples of amine include but are not limited to: propylamine, butylamine, heptadiamine, octylamine, oleylamine, dodecylamine, octadecylamine, tetradecylamine, aniline, 1,6-hexanediamine, or mixture thereof.

According to one embodiment, examples of carboxylic acid include but are not limited to: oleic acid, myristic acid, octanoic acid, 4-mercaptobenzoic acid, stearic acid, arachidic acid. Decanoic acid, butyric acid, ethanoic acid, methanoic acid, or mixture thereof.

According to one embodiment, examples of phosphine include but are not limited to: tributylphosphine, trioctylphosphine, phenylphosphine, diphenylphosphine or mixture thereof.

According to one embodiment, examples of phosphine oxide include but are not limited to: trioctylphosphine oxide.

According to one embodiment, the organic ligand density of the material surface ranges from 0.01 ligand.nm⁻² to 100 ligands.nm⁻², preferably from 0.1 ligand.nm⁻² to 10 ligands.nm⁻².

According to one embodiment, the material is a nanoparticle or nanocrystal, referred as nanoparticle hereafter.

According to one embodiment, the nanoparticle is a colloidal.

According to one embodiment, the nanoparticle has a cation rich surface. According to one embodiment, the nanoparticle has an anion rich surface.

According to one embodiment, said nanoparticle has an average size ranging from 1 nm to 1 μm, preferably between 3 nm to 50 nm, more preferably between 3 nm and 20 nm.

According to one embodiment, the nanoparticle has an average size of at least 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 55 nm, 60 nm, 65 nm, 70 nm, 75 nm, 80 nm, 85 nm, 90 nm, 95 nm, 100 nm, 105 nm, 110 nm, 115 nm, 120 nm, 125 nm, 130 nm, 135 nm, 140 nm, 145 nm, 150 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, or 1 μm.

According to one embodiment, the largest dimension of the nanoparticle is at least 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 105 nm, 110 nm, 115 nm, 120 nm, 125 nm, 130 nm, 135 nm, 140 nm, 145 nm, 150 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, or 1 μm.

According to one embodiment, the smallest dimension of the nanoparticle is at least 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 30 nm, 40 nm, 50 nm, 60 nm, 70 nm, 80 nm, 90 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, or 1 μm.

According to one embodiment, the smallest dimension of the nanoparticle is smaller than the largest dimension of said nanocrystals by a factor (aspect ratio) of at least 1.5; at least 2; at least 2.5; at least 3; at least 3.5; at least 4; at least 4.5; at least 5; at least 5.5; at least 6; at least 6.5; at least 7; at least 7.5; at least 8; at least 8.5; at least 9; at least 9.5; at least 10; at least 10.5; at least 11; at least 11.5; at least 12; at least 12.5; at least 13; at least 13.5; at least 14; at least 14.5; at least 15; at least 15.5; at least 16; at least 16.5; at least 17; at least 17.5; at least 18; at least 18.5; at least 19; at least 19.5; at least 20; at least 25; at least 30; at least 35; at least 40; at least 45; at least 50; at least 55; at least 60; at least 65; at least 70; at least 75; at least 80; at least 85; at least 90; at least 95; at least 100, at least 150, at least 200, at least 250, at least 300, at least 350, at least 400, at least 450, at least 500, at least 550, at least 600, at least 650, at least 700, at least 750, at least 800, at least 850, at least 900, at least 950, or at least 1000.

According to one embodiment, in a statistical set of nanoparticles, said nanoparticles are polydisperse.

According to one embodiment, in a statistical set of nanoparticles, said nanoparticles are monodisperse.

According to one embodiment, in a statistical set of nanoparticles, said nanoparticles have a narrow size distribution.

According to one embodiment, the size distribution for the average size of a statistical set of nanoparticles is inferior than 1%, 2%, 3%, 4%, 5%, 6%, 7%, 8%, 9%, 10%, 15%, 20%, 25%, 30%, 35%, or 40% of said average size.

According to one embodiment, the size distribution for the smallest dimension of a statistical set of nanoparticles is inferior than 1%, 2%, 3%, 4%, 5%, 6%, 7%, 8%, 9%, 10%, 15%, 20%, 25%, 30%, 35%, or 40% of said smallest dimension.

According to one embodiment, the size distribution for the largest dimension of a statistical set of nanoparticles inferior than 1%, 2%, 3%, 4%, 5%, 6%, 7%, 8%, 9%, 10%, 15%, 20%, 25%, 30%, 35%, or 40% of said largest dimension.

According to one embodiment, the nanoparticle has an isotropic shape.

According to one embodiment, the nanoparticle has an anisotropic shape.

According to one embodiment, the nanoparticle has a 0D, 1D or 2D dimension.

In one embodiment, examples of shape of nanoparticle include but are not limited to: quantum dots, sheet, rod, platelet, plate, prism, wall, disk, nanoparticle, wire, tube, tetrapod, ribbon, belt, needle, cube, ball, coil, cone, piller, flower, sphere, faceted sphere, polyhedron, bar, monopod, bipod, tripod, star, octopod, snowflake, thorn, hemisphere, urchin, filamentous nanoparticle, biconcave discoid, worm, tree, dendrite, necklace, chain, plate triangle, square, pentagon, hexagon, ring, tetrahedron, truncated tetrahedron, or combination thereof.

According to one embodiment, the nanoparticle has a spherical shape.

According to one embodiment, the nanoparticle has a diameter ranging from 20 nm to 10 μm, preferably between 20 nm to 2 μm, more preferably between 20 nm and 1 μm.

According to one embodiment, the nanoparticle has a diameter of at least 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 30 nm, 40 nm, 50 nm, 60 nm, 70 nm, 80 nm, 90 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.1 μm, 1.2 μm, 1.3 μm, 1.4 μm, 1.5 μm, 1.6 μm, 1.7 μm, 1.8 μm, 1.9 μm, 2 μm, 2.1 μm, 2.2 μm, 2.3 μm, 2.4 μm, 2.5 μm, 2.6 μm, 2.7 μm, 2.8 μm, 2.9 μm, 3 μm, 3.1 μm, 3.2 μm, 3.3 μm, 3.4 μm, 3.5 μm, 3.6 μm, 3.7 μm, 3.8 μm, 3.9 μm, 4 μm, 4.1 μm, 4.2 μm, 4.3 μm, 4.4 μm, 4.5 μm, 4.6 μm, 4.7 μm, 4.8 μm, 4.9 μm, 5 μm, 5.1 μm, 5.2 μm, 5.3 μm, 5.4 μm, 5.5 μm, 5.6 μm, 5.7 μm, 5.8 μm, 5.9 μm, 6 μm, 6.1 μm, 6.2 μm, 6.3 μm, 6.4 μm, 6.5 μm, 6.6 μm, 6.7 μm, 6.8 μm, 6.9 μm, 7 μm, 7.1 μm, 7.2 μm, 7.3 μm, 7.4 μm, 7.5 μm, 7.6 μm, 7.7 μm, 7.8 μm, 7.9 μm, 8 μm, 8.1 μm, 8.2 μm, 8.3 μm, 8.4 μm, 8.5 μm, 8.6 μm, 8.7 μm, 8.8 μm, 8.9 μm, 9 μm, 9.1 μm, 9.2 μm, 9.3 μm, 9.4 μm, 9.5 μm, 9.6 μm, 9.7 μm, 9.8 μm, 9.9 μm, or 10 μm.

According to one embodiment, in a statistical set of nanoparticles, said nanoparticles are not aggregated. This embodiment prevents the loss of colloidal stability.

According to one embodiment, in a statistical set of nanoparticles, said nanoparticles are aggregated.

According to one embodiment, the nanoparticle is a crystalline nanoparticle.

According to one embodiment, the material is a film.

According to one embodiment, the material is a granular film.

According to one embodiment, the material is a film comprising a plurality of first optically active nanocrystals.

According to one embodiment, the first optically active nanocrystals are not aggregated in the film.

According to one embodiment, the first optically active nanocrystals do not touch, are not in contact in the film.

According to one embodiment, the first optically active nanocrystals are aggregated in the film.

According to one embodiment, the first optically active nanocrystals touch, are in contact in the film.

According to one embodiment, the film has a thickness from 1 nm to 1 mm, preferably from 3 nm to 100 μm, more preferably from 10 nm to 1 μm.

According to one embodiment, the film has a thickness of at least 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 30 nm, 40 nm, 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, 30 μm, 30.5 μm, 31 μm, 31.5 μm, 32 μm, 32.5 μm, 33 μm, 33.5 μm, 34 μm, 34.5 μm, 35 μm, 35.5 μm, 36 μm, 36.5 μm, 37 μm, 37.5 μm, 38 μm, 38.5 μm, 39 μm, 39.5 μm, 40 μm, 40.5 μm, 41 μm, 41.5 μm, 42 μm, 42.5 μm, 43 μm, 43.5 μm, 44 μm, 44.5 μm, 45 μm, 45.5 μm, 46 μm, 46.5 μm, 47 μm, 47.5 μm, 48 μm, 48.5 μm, 49 μm, 49.5 μm, 50 μm, 50.5 μm, 51 μm, 51.5 μm, 52 μm, 52.5 μm, 53 μm, 53.5 μm, 54 μm, 54.5 μm, 55 μm, 55.5 μm, 56 μm, 56.5 μm, 57 μm, 57.5 μm, 58 μm, 58.5 μm, 59 μm, 59.5 μm, 60 μm, 60.5 μm, 61 μm, 61.5 μm, 62 μm, 62.5 μm, 63 μm, 63.5 μm, 64 μm, 64.5 μm, 65 μm, 65.5 μm, 66 μm, 66.5 μm, 67 μm, 67.5 μm, 68 μm, 68.5 μm, 69 μm, 69.5 μm, 70 μm, 70.5 μm, 71 μm, 71.5 μm, 72 μm, 72.5 μm, 73 μm, 73.5 μm, 74 μm, 74.5 μm, 75 μm, 75.5 μm, 76 μm, 76.5 μm, 77 μm, 77.5 μm, 78 μm, 78.5 μm, 79 μm, 79.5 μm, 80 μm, 80.5 μm, 81 μm, 81.5 μm, 82 μm, 82.5 μm, 83 μm, 83.5 μm, 84 μm, 84.5 μm, 85 μm, 85.5 μm, 86 μm, 86.5 μm, 87 μm, 87.5 μm, 88 μm, 88.5 μm, 89 μm, 89.5 μm, 90 μm, 90.5 μm, 91 μm, 91.5 μm, 92 μm, 92.5 μm, 93 μm, 93.5 μm, 94 μm, 94.5 μm, 95 μm, 95.5 μm, 96 μm, 96.5 μm, 97 μm, 97.5 μm, 98 μm, 98.5 μm, 99 μm, 99.5 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, or 1 mm

According to one embodiment, the film has an area from 100 nm² to 1 m², preferably from 1 μm² to 10 cm², more preferably from 50 μm² to 1 cm².

According to one embodiment, the film has an area of at least 100 nm², 200 nm², 300 nm², 400 nm², 500 nm², 600 nm², 700 nm², 800 nm², 900 nm², 1000 nm², 2000 nm², 3000 nm², 4000 nm², 5000 nm², 6000 nm², 7000 nm², 8000 nm², 9000 nm², 10000 nm², 20000 nm², 30000 nm², 40000 nm², 50000 nm², 60000 nm², 70000 nm², 80000 nm², 90000 nm², 100000 nm², 200000 nm², 300000 nm², 400000 nm², 500000 nm², 600000 nm², 700000 nm², 800000 nm², 900000 nm², 1 μm², 2 μm², 3 μm², 4 μm², 5 μm², 6 μm², 7 μm², 8 μm², 9 μm², 10 μm², 20 μm², 30 μm², 40 μm², 50 μm², 60 μm², 70 μm², 80 μm², 90 μm², 100 μm², 200 μm², 300 μm², 400 μm², 500 μm², 600 μm², 700 μm², 800 μm², 900 μm², 1000 μm², 2000 μm², 3000 μm², 4000 μm², 5000 μm², 6000 μm², 7000 μm², 8000 μm², 9000 μm², 10000 μm², 20000 μm², 30000 μm², 40000 μm², 50000 μm², 60000 μm², 70000 μm², 80000 μm², 90000 μm², 100000 μm², 200000 μm², 300000 μm², 400000 μm², 500000 μm², 600000 μm², 700000 μm², 800000 μm², 900000 μm², 1000000 μm², 2000000 μm², 3000000 μm², 4000000 μm², 5000000 μm², 6000000 μm², 7000000 μm², 8000000 μm², 9000000 μm², 10000000 μm², 20000000 μm², 3000000 μm², 4000000 μm², 5000000 μm², 6000000 μm², 7000000 μm², 8000000 μm², 9000000 μm², 1 cm², 2 cm², 3 cm², 4 cm², 5 cm², 6 cm², 7 cm², 8 cm², 9 cm², 10 cm², 20 cm², 30 cm², 40 cm², 50 cm², 60 cm², 70 cm², 80 cm², 90 cm², 100 cm², 200 cm², 300 cm², 400 cm², 500 cm², 600 cm², 700 cm², 800 cm², 900 cm², 1000 cm², 2000 cm², 3000 cm², 4000 cm², 5000 cm², 6000 cm², 7000 cm², 8000 cm², 9000 cm², or 1 m².

According to one embodiment, the material allows percolation of the second optically inactive region over the film.

According to one embodiment, the material comprises a ratio of second optically inactive region allowing percolation of the second optically inactive region over the film.

According to one embodiment, the material is a film comprising a mixture of colloidal nanocrystals, i.e. first optically active nanocrystals and second optically inactive nanocrystals, wherein the ratio of second optically inactive nanocrystals allows percolation of the second optically inactive region over said film.

According to one embodiment, the film can be deposited on a substrate using dropcasting, spincoating, dipcoating, doctor blading, ink jet printing, electrophoretic deposition, spray coating, a Langmuir blodget method, an electrophoretic procedure, or any method known by those skilled in the art.

According to one embodiment, the film was prepared by dropcasting, spincoating, dipcoating, doctor blading, ink jet printing, electrophoretic deposition, spray coating, a Langmuir blodget method, an electrophoretic procedure, or any method known by those skilled in the art.

According to one embodiment, the substrate comprises glass, CaF₂, undoped Si, undoped Ge, ZnSe, ZnS, KBr, LiF, Al₂O₃, KCl, BaF₂, CdTe, NaCl, KRS-5, a stack thereof or a mixture thereof.

According to one embodiment, the film further comprises at least one particle having optical absorption features at wavelengths shorter than the optical absorption feature of the first optically active region.

According to one embodiment, the film further comprises a solvent such as for example hexane, octane, hexane-octane mixture, toluene, chloroform, tetrachloroethylene, or a mixture thereof.

According to one embodiment, the film is free of oxygen.

According to one embodiment, the film is free of water.

According to one embodiment, the film further comprises at least one host material as described hereabove.

According to one embodiment, the film further comprises at least two host materials as described hereabove. In this embodiment, the host materials can be identical or different from each other.

According to one embodiment, the film further comprises a plurality of host materials as described hereabove. In this embodiment, the host materials can be identical or different from each other.

According to one embodiment, the material is a photoabsorptive layer or photoabsorptive film.

According to one embodiment, the material is protected by at least one capping layer as described hereabove.

In a ninth aspect, the present invention also relates to a method for manufacturing the material disclosed herein.

According to one embodiment, the method for manufacturing the material of the invention comprises the following steps:
preparing a first optically active region according to the method described hereabove;
growing a second optically inactive region on said first optically active region; and
isolating the material of the invention;

wherein said first optically active region comprising a first material presenting an intraband absorption feature, said first optically active region being a nanocrystal;

wherein said second optically inactive region comprising a semiconductor material having a bandgap superior to the energy of the intraband absorption feature of the first optically active region; and

wherein said material presents an intraband absorption feature.

According to one embodiment, the method for manufacturing the material of the invention comprises the following steps:
preparing a first optically active region:
   providing a metal carboxylate, preferably a metal oleate or a metal acetate in a coordinating solvent selected preferably from a primary amine more preferably oleyamine, hexadecylamine or octadecylamine;
   admixing within said solution a chalcogenide precursor selected preferably from trioctylphosphine chalcogenide, trimethylsilyl chalcogenide or disulfide chalcogenide at a temperature ranging from 60° C. to 130° C.;
   isolating the first optically active region;
growing a second optically inactive region on said first optically active region; and
isolating the material of the invention;

wherein said first optically active region comprising a first material presenting an intraband absorption feature, said first optically active region being a nanocrystal;

wherein said second optically inactive region comprising a semiconductor material having a bandgap superior to the energy of the intraband absorption feature of the first optically active region; and

wherein said material presents an intraband absorption feature.

According to one embodiment, the method for manufacturing the material of the invention comprises the following steps:
preparing a first optically active region according to any method known by those skilled in the art;
growing a second optically inactive region on said first optically active region; and
isolating the material of the invention;

wherein said first optically active region comprising a first material presenting an intraband absorption feature, said first optically active region being a nanocrystal;

wherein said second optically inactive region comprising a semiconductor material having a bandgap superior to the energy of the intraband absorption feature of the first optically active region; and

wherein said material presents an intraband absorption feature.

According to one embodiment, the second optically inactive region is grown on the first optically active region by epitaxial growth.

According to one embodiment, the epitaxial growth of the second optically inactive region on the first optically active region is performed using molecular beam epitaxy, MOCVD (metalorganic chemical vapor deposition), MOVPE (metalorganic vapor phase epitaxy), ultrahigh vacuum method or any epitaxial method known by those skilled in the art.

According to one embodiment, the second optically inactive region is grown on the first optically active region by CVD (chemical vapor deposition), ALD (atomic layer deposition), colloidal atomic layer deposition, colloidal method or any method known by those skilled in the art.

According to one embodiment, the second optically inactive region is not grown by epitaxial growth on the first optically active region.

According to one embodiment, the method for manufacturing the material of the invention comprises the following steps:
preparing a first optically active region according to the method described hereabove;
preparing a second optically inactive region according to the method described hereabove;
mixing the as-prepared regions to obtain the material of the invention;
isolating the material of the invention;

wherein said first optically active region comprising a first material presenting an intraband absorption feature, said first optically active region being a nanocrystal;

wherein said second optically inactive region comprising a semiconductor material having a bandgap superior to the energy of the intraband absorption feature of the first optically active region; and

wherein said material presents an intraband absorption feature.

According to one embodiment, the method for manufacturing the material of the invention comprises the following steps:
preparing a first optically active region:
   providing a metal carboxylate, preferably a metal oleate or a metal acetate in a coordinating solvent selected preferably from a primary amine more preferably oleyamine, hexadecylamine or octadecylamine;
   admixing within said solution a chalcogenide precursor selected preferably from trioctylphosphine chalcogenide, trimethylsilyl chalcogenide or disulfide chalcogenide at a temperature ranging from 60° C. to 130° C.;
   isolating the first optically active region;
preparing a second optically inactive:
   providing a metal carboxylate, preferably a metal oleate or a metal acetate in a coordinating solvent selected preferably from a primary amine more preferably oleyamine, hexadecylamine or octadecylamine;
   admixing within said solution a chalcogenide precursor selected preferably from trioctylphosphine chalcogenide, trimethylsilyl chalcogenide or disulfide chalcogenide at a temperature ranging from 60° C. to 130° C.;
   isolating the second optically inactive;
mixing the as-prepared regions to obtain the material of the invention;
isolating the material of the invention;

wherein said first optically active region comprising a first material presenting an intraband absorption feature, said first optically active region being a nanocrystal;

wherein said second optically inactive region comprising a semiconductor material having a bandgap superior to the energy of the intraband absorption feature of the first optically active region; and

wherein said material presents an intraband absorption feature.

According to one embodiment, the method for manufacturing the material of the invention comprises the following steps:
preparing a first optically active region according to any method known by those skilled in the art;
preparing a second optically inactive region according to any method known by those skilled in the art;
mixing the as-prepared regions to obtain the material of the invention;
isolating the material of the invention;

wherein said first optically active region comprising a first material presenting an intraband absorption feature, said first optically active region being a nanocrystal;

wherein said second optically inactive region comprising a semiconductor material having a bandgap superior to the energy of the intraband absorption feature of the first optically active region; and

wherein said material presents an intraband absorption feature.

In another aspect, the present invention also relates to an apparatus comprising:
at least one material of the invention; and
a first plurality of electrical connections bridging said material;

wherein the material is positioned such that there is a conductivity between the electrical connections and across the material, in response to illumination of said material with light at a wavelength ranging from 1.7 μm to 12 μm; and

wherein said apparatus is a photoconductor, photodetector, photodiode or phototransistor.

According to one embodiment, the material of the invention is an active layer of the apparatus.

According to one embodiment, the apparatus can be selected in the group of a charge-coupled device (CCD), a luminescent probe, a laser, a thermal imager, a night-vision system and a photodetector.

According to one embodiment, the apparatus has a high carrier mobility.

According to one embodiment, the apparatus has a carrier mobility higher than 1 cm²V⁻¹s⁻¹, preferably higher than 5 cm²V⁻¹s⁻¹, more preferably higher than 10 cm²V⁻¹s⁻¹.

According to one embodiment, the carrier mobility is not less than 1 cm²V⁻¹s⁻¹, preferably more than 10 cm²V⁻¹s⁻¹, more preferably higher than 50 cm²V⁻¹s⁻¹.

According to one embodiment, the apparatus of the invention comprises a first cathode, the first cathode being electronically coupled to a first material of the invention, the first material being coupled to a first anode.

According to one embodiment, the apparatus comprises a plurality of electrodes, said electrodes comprising at least one cathode and one anode.

According to one embodiment, the material of the invention is connected to at least two electrodes.

According to one embodiment, the material of the invention is connected to three electrodes, wherein one of them is used as a gate electrode.

According to one embodiment, the material of the invention is connected to an array of electrodes.

The electrodes are described hereabove.

According to one embodiment, the apparatus comprises an electrolyte as described hereabove (FIG. 23A-B, FIG. 24A-B).

According to one embodiment, the material of the invention is connected to a read out circuit.

According to one embodiment, the material of the invention is not directly connected to the electrodes.

According to one embodiment, the material of the invention is spaced from the electrodes by a unipolar barrier which band alignment with respect to the material of the invention only favors the transfer of one carrier (electron or hole) to the electrode.

According to one embodiment, the material of the invention is spaced from the electrodes by a unipolar barrier which band alignment with respect to the material of the invention only favors the transfer of one carrier (electron or hole) from the electrode.

According to one embodiment, the unipolar barrier is as described hereabove.

According to one embodiment, the material of the invention is cooled down by a Peltier device, a cryogenic cooler, using liquid nitrogen, or using liquid helium.

According to one embodiment, the material of the invention is operated from 1.5K to 350K, preferably from 4K to 330K, more preferably from 70K to 320K.

According to one embodiment, the material of the invention is illuminated by the front side.

According to one embodiment, the material of the invention is illuminated by the back side (through a transparent substrate).

According to one embodiment, the material of the invention is used as an infrared emitting material.

According to one embodiment, the material of the invention has a photo response ranging from 1 μA.W⁻¹ to 1 kA.W⁻¹, from 1 mA.W⁻¹ to 50 A.W⁻¹, or from 10 mA.W⁻¹ to 10 A.W⁻¹.

According to one embodiment, the material of the invention has a noise current density limited by 1/f noise.

According to one embodiment, the material of the invention has a specific detectivity ranging from 10⁶ to 10¹⁴ jones, from 10⁷ to 10¹³ jones, or from 10⁸ to 5×10¹² jones.

According to one embodiment, the material of the invention has a bandwidth of at least 1 Hz, 2 Hz, 3 Hz, 4 Hz, 5 Hz, 6 Hz, 7 Hz, 8 Hz, 9 Hz, 10 Hz, 11 Hz, 12 Hz, 13 Hz, 14 Hz, 15 Hz, 16 Hz, 17 Hz, 18 Hz, 19 Hz, 20 Hz, 30 Hz, 40 Hz, 50 Hz, 60 Hz, 70 Hz, 80 Hz, 100 Hz, 110 Hz, 120 Hz, 130 Hz, 140 Hz, 150 Hz, 160 Hz, 170 Hz, 180 Hz, 190 Hz, 200 Hz, 210 Hz, 220 Hz, 230 Hz, 240 Hz, 250 Hz, 260 Hz, 270 Hz, 280 Hz, 290 Hz, 300 Hz, 350 Hz, 400 Hz, 450 Hz, 500 Hz, 550 Hz, 600 Hz, 650 Hz, 700 Hz, 750 Hz, 800 Hz, 850 Hz, 900 Hz, 950 Hz, 1 kHz, 5 kHz, 10 kHz, 20 kHz, 25 kHz, 30 kHz, 35 kHz, 40 kHz, 45 kHz, 50 kHz, 55 kHz, 60 kHz, 65 kHz, 70 kHz, 75 kHz, 80 kHz, 85 kHz, 90 kHz, 95 kHz, 100 kHz, 200 kHz, 250 kHz, 300 kHz, 350 kHz, 400 kHz, 450 kHz, 500 kHz, 550 kHz, 600 kHz, 650 kHz, 700 kHz, 750 kHz, 800 kHz, 850 kHz, 900 kHz, 950 kHz, 1 MHz, 5 MHz, 10 MHz, 15 MHz, 20 MHz, 25 MHz, 30 MHz, 35 MHz, 40 MHz, 45 MHz, 50 MHz, 55 MHz, 60 MHz, 65 MHz, 70 MHz, 75 MHz, 80 MHz, 85 MHz, 90 MHz, 95 MHz, 100 MHz, 200 MHz, 250 MHz, 300 MHz, 350 MHz, 400 MHz, 450 MHz, 500 MHz, 550 MHz, 600 MHz, 650 MHz, 700 MHz, 750 MHz, 800 MHz, 850 MHz, 900 MHz, 950 MHz, or 1 GHz.

According to one embodiment, the time response of the material of the invention under a pulse of light is smaller than 1 ms, preferably smaller than 100 μs, more preferably smaller than 10 μs and even more preferably smaller than 1 μs.

According to one embodiment, the time response of the material of the invention under a pulse of light is smaller than 1 μs, preferably smaller than 100 ns, more preferably smaller than 10 ns and even more preferably smaller than 1 ns.

According to one embodiment, the time response of the material of the invention under a pulse of light is smaller than 1 ns, preferably smaller than 100 ps, more preferably smaller than 10 ps and even more preferably smaller than 1 ps.

According to one embodiment, the magnitude and sign of the photoresponse of the material of the invention is tuned or controlled by a gate bias.

According to one embodiment, the magnitude and sign of the photoresponse of the material of the invention is tuned with the incident wavelength of the light.

According to one embodiment, the time response of the apparatus is fastened by reducing the spacing between electrodes.

According to one embodiment, the time response of the apparatus is fastened by using a nanotrench geometry compared to micrometer spaced electrodes.

According to one embodiment, the time response of the apparatus is tuned or controlled with a gate bias.

According to one embodiment, the time response of the apparatus depends on the incident wavelength of the light.

According to one embodiment, the time response of the apparatus is smaller than 1 s, preferably smaller than 100 ms, more preferably smaller than 10 ms and even more preferably smaller than 1 ms.

According to one embodiment, the magnitude, sign and duration of the photoresponse of the photodetector is tuned or controlled by a gate bias.

According to one embodiment, the magnitude, sign and duration of the photoresponse of the photodetector depends on the incident wavelength.

According to one embodiment, the carrier density of the material of the invention is tuned using a gate, a back gate, a top gate, an electrochemical gate, a liquid electrochemical gate, or a solid electrochemical gate.

According to one embodiment, the photodetector is used as a flame detector.

According to one embodiment, the photodetector allows bicolor detection as described hereabove.

According to one embodiment, the photodetector allows multicolor detection.

According to one embodiment, the apparatus comprises at least one pixel comprising the material of the invention.

According to one embodiment, the apparatus comprises only one pixel. In this embodiment, the apparatus is a single pixel device.

According to one embodiment, the apparatus comprises a plurality of pixels, each pixel comprising the material of the invention.

According to one embodiment, the apparatus comprises at least 1, 2, 3, 4, 5, 6, 7, 8, 9, 10 pixels.

According to one embodiment, the pixels form an array of pixels.

The pixel and/or the array of pixels are as described hereabove.

According to one embodiment, the photodetector is a 1D (line) detector.

According to one embodiment, the photodetector is a 2D (line) detector.

A device comprising a plurality of apparatus as described hereabove; and a readout circuit electrically connected to the plurality of apparatus.

According to one embodiment, the material of the invention is used for photodetection.

According to one embodiment, the material of the invention is used for photodetection in the UV range.

According to one embodiment, the material of the invention is used for photodetection in the visible range.

According to one embodiment, the material of the invention is used for photodetection in the infrared range.

According to one embodiment, the material of the invention is used for its photoconductive properties.

According to one embodiment, the material of the invention is used in a photoconductive device in a planar geometry.

According to one embodiment, the material of the invention is used in a photoconductive device in a vertical geometry.

According to one embodiment, the material of the invention is used to build a transistor.

According to one embodiment, the material of the invention is used in a transistor.

According to one embodiment, the material of the invention is used to build a phototransistor.

According to one embodiment, the material of the invention is used in a phototransistor.

According to one embodiment, the material of the invention is used to build a photodetector.

According to one embodiment, the material of the invention is used in a photodetector. According to one embodiment, the material of the invention is used to build a diode.

According to one embodiment, the material of the invention is used in a diode.

According to one embodiment, the material of the invention is used to build an LED.

According to one embodiment, the material of the invention is used in a smart window.

According to one embodiment, the material of the invention is used in a smart window with tunable transmission in the visible range of wavelength.

According to one embodiment, the material of the invention is used in a smart window with tunable transmission in the near infrared range of wavelength.

According to one embodiment, the material of the invention is used in a smart window with tunable transmission in the mid infrared range of wavelength.

According to one embodiment, the material of the invention is used in a smart window which tunable optical transmission is used to control room temperature.

According to one embodiment, the material of the invention presents air stable properties.

In another aspect illustrated in FIG. 25, the present invention also relates to a device 3 comprising:
at least one substrate 31;
at least one electronic contact layer 32;
at least one electron transport layer 33; and
at least one photoactive layer 34;

wherein said device has a vertical geometry.

The vertical geometry allows a shorter travel distance for the charge carriers compared to a planar geometry, thus enhancing the transport properties of the device 3.

In one embodiment, the vertical geometry refers to a photodiode geometry while a planar geometry refers to a photoconductive geometry.

The photodiode geometry allows a lower operating bias, thus reducing the dark current compared to photoconductive geometry.

According to one embodiment illustrated in FIG. 26 and FIG. 38A, the device 3 comprises at least two electronic contact layers (321, 322).

According to one embodiment, the device 3 comprises:
at least one substrate 31;
a first electronic contact layer 321;
at least one electron transport layer 33;
at least one photoactive layer 34; and
a second electronic contact layer 322;

wherein said device has a vertical geometry.

According to one embodiment illustrated in FIG. 26, the device 3 comprises:
at least one substrate 31;
a first electronic contact layer 321;
at least one photoactive layer 34; and
a second electronic contact layer 322;

wherein said device has a vertical geometry.

According to one embodiment, the device 3 further comprises at least one hole transport layer 35.

According to one embodiment, the device 3 presents optimized hole extraction properties that may be due to a hole transport layer 35 or a structuration of the photoactive layer 34. In this embodiment, the hole transport layer 35 or a structuration of the photoactive layer 34 helps to guide and extract the hole carriers.

According to one embodiment, the device 3 comprises:
at least one substrate 31;
a first electronic contact layer 321;
at least one electron transport layer 33;
at least one photoactive layer 34;
at least one hole transport layer 35; and
a second electronic contact layer 322;

wherein said device has a vertical geometry.

According to one embodiment illustrated in FIG. 32, the device 3 further comprises at least one encapsulating layer 36.

The encapsulation with the at least one encapsulating layer 36 enhances the stability of the device 3 under air and/or humidity conditions, prevents the degradation of said device 3 due to air and/or humidity exposure. Said encapsulation is not detrimental to the transport and/or optical properties of the device 3, and helps preserving said transport and/or optical properties of the device 3 upon air and/or humidity exposure.

According to one embodiment, the device 3 comprises:
at least one substrate 31;
a first electronic contact layer 321;
at least one electron transport layer 33;
at least one photoactive layer 34;
at least one hole transport layer 35;
a second electronic contact layer 322; and
at least one encapsulating layer 36;

wherein said device has a vertical geometry.

According to one embodiment, the device 3 comprises a plurality of encapsulating layers 36.

According to one embodiment illustrated in FIG. 34A-D, the device 3 comprises at least three encapsulating layers (361, 362, 363).

According to one embodiment, the device 3 comprises three encapsulating layers (361, 362, 363).

According to one embodiment, the layers are successively overlaid on the substrate.

According to one embodiment, the electronic contact layer 32 is overlaid on the substrate 31.

According to one embodiment, the first electronic contact layer 321 is overlaid on the substrate 31.

According to one embodiment, the electron transport layer 33 is overlaid on the electronic contact layer 32.

According to one embodiment, the photoactive layer 34 is overlaid on the electron transport layer 33.

According to one embodiment, the hole transport layer 35 is overlaid on the photoactive layer 34.

According to one embodiment, the second electronic contact layer 322 is overlaid on the hole transport layer 35 or the photoactive layer 34.

According to one embodiment, the at least one encapsulating layer 36 is overlaid on the second electronic contact layer 322.

According to one embodiment, the device 3 is dedicated to photodetection.

According to one embodiment, the device 3 is dedicated to photodetection and operating in photoconductor mode.

According to one embodiment, the device 3 is dedicated to photodetection and operating in photovoltaic mode.

According to one embodiment, the device 3 is a photodiode, a diode, a solar cell, or a photoconductor.

FIG. 27 illustrates the transfer curve (drain and gate current as a function of the applied gate voltage at constant drain bias) of the device 3 as a photodiode.

According to one embodiment, the device 3 comprises several pixels.

According to one embodiment, the device 3 comprises at least 2, 3, 4, 5, 6, 7, 8, 9, or 10 pixels.

According to one embodiment, the device 3 comprises an array of pixels.

According to one embodiment, the pixel is as described hereabove.

According to one embodiment, the pixel array forms a 1D (line) detector.

According to one embodiment, the pixel array forms a 2D (matrix) detector.

According to one embodiment, the array of pixels comprises at least 50×50 pixels, 256×256 pixels, 512×512 pixels, or 1024×1024 pixels.

According to one embodiment, the array of pixels is a megapixel matrix.

According to one embodiment, the array of pixels comprises more than one megapixel, more than 2, 4, 8, 16, 32 or 64 megapixels.

According to one embodiment, the array of pixels has a filling factor higher than 40% (i.e. more than 40% of the area of the total matrix is made of pixel), more preferably higher than 50%; more preferably higher than 60%, more preferably higher than 70%, more preferably higher than 80%, and even more preferably higher than 90%.

According to one embodiment, the spacing between the pixels is less than the pixel size, less than 50%, 40%, 30%, or 20% of the pixel size.

According to one embodiment, the pixel is connected to a read out circuit.

According to one embodiment, the pixel is connected to a read out circuit in a planar geometry.

According to one embodiment, the pixel is connected to a read out circuit in a vertical geometry.

According to one embodiment illustrated in FIG. 28A-B, the time response of the device 3 is smaller than 1 s, 900 ms, 800 ms, 700 ms, 600 ms, 500 ms, 400 ms, 300 ms, 200 ms, 100 ms, 90 ms, 80 ms, 70 ms, 60 ms, 50 ms, 40 ms, 30 ms, 20 ms, 10 ms, 9 ms, 8 ms, 7 ms, 6 ms, 5 ms, 4 ms, 3 ms, 2 ms, 1 ms, 900 μs, 800 μs, 700 μs, 600 μs, 500 μs, 400 μs, 300 μs, 200 μs, 100 μs, 90 μs, 80 μs, 70 μs, 60 μs, 50 μs, 40 μs, 30 μs, 20 μs, 10 μs, 9 μs, 8 μs, 7 μs, 6 μs, 5 μs, 4 μs, 3 μs, 2 μs, 1 μs, 900 ns, 800 ns, 700 ns, 600 ns, 500 ns, 400 ns, 300 ns, 200 ns, 100 ns, 90 ns, 80 ns, 70 ns, 60 ns, 50 ns, 40 ns, 30 ns, 20 ns, 10 ns, 9 ns, 8 ns, 7 ns, 6 ns, 5 ns, 4 ns, 3 ns, 2 ns, 1 ns, 900 ps, 800 ps, 700 ps, 600 ps, 500 ps, 400 ps, 300 ps, 200 ps, 100 ps, 90 ps, 80 ps, 70 ps, 60 ps, 50 ps, 40 ps, 30 ps, 20 ps, 10 ps, 9 ps, 8 ps, 7 ps, 6 ps, 5 ps, 4 ps, 3 ps, 2 ps, or 1 ps.

According to one embodiment, the time response of the device 3 can be fastened by reducing the spacing between electrodes.

According to one embodiment, the time response of the device 3 is faster while using a nanotrench geometry compared to μm spaced electrodes.

According to one embodiment, the magnitude and sign of the photoresponse of the photoactive layer 34 can be tuned with a gate bias.

According to one embodiment, the magnitude and sign of the photoresponse of the photoactive layer 34 can be tuned with the wavelength of the incident light.

According to one embodiment, the time response of the device 3 can be tuned with a gate bias.

According to one embodiment, the time response of the device 3 depends on the wavelength of the incident light.

According to one embodiment, the device 3 is coupled to a read out circuit. According to one embodiment, the device 3 is coupled to a CMOS read out circuit.

According to one embodiment, the device 3 further comprises an electrolyte.

According to one embodiment, the electrolyte comprises or consists of an ion gel gating such as LiClO₄.

In one embodiment, the electrolyte comprises a matrix and ions. In one embodiment, the electrolyte comprises a polymer matrix.

In one embodiment, the electrolyte comprises a polymer matrix doped with ions salts.

In one embodiment, examples of a polymer matrix include but are not limited to: polystyrene, poly(N-isopropyl acrylamide), polyethylene glycol, polyethylene, polybutadiene, polyisoprene, polyethylene oxide, polyethyleneimine, polymethylmethacrylate, polyethylacrylate, polyvinylpyrrolidone, polypropylene glycol, polydimethylsiloxane, polyisobutylene, or a blend/multiblocks polymer thereof, or a mixture thereof.

In one embodiment, the electrolyte comprises at least one ion salt.

In one embodiment, the electrolyte comprises ions salts.

In one embodiment, examples of ions salts include but are not limited to: LiCl, LiBr, LiI, LiSCN, LiClO₄, KClO₄, NaClO₄, ZnCl₃⁻, ZnCl₄²⁻, ZnBr₂, LiCF₃SO₃, NaCl, NaI, NaBr, NaSCN, KCl, KBr, KI, KSCN, LIN(CF₃SO₂)₂ or a mixture thereof.

According to one embodiment, the substrate 31 is used as a mechanical support.

According to one embodiment, the substrate 31 combines mechanical and optical properties.

According to one embodiment, the substrate 31 includes an antireflexion coating.

According to one embodiment, the substrate 31 is partly or totally optically transparent in the infrared range.

According to one embodiment, the substrate 31 is partly or totally optically transparent in the near infrared range.

According to one embodiment, the substrate 31 is partly or totally optically transparent in the short wave infrared range, i.e. from 0.8 to 2.5 μm.

According to one embodiment, the substrate 31 is partly or totally optically transparent in the mid wave infrared range, i.e. from 3 to 5 μm.

According to one embodiment, the substrate 31 is partly or totally optically transparent in the long wave infrared range, i.e. from 8 to 12 μm.

According to one embodiment, the substrate 31 is partly or totally optically transparent in the mid infrared, i.e. from 2.5 to 15 μm.

According to one embodiment, the substrate 31 is partly or totally optically transparent in the far infrared, i.e. above 15 μm.

According to one embodiment, the substrate 31 is partly or totally optically transparent in the THz range, i.e. above 30 μm.

According to one embodiment, the substrate 31 has a transmission higher than 20%, preferably higher than 50%and more preferably higher than 80% in the infrared range.

According to one embodiment, the substrate 31 has a transmission higher than 20%, preferably higher than 50%and more preferably higher than 80% in the near infrared range.

According to one embodiment, the substrate 31 has a transmission higher than 20%, preferably higher than 50%and more preferably higher than 80% in the short wave infrared range, i.e. from 0.8 to 2.5 nm.

According to one embodiment, the substrate 31 has a transmission higher than 20%, preferably higher than 50%and more preferably higher than 80% in the mid wave infrared range, i.e. from 3 to 5 nm.

According to one embodiment, the substrate 31 has a transmission higher than 20%, preferably higher than 50%and more preferably higher than 80% in the long wave infrared range, i.e. from 8 to 12 nm.

According to one embodiment, the substrate 31 has a transmission higher than 20%, preferably higher than 50%and more preferably higher than 80% in the mid infrared, i.e. from 2.5 to 15 nm.

According to one embodiment, the substrate 31 has a transmission higher than 20%, preferably higher than 50%and more preferably higher than 80% in the far infrared, i.e. above 15 nm.

According to one embodiment, the substrate 31 has a transmission higher than 20%, preferably higher than 50%and more preferably higher than 80% in the THz range, i.e. above 30 nm.

According to one embodiment, examples of substrate 31 include but are not limited to: glass, fused silica, quartz, undoped double side polished wafer, silicon wafer, or highly resistive silicon wafer.

According to one embodiment, the substrate 31 comprises a material including but not limited to: glass, Si, SiO₂, ZnSe, ZnS, CaF₂, BaF₂, CdTe, CsBr, GaAs, Ge, LiF, MgF₂, KBr, KCl, Al₂O₃, NaCl, KRS₅, a mixture thereof, or a stack of layers thereof.

According to one embodiment, the substrate 31 comprises a material including but not limited to: glass, Si, SiO₂, ZnSe, ZnS, CaF₂, BaF₂, CdTe, CsBr, GaN, GaAsP, GaSb, GaAs, GaP, InP, Ge, SiGe, InGaN, GaAlN, GaAlPN, AlN, AlGaAs, AlGaP, AlGaInP, AlGaN, AlGaInN, LiF, SiC, BN, MgF₂, KBr, KCl, Al₂O₃, NaCl, KRS₅, Au, Ag, Pt, Ru, Ni, Co, Cr, Cu, Sn, Rh Pd, Mn, Ti, a mixture thereof, or a stack of layers thereof.

According to one embodiment, the substrate 31 is electrically insulating.

According to one embodiment, the substrate 31 has a resistivity higher than 100 Ω.cm, 200 Ω.cm, 300 Ω.cm, 400 Ω.cm, 500 Ω.cm, 600 Ω.cm, 700 Ω.cm, 800 Ω.cm, 900 Ω.cm, 1000 Ω.cm, 1500 Ω.cm, 2000 Ω.cm, 2500 Ω.cm, 3000 Ω.cm, 3500 Ω.cm, 4000 Ω.cm, 4500 Ω.cm, 5000 Ω.cm, 5500 Ω.cm, 6000 Ω.cm, 6500 Ω.cm, 7000 Ω.cm, 7500 Ω.cm, 8000 Ω.cm, 8500 Ω.cm, 9000 Ω.cm, 9500 Ω.cm, or 10000 Ω.cm.

According to one embodiment, the substrate 31 is rigid, not flexible.

According to one embodiment, the substrate 31 is flexible.

According to one embodiment, the substrate 31 is patterned.

According to one embodiment, the substrate 31 is patterned using a photoresist.

According to one embodiment, the electronic contact layer 32 is an electrode.

According to one embodiment, the electronic contact layer 32 is a metal contact.

In one embodiment, the device 3 comprises at least two electronic contact layers (321, 322): at least one bottom electrode 321 and one top electrode 322.

In one embodiment illustrated in FIG. 38B, the at least two electronic contact layers (321, 322) are interdigitated electrodes 38.

In one embodiment, the at least two electronic contact layers (321, 322) are pre-patterned interdigitated electrodes 38.

In one embodiment, the device 3 comprises contact pads 37 connected to the at least two electronic contact layers (321, 322).

According to one embodiment illustrated in Fig.26, the at least two electronic contact layers (321, 322) are both deposited directly on the substrate 31.

According to one embodiment, the electronic contact layer 32 comprises a metal, a metal oxide or a mixture thereof.

According to one embodiment, the device 3 comprises an additional adhesion layer between the substrate 31 and the electronic contact layer 32 to promote the adhesion of said electronic contact layer 32.

According to one embodiment, the additional adhesion layer comprises of consists of Ti or Cr.

According to one embodiment, the additional adhesion layer has a thickness of at least 1 nm, 1.5 nm, 2 nm, 2.5 nm, 3 nm, 3.5 nm, 4 nm, 4.5 nm, 5 nm, 5.5 nm, 6 nm, 6.5 nm, 7 nm, 7.5 nm, 8 nm, 8.5 nm, 9 nm, 9.5 nm, 10 nm, 10.5 nm, 11 nm, 11.5 nm, 12 nm, 12.5 nm, 13 nm, 13.5 nm, 14 nm, 14.5 nm, 15 nm, 15.5 nm, 16 nm, 16.5 nm, 17 nm, 17.5 nm, 18 nm, 18.5 nm, 19 nm, 19.5 nm, or 20 nm.

According to one embodiment, examples of metal include but are not limited to: Au, Ag, Al, Pt, Cu, or a mixture thereof.

According to one embodiment, the electronic contact layer 32 comprises a transparent oxide.

According to one embodiment, the electronic contact layer 32 comprises a conductive oxide.

According to one embodiment, the electronic contact layer 32 comprises a transparent conductive oxide.

According to one embodiment, examples of transparent conductive oxide include but are not limited to: ITO (indium tin oxide) or FTO (fluor doped tin oxide).

According to one embodiment, the electronic contact layer 32 is used as electron extractor.

According to one embodiment, the electronic contact layer 32 is used as hole extractor.

According to one embodiment, the electronic contact layer 32 has a work function ranging from 6 eV to 3 eV, preferably ranging from 5.5 eV to 4 eV, more preferably ranging from 5 eV to 4.5 eV.

According to one embodiment, the electronic contact layer 32 is partly or totally optically transparent in the infrared range.

According to one embodiment, the electronic contact layer 32 is partly or totally optically transparent in the near infrared range.

According to one embodiment, the electronic contact layer 32 is partly or totally optically transparent in the short wave infrared range, i.e. from 0.8 to 2.5 μm.

According to one embodiment, the electronic contact layer 32 is partly or totally optically transparent in the mid wave infrared range, i.e. from 3 to 5 μm.

According to one embodiment, the electronic contact layer 32 is partly or totally optically transparent in the long wave infrared range, i.e. from 8 to 12 μm.

According to one embodiment, the electronic contact layer 32 is partly or totally optically transparent in the mid infrared, i.e. from 2.5 to 15 μm.

According to one embodiment, the electronic contact layer 32 is partly or totally optically transparent in the far infrared, i.e. above 15 μm.

According to one embodiment, the electronic contact layer 32 is partly or totally optically transparent in the THz range, i.e. above 30 μm.

According to one embodiment illustrated in FIG. 29, the electronic contact layer 32 has a transparency of at least 30%, at least 40%, at least 50%, at least 60%, at least 70% in the infrared range, in the near infrared range, in the short wave infrared range, in the mid wave infrared range, in the long wave infrared range, in the mid infrared range, in the far infrared range, and/or in the THz range.

According to one embodiment, the electronic contact layer 32 has a thickness of at least 0.5 nm, 1 nm, 1.5 nm, 2 nm, 2.5 nm, 3 nm, 3.5 nm, 4 nm, 4.5 nm, 5 nm, 5.5 nm, 6 nm, 6.5 nm, 7 nm, 7.5 nm, 8 nm, 8.5 nm, 9 nm, 9.5 nm, 10 nm, 11 nm, 12 nm, 13 nm, 14 nm, 15 nm, 16 nm, 17 nm, 18 nm, 19 nm, 20 nm, 30 nm, 40 nm, 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, or 300 nm.

According to one embodiment, the electronic contact layer 32 has a thickness ranging from 5 to 200 nm, preferably from 20 to 100 nm.

A low thickness, i.e. the electronic contact layer 32 being a thin layer, allows a weak absorption of said electronic contact layer 32 in the infrared range, thus an optimal transmission to the photoactive layer. A low thickness enables better performances for the device 3.

According to one embodiment, to build a partly transparent electronic contact layer 32, a thin layer of material (metal or metal oxide as described hereabove) which thickness is below 10 nm is coupled to a metallic grid which covers less than 50% of the total electronic contact layer 32 surface, preferably less than 33% and more preferably less than 25%.

According to one embodiment, the electron transport layer 33 is used to extract electrons from the photoactive layer.

According to one embodiment, the electron transport layer 33 has a work function lower than 4.7 eV, lower than 4.6 eV, lower than 4.5 eV, lower than 4.4 eV, lower than 4.3 eV, lower than 4.2 eV, lower than 4.1 eV, lower than 4.0 eV, lower than 3.9 eV, lower than 3.8 eV, lower than 3.7 eV, lower than 3.6 eV, lower than 3.5 eV, lower than 3.4 eV, lower than 3.3 eV, lower than 3.2 eV, lower than 3.1 eV, lower than 3.0 eV.

According to one embodiment, the electron transport layer 33 has a thickness of at least 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 55 nm, 60 nm, 65 nm, 70 nm, 75 nm, 80 nm, 85 nm, 90 nm, 95 nm, 100 nm, 105 nm, 110 nm, 115 nm, 120 nm, 125 nm, 130 nm, 135 nm, 140 nm, 145 nm, 150 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, or 1 μm.

According to one embodiment, the electron transport layer 33 comprises at least one n-type polymer.

According to one embodiment, examples of n-type polymer include but are not limited to: polyethylenimine (PEI), poly(sulfobetaine methacrylate) (PSBMA), amidoamine-functionalized polyfluorene (PFCON-C), or a mixture thereof.

According to one embodiment, the electron transport layer 33 comprises an inorganic material.

According to one embodiment, the electron transport layer 33 comprises an inorganic material such as fullerenes (C₆₀, C₇₀) or tris(8-hydroxyquinoline) aluminum (Alq₃), or a mixture thereof.

According to one embodiment, the electron transport layer 33 comprises at least one n-type oxide.

According to one embodiment, examples of n-type oxide include but are not limited to: ZnO, aluminum doped zinc oxide (AZO), TiO₂, Cr₂O₃, CuO, CuO₂, Cu₂O, Cu₂O₃, SnO₂, ZrO₂, MoO₃, mixed oxides, or a mixture thereof.

According to one embodiment, the electron transport layer 33 has a transparency higher than 80%, preferably higher than 90%, more preferably higher than 95% in the infrared range, in the near infrared range, in the short wave infrared range, in the mid wave infrared range, in the long wave infrared range, in the mid infrared range, in the far infrared range, and/or in the THz range.

According to one embodiment, the electron transport layer 33 has an electron mobility higher than 10⁻⁴ cm²V⁻¹s⁻¹, 10⁻³ cm²V⁻¹s⁻¹, 10⁻² cm²V⁻¹s⁻¹, 10⁻¹ cm²V⁻¹s⁻¹, 1 cm²V⁻¹s⁻¹, 10 cm²V⁻¹s⁻¹, 20 cm²V⁻¹s⁻¹, 30 cm²V⁻¹s⁻¹, 40 cm²V⁻¹s⁻¹, or 50 cm²V⁻¹s⁻¹.

According to one embodiment, the photoactive layer 34 is a photoabsorptive layer as described hereabove.

According to one embodiment, the photoactive layer 34 is a layer or a film comprising a plurality of nanocrystals, the material of the invention, or at least one film of the invention.

According to one embodiment, the substrate 31 has no epitaxial relation with the nanocrystals atomic lattice.

According to one embodiment, the nanocrystals, the material of the invention, or the film of the invention exhibit infrared absorption.

According to one embodiment, the nanocrystals, the material of the invention, or the film of the invention exhibit infrared absorption in the range from 800 nm to 12 μm.

According to one embodiment, the nanocrystals, the material of the invention, or the film of the invention exhibit infrared absorption in the short wave infrared range, i.e. from 800 nm to 1.7 μm.

According to one embodiment, the nanocrystals, the material of the invention, or the film of the invention exhibit infrared absorption in the extended short wave infrared, i.e. from 800 nm to 2.5 μm.

According to one embodiment, the nanocrystals, the material of the invention, or the film of the invention exhibit infrared absorption in the mid wave infrared, i.e. from 3 μm to 5 μm.

According to one embodiment, the nanocrystals, the material of the invention, or the film of the invention exhibit infrared absorption in the long wave infrared, i.e. from 8 μm to 12 μm.

According to one embodiment, the nanocrystals, the material of the invention, or the film of the invention exhibit interband transition. In this embodiment, the physical mechanism responsible for the infrared absorption is interband transition.

According to one embodiment, the nanocrystals, the material of the invention, or the film of the invention exhibit intraband transition. In this embodiment, the physical mechanism responsible for the infrared absorption is intraband transition.

According to one embodiment, the nanocrystals, the material of the invention, or the film of the invention exhibit plasmonic absorption. In this embodiment, the physical mechanism responsible for the infrared absorption is plasmonic absorption.

According to one embodiment, the nanocrystals, the material of the invention, or the film of the invention are as described hereabove.

According to one embodiment, the nanocrystals comprise a single material.

According to one embodiment, the nanocrystals, the material of the invention, or the film of the invention comprise a semiconductor material selected from the group consisting of group IV, group IIIA-VA, group IIA-VIA, group IIIA-VIA, group IA-IIIA-VIA, group IIA-VA, group IVA-VIA, group VIB-VIA, group VB-VIA, group IVB-VIA or mixture thereof.

According to one embodiment, the nanocrystals are non intentionally doped nanocrystals.

According to one embodiment, the nanocrystals are non degeneratly doped nanocrystals.

According to one embodiment, the doped nanocrystals are p-type semiconductor.

According to one embodiment, the doped nanocrystals are n-type semiconductor.

According to one embodiment, the non intentionally doped nanocrystals have a residual doping of less than 10¹⁸ cm⁻³.

According to one embodiment, the nanocrystals are degenerately doped.

According to one embodiment, the doped nanocrystals are self doped.

According to one embodiment, the doped nanocrystals are intentionally doped.

According to one embodiment, the doped nanocrystals are doped with electrons.

According to one embodiment, the doped nanocrystals are doped with holes.

According to one embodiment, the doped nanocrystals have a doping higher than 0.1 carrier per nanocrystal.

According to one embodiment, the doped nanocrystals have a doping between 0.1 and 10 carrier per nanocrystal.

According to one embodiment, the self doped nanocrystals have a doping higher than 10¹⁸ cm³.

According to one embodiment, the intentionally doped nanocrystals have a doping higher than 10¹⁸ cm⁻³.

According to one embodiment, the intentionally doped nanocrystals have a doping smaller than 10²³ cm⁻³.

According to one embodiment, the nanocrystals comprise a narrow bandgap semiconductor material.

According to one embodiment, the nanocrystals have a bandgap smaller than 1.1 eV.

According to one embodiment, the nanocrystals comprise at least one metal with a sparse density of state near the fermi energy.

According to one embodiment, the nanocrystals comprise at least one semimetal.

According to one embodiment, examples of semimetal include but are not limited to: C, Bi, Sn, SnTe, HgTe, HgSe, Cd₃As₂.

According to one embodiment, the nanocrystals comprise metal chalcogenide nanocrystals comprising a material AₙXₘ; wherein A is selected from the group consisting of Ia, Ha, Ma, IVa, IVb, IV, Vb, VIb, or mixture thereof; X is selected from the group consisting of Va, VIa, or mixture thereof; and n and m are decimal numbers ranging from 0 to 1; n and m are both strictly superior to 0.

According to one embodiment, metal A is selected from the group consisting of Hg or a mixture of Hg and at least one of Pb, Ag, Sn, Cd, Bi, or Sb.

According to one embodiment, examples of material AₙXₘ include but are not limited to: HgS, HgSe, HgTe, HgₓCd₁₋ₓTe wherein x is a real number strictly included between 0 and 1, PbS, PbSe, PbTe, Bi₂S₃, Bi₂Se₃, Bi₂Te₃, SnS, SnS₂, SnTe, SnSe, Sb₂S₃, Sb₂Se₃, Sb₂Te₃, Ag₂S, Ag₂Se, Ag₂Te or alloys, or mixture thereof.

According to one embodiment, examples of metal chalcogenide nanocrystals include but are not limited to: mercury chalcogenide nanocrystals, lead chalcogenide nanocrystals, or a mixture thereof.

According to one embodiment, the nanocrystals comprise mercury chalcogenide nanocrystals.

According to one embodiment, the nanocrystals comprise a core comprising mercury chalcogenide.

According to one embodiment, the nanocrystals comprise a core consisting of mercury chalcogenide.

According to one embodiment, examples of mercury chalcogenide nanocrystals include but are not limited to: HgS, HgSe, HgTe, or a mixture thereof.

According to one embodiment, the nanocrystals comprise lead chalcogenide nanocrystals.

According to one embodiment, the nanocrystals do not comprise or do not consist of lead chalcogenide nanocrystals.

According to one embodiment, examples of lead chalcogenide nanocrystals include but are not limited to: PbS, PbSe, PbTe, or a mixture thereof.

According to one embodiment, the nanocrystals comprise copper chalcogenides such as Cu2S, Cu2Se or Cu₂Te, alloys thereof, or a mixture thereof.

According to one embodiment, the nanocrystals comprise a non-stoichiometric form of a copper chalcogenide.

According to one embodiment, the nanocrystals comprise InN and any other nitrogen derivative behaving as a degenerately doped semiconductor.

According to one embodiment, the nanocrystals comprise a doped oxide.

According to one embodiment, examples of doped oxide include but are not limited to: Ga or Al doped ZnO, or a mixture thereof.

According to one embodiment, the nanocrystals comprise doped silicon, or doped germanium.

According to one embodiment, examples of doped silicon include but are not limited to: B or N doped silicon.

According to one embodiment, examples of shape of nanocrystals include but are not limited to: quantum dots, sheet, rod, platelet, plate, prism, wall, disk, nanoparticle, wire, tube, tetrapod, ribbon, belt, needle, cube, ball, coil, cone, piller, flower, sphere, faceted sphere, polyhedron, bar, monopod, bipod, tripod (FIG. 30A-B), star, octopod, snowflake, thorn, hemisphere, urchin, filamentous nanoparticle, biconcave discoid, worm, tree, dendrite, necklace, chain, plate triangle, square, pentagon, hexagon, ring, tetrahedron, truncated tetrahedron, or combination thereof.

According to one embodiment, the nanocrystals have a cation rich surface.

According to one embodiment, the nanocrystals have an anion rich surface.

According to one embodiment, the nanocrystals are heterostructures. In this embodiment, each nanocrystal comprises a core partially or totally covered by at least one layer of inorganic material.

According to one embodiment, the nanocrystals are heterostructures. In this embodiment, each nanocrystal comprises a core partially or totally covered by at least one layer of AₙXₘ material.

The heterostructure enhances charge dissociation.

According to one embodiment, the nanocrystals are heterostructures with a type II band alignment to enhance charge dissociation.

According to one embodiment, the nanocrystals are heterostructures of HgSe/HgTe.

According to one embodiment, the nanocrystals are heterostructures, wherein the core is optically active and the shell is here to mechanically harden the material.

According to one embodiment, the nanocrystals are heterostructures, wherein the core absorbs in the infrared range and the shell is used to prevent the nanocrystal aggregation during annealing.

According to one embodiment, the photoactive layer 34 has an absorption coefficient ranging from 100 cm⁻¹ to 20000 cm⁻¹, from 500 cm⁻¹ to 20000 cm⁻¹, from 1000 cm⁻¹ to 20000 cm⁻¹, from 1500 cm⁻¹ to 20000 cm⁻¹, from 2000 cm⁻¹ to 20000 cm⁻¹, from 2500 cm⁻¹ to 20000 cm⁻¹, from 3000 cm⁻¹ to 20000 cm⁻¹, from 3500 cm⁻¹ to 20000 cm⁻¹, from 4000 cm⁻¹ to 20000 cm⁻¹, from 4500 cm⁻¹ to 20000 cm⁻¹, from 5000 cm⁻¹ to 20000 cm⁻¹, from 5500 cm⁻¹ to 20000 cm⁻¹, from 6000 cm⁻¹ to 20000 cm⁻¹, from 6500 cm⁻¹ to 20000 cm⁻¹, from 7000 cm⁻¹ to 20000 cm⁻¹, from 7500 cm⁻¹ to 20000 cm⁻¹, from 8000 cm⁻¹ to 20000 cm⁻¹, from 8500 cm⁻¹ to 20000 cm⁻¹, from 9000 cm⁻¹ to 20000 cm⁻¹, from 9500 cm⁻¹ to 20000 cm⁻¹, from 10000 cm⁻¹ to 20000 cm⁻¹, from 11000 cm⁻¹ to 20000 cm⁻¹, from 12000 cm⁻¹ to 20000 cm⁻¹, from 13000 cm⁻¹ to 20000 cm⁻¹, from 14000 cm⁻¹ to 20000 cm⁻¹, from 15000 cm⁻¹ to 20000 cm⁻¹, from 16000 cm⁻¹ to 20000 cm⁻¹, from 17000 cm⁻¹ to 20000 cm⁻¹, from 18000 cm⁻¹ to 20000 cm⁻¹, from 19000 cm⁻¹ to 20000 cm⁻¹; ranging from 100 cm⁻¹ to 19000 cm⁻¹, from 100 cm⁻¹ to 18000 cm⁻¹, from 100 cm⁻¹ to 17000 cm⁻¹, from 100 cm⁻¹ to 16000 cm⁻¹, from 100 cm⁻¹ to 15000 cm⁻¹, from 100 cm⁻¹ to 14000 cm⁻¹, from 100 cm⁻¹ to 13000 cm⁻¹, from 100 cm⁻¹ to 12000 cm⁻¹, from 100 cm⁻¹ to 11000 cm⁻¹, from 100 cm⁻¹ to 10000 cm⁻¹, from 100 cm⁻¹ to 9000 cm⁻¹, from 100 cm⁻¹ to 8000 cm⁻¹, from 100 cm⁻¹ to 7000 cm⁻¹, from 100 cm⁻¹ to 6000 cm⁻¹, from 100 cm⁻¹ to 5000 cm⁻¹, from 100 cm⁻¹ to 4000 cm⁻¹, from 100 cm⁻¹ to 3000 cm⁻¹, from 100 cm⁻¹ to 2000 cm⁻¹, from 100 cm⁻¹ to 1000 cm⁻¹, or from 100 cm⁻¹ to 500 cm⁻¹.

According to one embodiment, the photoactive layer 34 has a thickness of at least 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 55 nm, 60 nm, 65 nm, 70 nm, 75 nm, 80 nm, 85 nm, 90 nm, 95 nm, 100 nm, 105 nm, 110 nm, 115 nm, 120 nm, 125 nm, 130 nm, 135 nm, 140 nm, 145 nm, 150 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, or 1 μm.

According to one embodiment, the photoactive layer 34 is conducting holes.

According to one embodiment, the photoactive layer 34 is conducting electrons.

According to one embodiment illustrated in FIG. 30D, the photoactive layer 34 is ambipolar. In this embodiment, said photoactive layer 34 exhibits both electron and hole mobility.

According to one embodiment, the photoactive layer 34 has a hole mobility higher than 10⁻⁴ cm²V⁻¹s⁻¹, 10⁻³ cm²V⁻¹s⁻¹, 10⁻² cm²V⁻¹s⁻¹, 10⁻¹ cm²V⁻¹s⁻¹, 1 cm²V⁻¹s⁻¹, 10 cm²V⁻¹s⁻¹, 20 cm²V⁻¹s⁻¹, 30 cm²V⁻¹s⁻¹, 40 cm²V⁻¹s⁻¹, or 50 cm²V⁻¹s⁻¹.

According to one embodiment, the photoactive layer 34 has an electron mobility higher than 10⁻⁴ cm²V⁻¹s⁻¹, 10⁻³ cm²V⁻¹s⁻¹, 10⁻² cm²V⁻¹s⁻¹, 10⁻¹ cm²V⁻¹s⁻¹, 1 cm²V⁻¹s⁻¹, 10 cm²V⁻¹s⁻¹, 20 cm²V⁻¹s⁻¹, 30 cm²V⁻¹s⁻¹, 40 cm²V⁻¹s⁻¹, or 50 cm²V⁻¹s⁻¹.

According to one embodiment, the photoactive layer 34 has a ratio of electron mobility over hole mobility ranging from 10⁻² to 100, from 10⁻¹ to 100, from 1 to 100, from 10 to 100, or from 10⁻¹ to 10.

According to one embodiment illustrated in FIG. 30C, the photoactive layer 34 has a urbach energy ranging from 25 to 75 meV at room temperature, from 25 to 50 meV, or from 25 to 40 meV.

According to one embodiment, the photoactive layer 34 is cooled down by a Peltier device, a cryogenic cooler, using liquid nitrogen, or using liquid helium.

According to one embodiment, the photoactive layer 34 is operated from 1.5K to 350K, preferably from 4K to 310K, more preferably from 70K to 300K.

According to one embodiment, the photoactive layer 34 is illuminated by the front side.

According to one embodiment, the photoactive layer 34 is illuminated by the back side (through a transparent substrate).

According to one embodiment, the photoactive layer 34 is used as infrared emitting layer.

According to one embodiment, the photoactive layer 34 has a photoresponse from 1 A.W⁻¹ to 1 kA.W⁻¹, from 1 mA.W⁻¹ to 50 A.W⁻¹, more preferably from 10 mA.W⁻¹ to 10 A.W⁻¹.

According to one embodiment illustrated in FIG. 28C, the photoactive layer 34 has a noise current density limited by 1/f noise.

According to one embodiment, the photoactive layer 34 has a noise current density limited by Johnson noise.

According to one embodiment illustrated in FIG. 28F, the photoactive layer 34 as a specific detectivity from 10⁶ to 10¹⁴ jones, more preferably from 10⁷ to 10¹³ jones and even more preferably from 10⁸ to 5×10¹² jones.

According to one embodiment illustrated in FIG. 28B, the photoactive layer 34 has a bandwidth higher than 1 Hz, more preferably higher than 10 Hz, 20 Hz, 30 Hz, 40 Hz, 50 Hz, 60 Hz, 70 Hz, 80 Hz, 100 Hz, 110 Hz, 120 Hz, 130 Hz, 140 Hz, 150 Hz, 160 Hz, 170 Hz, 180 Hz, 190 Hz, 200 Hz, 210 Hz, 220 Hz, 230 Hz, 240 Hz, 250 Hz, 260 Hz, 270 Hz, 280 Hz, 290 Hz, 300 Hz, 350 Hz, 400 Hz, 450 Hz, 500 Hz, 550 Hz, 600 Hz, 650 Hz, 700 Hz, 750 Hz, 800 Hz, 850 Hz, 900 Hz, 950 Hz, or 1 kHz.

According to one embodiment, the photoactive layer 34 has a size compatible with the targeted detection wavelength.

According to one embodiment, the photoactive layer 34 has a size larger than the targeted detection wavelength.

According to one embodiment, the photoactive layer 34 is structured to better extract the hole carriers.

According to one embodiment, the photoactive layer 34 is a multilayer structure.

According to one embodiment, the photoactive layer 34 is a multilayer structure comprising a p-type material layer and an ambipolar material layer.

According to one embodiment illustrated in FIG. 36B, the photoactive layer 34 is a multilayer structure comprising a p-type HgTe layer and an ambipolar HgTe layer. In this embodiment, the structuration of the photoactive layer 34 helps to guide and extract the hole carriers.

According to one embodiment, the hole transport layer 35 is used to extract holes from the photoactive layer.

According to one embodiment, the hole transport layer 35 has a work function higher than 4.7 eV, 4.8 eV, 4.9 eV, or 5.0 eV.

According to one embodiment, the hole transport layer 35 has a thickness of at least 1 nm, 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 21 nm, 22 nm, 23 nm, 24 nm, 25 nm, 26 nm, 27 nm, 28 nm, 29 nm, 30 nm, 31 nm, 32 nm, 33 nm, 34 nm, 35 nm, 36 nm, 37 nm, 38 nm, 39 nm, 40 nm, 41 nm, 42 nm, 43 nm, 44 nm, 45 nm, 46 nm, 47 nm, 48 nm, 49 nm, 50 nm, 55 nm, 60 nm, 65 nm, 70 nm, 75 nm, 80 nm, 85 nm, 90 nm, 95 nm, 100 nm, 105 nm, 110 nm, 115 nm, 120 nm, 125 nm, 130 nm, 135 nm, 140 nm, 145 nm, 150 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, or 1 μm.

According to one embodiment, the hole transport layer 35 comprises an inorganic material.

According to one embodiment, the hole transport layer 35 comprises a p-type oxide.

According to one embodiment, the hole transport layer 35 comprises molybdenum trioxide MoO₃, vanadium pentoxide V₂O₅, tungsten trioxide WO₃, nickel oxide NiO, chromium oxide CrOₓ, rhenium oxide ReO₃, ruthenium oxide RuOₓ, cuprous oxide Cu₂O, cupric oxide CuO, or a mixture thereof; wherein x is a decimal number ranging from 0 to 5.

According to one embodiment, the hole transport layer 35 comprises graphene oxide GO, copper iodide CuI, copper(I) thiocyanate CuSCN, or a mixture thereof.

According to one embodiment, the hole transport layer 35 comprises a p-type polymer.

According to one embodiment, examples of p-type polymer include but are not limited to: poly(3-hexylthiophene) (P3HT), poly(3,4-ethylenedioxythiophene) (PEDOT), polystyrene sulfonate (PSS), poly(3,4-ethylenedioxythiophene):poly(4-styrenesulfonate) PEDOT:PSS, poly(9-vinylcarbazole) (PVK), N,N′-Bis(3-methylphenyl)-N,N′-diphenylbenzidine based-polymer, ammonium heptamolybdate (NH₄)₆Mo₇O₂₄.4H₂O, poly(4-butyl-phenyl-diphenyl-amine), N,N′-diphenyl-N,N′-bis(3-methylphenyl)-1,1′-diphenyl-4,4′-diamine, 4,4′,4″-tris(Ncarbazolyl)-triphenyl-amine (TCTA), 4,4′-bis(carbazole-9-yl)-biphenyl (CB P) , vanadylphthalocyanine (VOPc), 4,4′,4′-tris(3-methylphenylphenylamino)triphenylamine, or a mixture thereof.

According to one embodiment, the hole transport layer 35 has a transparency higher than 80%, preferably higher than 90%, more preferably higher than 95% in the infrared range, in the near infrared range, in the short wave infrared range, in the mid wave infrared range, in the long wave infrared range, in the mid infrared range, in the far infrared range, and/or in the THz range.

According to one embodiment, the hole transport layer 35 has a hole mobility higher than 10⁻⁴ cm²V⁻¹s⁻¹, 10⁻³ cm²V⁻¹s⁻¹, 10⁻² cm²V⁻¹s⁻¹, 10⁻¹ cm²V⁻¹s⁻¹, 1 cm²V⁻¹s⁻¹, 10 cm²V⁻¹s⁻¹, 20 cm²V⁻¹s⁻¹, 30 cm²V⁻¹s⁻¹, 40 cm²V⁻¹s⁻¹, or 50 cm²V⁻¹S⁻¹.

According to one embodiment, the encapsulating layer 36 is a capping layer as described hereabove.

According to one embodiment illustrated in FIG. 31A, the photoactive layer 34 presents a non monotonic cooling curve (current as a function of temperature) once exposed to air. In this embodiment, the presence of the at least one encapsulating layer 36 allows to obtain a monotonic cooling curve (ie current as a function of temperature) once exposed to air (illustrated in FIG. 31B).

According to one embodiment, the at least one encapsulating layer 36 preserves the photoactive layer 34 and the device 3 performances obtained in air free environment while the device 3 is operated in air.

According to one embodiment, the photoactive layer 34 experiences an increase of its dark conductance while exposed to air. In this embodiment, the presence of the at least one encapsulating layer 36 reduces said increase upon exposition to air.

According to one embodiment, the at least one encapsulating layer 36 helps stabilize the device 3 so that said encapsulated device 3 has air stable properties.

According to one embodiment, the at least one encapsulating layer 36 allows to obtain device activation energy extracted from the cooling curve above 50 meV, preferably above 100 meV.

According to one embodiment, the at least one encapsulating layer 36 allows to obtain device activation energy extracted from the cooling curve which value is between 1/10 th and 1 time the value of the optical band gap.

According to one embodiment, the at least one encapsulating layer 36 allows to obtain device activation energy extracted from the cooling curve which value is between ¼th and ½ th of the optical band gap.

According to one embodiment illustrated in FIG. 33, the at least one encapsulating layer 36 allows to keep unchanged the dark current level in air operation for at least 3 months, 100 days, 4 months, 5 months, 6 months, 7 months, 8 months, 9 months, 10 months, 11 months, 12 months, 2 years, 2.5 years, 3 years, 3.5 years, 4 years, 4.5 years, or 5 years.

According to one embodiment, the at least one encapsulating layer 36 covers partially or totally the second electronic contact layer 322.

According to one embodiment, the at least one encapsulating layer 36 covers and surrounds partially or totally the second electronic contact layer 322.

According to one embodiment, the at least one encapsulating layer 36 is deposited by atomic layer deposition, chemical bath deposition, or any other method known by the skilled artisan.

According to one embodiment, the at least one encapsulating layer 36 is deposited at low temperature to avoid any aggregation of the nanocrystals comprised the photoactive layer 34.

According to one embodiment, the at least one encapsulating layer 36 is deposited at low temperature to avoid any change of the optical spectrum of the device 3.

According to one embodiment, the at least one encapsulating layer 36 is deposited at temperature below 200° C., 190° C., 180° C., 170° C., 160° C., 150° C., 140° C., 130° C., 120° C., 110° C., 100° C., 90° C., 80° C., 70° C., 60° C., 50° C., or 40° C.

According to one embodiment, the at least one encapsulating layer 36 has a thickness of at least 1 nm, 1.5 nm, 2 nm, 2.5 nm, 3 nm, 3.5 nm, 4 nm, 4.5 nm, 5 nm, 5.5 nm, 6 nm, 6.5 nm, 7 nm, 7.5 nm, 8 nm, 8.5 nm, 9 nm, 9.5 nm, 10 nm, 10.5 nm, 11 nm, 11.5 nm, 12 nm, 12.5 nm, 13 nm, 13.5 nm, 14 nm, 14.5 nm, 15 nm, 15.5 nm, 16 nm, 16.5 nm, 17 nm, 17.5 nm, 18 nm, 18.5 nm, 19 nm, 19.5 nm, 20 nm, 30 nm, 40 nm, 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 21 μm, 22 μm, 23 μm, 24 μm, 25 μm, 26 μm, 27 μm, 28 μm, 29 μm, 30 μm, 31 μm, 32 μm, 33 μm, 34 μm, 35 μm, 36 μm, 37 μm, 38 μm, 39 μm, 40 μm, 41 μm, 42 μm, 43 μm, 44 μm, 45 μm, 46 μm, 47 μm, 48 μm, 49 μm, 50 μm, 51 μm, 52 μm, 53 μm, 54 μm, 55 μm, 56 μm, 57 μm, 58 μm, 59 μm, 60 μm, 61 μm, 62 μm, 63 μm, 64 μm, 65 μm, 66 μm, 67 μm, 68 μm, 69 μm, 70 μm, 71 μm, 72 μm, 73 μm, 74 μm, 75 μm, 76 μm, 77 μm, 78 μm, 79 μm, 80 μm, 81 μm, 8.2 μm, 83 μm, 84 μm, 85 μm, 86 μm, 87 μm, 88 μm, 89 μm, 90 μm, 91 μm, 92 μm, 93 μm, 94 μm, 95 μm, 96 μm, 97 μm, 98 μm, 99 μm, 100 μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, 1 mm, 1.5 mm, 2 mm, 2.5 mm, 3 mm, 3.5 mm, 4 mm, 4.5 mm, 5 mm, 5.5 mm, 6 mm, 6.5 mm, 7 mm, 7.5 mm, 8 mm, 8.5 mm, 9 mm, 9.5 mm, or 10 mm

According to one embodiment, the at least one encapsulating layer 36 has a transparency higher than 70%, preferably higher than 85%, more preferably higher than 90% in the infrared range, in the near infrared range, in the short wave infrared range, in the mid wave infrared range, in the long wave infrared range, in the mid infrared range, in the far infrared range, and/or in the THz range.

According to one embodiment, the at least one encapsulating layer 36 is an O₂ insulating layer.

According to one embodiment, the at least one encapsulating layer 36 is a H₂O insulating layer.

According to one embodiment, the at least one encapsulating layer 36 protects the photoactive layer 34 as it is sensitive to air exposure.

According to one embodiment, the at least one encapsulating layer 36 protects the photoactive layer 34 and the device 3 from O₂, O₃, CO₂ and/or H₂O.

According to one embodiment, the at least one encapsulating layer 36 is a O₂ barrier.

According to one embodiment, the at least one encapsulating layer 36 is a H₂O barrier.

According to one embodiment, the at least one encapsulating layer 36 is a O₃ barrier.

According to one embodiment, at least one encapsulating layer 36 is a CO₂ barrier.

According to one embodiment, the at least one encapsulating layer 36 is a stack of at least 3 layers (361, 362, 363), each of them behaving as a barrier for different molecular species or fluids (liquid or gas).

According to one embodiment, the first encapsulating layer 361 protects the photoactive layer 34 and the device 3 from O₂, O₃, CO₂ and/or H₂O.

According to one embodiment, the first encapsulating layer 361 allows the device 3 to have a flatten and smoothen surface.

According to one embodiment, the first encapsulating layer 361 behaves as a water repellant.

According to one embodiment, the second encapsulating layer 362 protects the photoactive layer 34 and the device 3 from O₂, O₃, CO₂ and/or H₂O.

According to one embodiment, the second encapsulating layer 362 protects the photoactive layer 34 and the device 3 from O₂.

According to one embodiment, the second encapsulating layer 362 is a O₂ barrier.

According to one embodiment, the second encapsulating layer 362 behaves as an oxygen repellant.

According to one embodiment, the third encapsulating layer 363 protects the photoactive layer 34 and the device 3 from O₂, O₃, CO₂ and/or H₂O.

According to one embodiment, the third encapsulating layer 363 protects the photoactive layer 34 and the device 3 from H₂O.

According to one embodiment, the third encapsulating layer 363 is a H₂O barrier.

According to one embodiment, the third encapsulating layer 363 behaves as a water repellant.

According to one embodiment, the at least one encapsulating layer 36 is an inorganic layer.

According to one embodiment, examples of inorganic layer include but are not limited to: ZnO, ZnS, ZnSe, Al₂O₃, SiO₂, TiO₂, ZrO₂, MgO, SnO₂, IrO₂, As₂S₃, As₂Se₃, or a mixture thereof.

According to one embodiment, the at least one encapsulating layer 36 comprises a wide band gap semiconductor material.

According to one embodiment, examples of wide band gap semiconductor material include but are not limited to: CdS, ZnO, ZnS, ZnSe, or a mixture thereof.

According to one embodiment, the at least one encapsulating layer 36 comprises an insulating material.

According to one embodiment, examples of insulating material include but are not limited to: SiO₂, HfO₂, Al₂O₃, or a mixture thereof.

According to one embodiment, the at least one encapsulating layer 36 is a polymer layer.

According to one embodiment, the encapsulating layer 36 comprises or consists of epoxy.

According to one embodiment, the at least one encapsulating layer 36 comprises a fluorinated polymer, such as for example polyvinylidene fluoride (PVDF) or a derivative of PVDF.

According to one embodiment, examples of polymer include but are not limited to: silicon based polymer, polyethylene terephthalate (PET), poly(methyl methacrylate) (PMMA), poly(lauryl methacrylate) (PMA), poly(maleic anhydride-alt- 1-octadecene) (PMAO), glycolized poly(ethylene terephthalate), polyvinyl alcohol (PVA), or mixture thereof.

According to one embodiment, the first encapsulating layer 361 comprises poly(methyl methacrylate) (PMMA), poly(lauryl methacrylate) (PMA), poly(maleic anhydride-alt-1-octadecene) (PMAO) or a mixture thereof.

According to one embodiment, the first encapsulating layer 361, the second encapsulating layer 362 and/or the third encapsulating layer 363 have a thickness of at least 1 nm, 1.5 nm, 2 nm, 2.5 nm, 3 nm, 3.5 nm, 4 nm, 4.5 nm, 5 nm, 5.5 nm, 6 nm, 6.5 nm, 7 nm, 7.5 nm, 8 nm, 8.5 nm, 9 nm, 9.5 nm, 10 nm, 10.5 nm, 11 nm, 11.5 nm, 12 nm, 12.5 nm, 13 nm, 13.5 nm, 14 nm, 14.5 nm, 15 nm, 15.5 nm, 16 nm, 16.5 nm, 17 nm, 17.5 nm, 18 nm, 18.5 nm, 19 nm, 19.5 nm, 20 nm, 30 nm, 40 nm, 50 nm, 60 nm, 70 nm, 80 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm, 290 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1 μm, 1.5 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 21 μm, 22 μm, 23 μm, 24 μm, 25 μm, 26 μm, 27 μm, 28 μm, 29 μm, 30 μm, 31 μm, 32 μm, 33 μm, 34 μm, 35 μm, 36 μm, 37 μm, 38 μm, 39 μm, 40 μm, 41 μm, 42 μm, 43 μm, 44 μm, 45 μm, 46 μm, 47 μm, 48 μm, 49 μm, 50 μm, 51 μm, 52 μm, 53 μm, 54 μm, 55 μm, 56 μm, 57 μm, 58 μm, 59 μm, 60 μm, 61 μm, 62 μm, 63 μm, 64 μm, 65 μm, 66 μm, 67 μm, 68 μm, 69 μm, 70 μm, 71 μm, 72 μm, 73 μm, 74 μm, 75 μm, 76 μm, 77 μm, 78 μm, 79 μm, 80 μm, 81 μm, 8.2 μm, 83 μm, 84 μm, 85 μm, 86 μm, 87 μm, 88 μm, 89 μm, 90 μm, 91 μm, 92 μm, 93 μm, 94 μm, 95 μm, 96 μm, 97 μm, 98 μm, 99 μm, 100μm, 200 μm, 250 μm, 300 μm, 350 μm, 400 μm, 450 μm, 500 μm, 550 μm, 600 μm, 650 μm, 700 μm, 750 μm, 800 μm, 850 μm, 900 μm, 950 μm, 1 mm, 1.5 mm, 2 mm, 2.5 mm, 3 mm, 3.5 mm, 4 mm, 4.5 mm, 5 mm, 5.5 mm, 6 mm, 6.5 mm, 7 mm, 7.5 mm, 8 mm, 8.5 mm, 9 mm, 9.5 mm, or 10 mm

According to one embodiment, the first encapsulating layer 361 has a thickness of 1.3 μm.

According to one embodiment, the second encapsulating layer 362 had a thickness of 500 nm.

According to one embodiment, the third encapsulating layer 363 has a thickness of 500 nm.

According to one embodiment, the first encapsulating layer 361 has a transparency higher than 70%, preferably higher than 85%, more preferably higher than 90% in the infrared range, in the near infrared range, in the short wave infrared range, in the mid wave infrared range, in the long wave infrared range, in the mid infrared range, in the far infrared range, and/or in the THz range.

According to one embodiment, the second encapsulating layer 362 comprises polyvinyl alcohol (PVA).

According to one embodiment, the second encapsulating layer 362 has a transparency higher than 70%, preferably higher than 85%, more preferably higher than 90% in the infrared range, in the near infrared range, in the short wave infrared range, in the mid wave infrared range, in the long wave infrared range, in the mid infrared range, in the far infrared range, and/or in the THz range.

According to one embodiment, the third encapsulating layer 363 comprises a fluorinated polymer, such as for example polyvinylidene fluoride (PVDF) or a derivative of PVDF.

According to one embodiment, the third encapsulating layer 363 has a transparency higher than 70%, preferably higher than 85%, more preferably higher than 90% in the infrared range, in the near infrared range, in the short wave infrared range, in the mid wave infrared range, in the long wave infrared range, in the mid infrared range, in the far infrared range, and/or in the THz range.

According to one embodiment illustrated in FIG. 34B-D, the at least one encapsulating layer 36 comprises a first 1.3 μm PMMA layer 361, a second 500 nm PVA layer 362 and a third 500 nm PVDF layer 363.

According to one embodiment, the at least one encapsulating layer 36 consists of a first 1.3 μm PMMA layer 361, a second 500 nm PVA layer 362 and a third 500 nm PVDF layer 363.

According to one embodiment, the first encapsulating layer 361 comprises PMMA, the second encapsulating layer 362 comprises PVA, and/or the third encapsulating layer 363 comprises PVDF.

According to one embodiment, the first encapsulating layer 361 is a PMMA layer, the second encapsulating layer 362 is a PVA layer, and/or the third encapsulating layer 363 is a PVDF layer.

According to one embodiment, the device 3 comprises a substrate 31; a first gold layer; a HgTe layer; and a second gold layer; wherein the layers are successively overlaid on the substrate and on each other.

According to one embodiment, the device 3 comprises a substrate 31; a first Pt layer; a HgTe layer; and a second Pt layer; wherein the layers are successively overlaid on the substrate and on each other.

According to one embodiment, the device 3 comprises a substrate 31; a first Al layer; a HgTe layer; and a second Al layer; wherein the layers are successively overlaid on the substrate and on each other.

According to one embodiment, the device 3 comprises a substrate 31; a first Ag layer; a HgTe layer; and a second Ag layer; wherein the layers are successively overlaid on the substrate and on each other.

According to one embodiment illustrated in FIG. 35A-C, the device 3 comprises a substrate 31; an ITO layer; a TiO₂ layer; a HgTe layer and a gold layer; wherein the layers are successively overlaid on the substrate and on each other.

According to one embodiment, the device 3 comprises a substrate 31; a FTO layer; a TiO₂ layer; a HgTe layer and a gold layer; wherein the layers are successively overlaid on the substrate and on each other.

According to one embodiment, the device 3 comprises a substrate 31; a ITO layer; a ZnO layer; a HgTe layer and a gold layer; wherein the layers are successively overlaid on the substrate and on each other.

According to one embodiment, the device 3 comprises a substrate 31; a FTO layer; a ZnO layer; a HgTe layer and a gold layer; wherein the layers are successively overlaid on the substrate and on each other.

According to one embodiment, the device 3 comprises a substrate 31; a FTO layer; a ZnO layer; a HgTe layer; a MoO₃ layer and a gold layer; wherein the layers are successively overlaid on the substrate and on each other.

According to one embodiment illustrated in FIG. 36A, the device 3 comprises a substrate 31; a ITO layer; a ZnO layer; a HgTe layer; a MoO₃ layer and a gold layer; wherein the layers are successively overlaid on the substrate and on each other.

According to one embodiment, the device 3 comprises a substrate 31; a FTO layer; a ZnO layer; a HgTe layer; a MoO₃ layer and a Pt layer; wherein the layers are successively overlaid on the substrate and on each other.

According to one embodiment illustrated in FIG. 36B, the device 3 comprises a substrate 31; a ITO layer; a ZnO layer; a HgTe (narrow gap and ambipolar) layer; a HgTe (wide gap and p-type) layer; a MoO₃ layer and a gold layer; wherein the layers are successively overlaid on the substrate and on each other. This configuration of the device 3 allows to obtain an enhanced hole extraction.

According to one embodiment, the device 3 comprises a substrate 31; an Al layer; a ZnO layer; a HgTe layer; a MoO₃ layer and an Au layer; wherein the layers are successively overlaid on the substrate and on each other.

According to one embodiment, the device 3 comprises a substrate 31; an Ag layer; a ZnO layer; a HgTe layer; a MoO₃ layer and an Au layer; wherein the layers are successively overlaid on the substrate and on each other.

According to one embodiment, the device 3 comprises a substrate 31; an Al layer; a TiO₂ layer; a HgTe layer; a MoO₃ layer and an Au layer; wherein the layers are successively overlaid on the substrate and on each other.

According to one embodiment, the device 3 comprises a substrate 31; an Ag layer; a TiO₂ layer; a HgTe layer; a MoO₃ layer and an Au layer; wherein the layers are successively overlaid on the substrate and on each other.

According to one embodiment, the device in vertical geometry include an absorbing semiconductor nanocrystals layer which is prepared from a semiconductor nanocrystals ink.

According to one embodiment, the device in vertical geometry include an absorbing quantum dots layer which is prepared from a quantum dots ink.

According to one embodiment, a semiconductor nanocrystals ink is a ligand exchange suspension of nanocrystals which can be directly deposited to build a photoconductive layer of nanocrystals without additional ligand exchange step.

According to one embodiment, a quantum dots ink is a ligand exchange solution of quantum dots which can be directly deposited to build a photoconductive layer of quantum dots without additional ligand exchange step.

According to one embodiment, a semiconductor nanocrystals ink is prepared by phase transfer method.

According to one embodiment, a quantum dots ink is prepared by phase transfer method.

According to one embodiment, the solvent of the ink is a polar solvent with a low boiling pont such as for example acetonitrile, propylamine, 2,6 difluoropyridine, or a mixture thereof.

According to one embodiment, the solvent of the ink is a pyridine derivative.

According to one embodiment, the solvent of the ink is a primary amine with a shirt alkyl chain (<C4).

According to one embodiment, the device is an intraband photodiode.

According to one embodiment, the device has interband absorption at high energy and intraband absorption for longer wavelengths in the infrared.

According to one embodiment, the device with intraband absorption is a photodiode.

According to one embodiment, the photodiode with intraband absorption, i.e. the intraband photodiode, further comprises a unipolar barrier 42. Said unipolar barrier selectively lets one carrier flow, while blocking the other type of carrier.

According to one embodiment illustrated in FIG. 40, the device comprises a first contact 41, a unipolar barrier 42, a photoactive layer 34 and a second contact 43.

According to one embodiment, the unipolar barrier is as described hereabove.

In another aspect, the present invention also relates to a method for manufacturing a device 3 of the invention, said method comprising:
preparing at least one substrate 31;
depositing on top of said substrate 31 at least one electronic contact layer 32;
depositing on top of said electronic contact layer 32 at least one electron transport layer 33; and
depositing on top of said electron transport layer 33 at least one photoactive layer 34.

The device 3, substrate 31, electronic contact layer 32, electron transport layer 33, photoactive layer 34, hole transport layer 35, encapsulating layer 36 are as described hereabove.

According to one embodiment, each layer of the device 3 is deposited successively on the substrate 31.

According to one embodiment, a second electronic contact layer 322 is deposited on top of the at least one photoactive layer 34.

According to one embodiment, at least one hole transport layer 35 is deposited on top of the at least one photoactive layer 34. In this embodiment, if the device 3 comprises a second electronic contact layer 322, it will be deposited on top of said hole transport layer 35.

According to one embodiment, at least one encapsulating layer 36 is deposited on top of the last deposited layer of the device 3.

According to one embodiment, three encapsulating layers (361, 362, 363) are deposited successively on top of the last deposited layer of the device 3.

According to one embodiment, a plurality of encapsulating layers 36 are deposited successively on top of the last deposited layer of the device 3.

According to one embodiment, each layer of the device 3 is deposited by spin coating, dropcasting, dip coating, electrophoretic method, atomic layer deposition, chemical bath deposition, or any other method known by the skilled artisan.

According to one embodiment, each layer of the device 3 is deposited at low temperature to avoid any aggregation of the nanocrystals comprised the photoactive layer 34.

According to one embodiment, each layer of the device 3 is deposited at low temperature to avoid any change of the optical spectrum of the device 3.

According to one embodiment, each layer of the device 3 is deposited at temperature below 200° C., 190° C., 180° C., 170° C., 160° C., 150° C., 140° C., 130° C., 120° C., 110° C., 100° C., 90° C., 80° C., 70° C., 60° C., 50° C., 40° C., or 30° C.

According to one embodiment, each layer of the device 3 is deposited at room temperature.

According to one embodiment, the method further comprises a ligand exchange step performed on the photoactive layer 34.

According to one embodiment, the ligand exchange step is a solid state ligand exchange.

According to one embodiment, the solid state ligand exchange is made by dipping a photoactive layer 34 in a solution containing an excess of the new capping ligand.

According to one embodiment, the ligand exchange step is a liquid phase ligand exchange.

According to one embodiment, the ligand exchange step is performed after the deposition of said photoactive layer 34.

According to one embodiment, the method further comprises an annealing step performed on the photoactive layer 34.

According to one embodiment, the annealing temperature ranges from 0° C. to 300° C., from 20° C. to 300° C., from 40° C. to 300° C., from 60° C. to 300° C., from 80° C. to 300° C., from 100° C. to 300° C., from 120° C. to 300° C., from 140° C. to 300° C., from 160° C. to 300° C., from 180° C. to 300° C., from 200° C. to 300° C., from 220° C. to 300° C., from 240° C. to 300° C., from 260° C. to 300° C., from 280° C. to 300° C.; from 0° C. to 300° C., from 0° C. to 280° C., from 0° C. to 260° C., from 0° C. to 240° C., from 0° C. to 220° C., from 0° C. to 200° C., from 0° C. to 180° C., from 0° C. to 160° C., from 0° C. to 140° C., from 0° C. to 120° C., from 0° C. to 100° C., from 0° C. to 80° C., from 0° C. to 60° C., from 0° C. to 40° C., or from 0° C. to 20° C.

According to one embodiment, the annealing step is performed after the deposition of said photoactive layer 34.

According to one embodiment, the method is conducted in air free condition.

According to one embodiment, the method is performed in a glove box.

According to one embodiment illustrated in FIG. 37B, the photoactive layer 34 is etched to form a pixel or an array of pixels.

According to one embodiment, the photoactive layer 34 is etched using wet chemical etching, plasma etching, O₂ plasma etching, Ar plasma etching, or any other method known in the art.

FIG. 37A-B illustrate a HgTe photoactive layer etched using O₂ plasma etching.

According to one embodiment, the photoactive layer 34 is etched to form a pixel or an array of pixels which area ranges from 100 nm² to 1 m², preferably from 1 μm² to 1 cm² and even more preferably from 10 μm² to 10 000 μm².

According to one embodiment, the pixel or array of pixels is as described hereabove.

According to one embodiment, the device 3 is used as a flame detector.

According to one embodiment, the device 3 is used as a photodetector allowing bicolor detection.

According to one embodiment, the device 3 is used as a photodetector allowing multicolor detection.

In another aspect, the present invention also relates to a device comprising:
at least one substrate 31;
at least one electronic contact layer 32; and
at least one photoactive layer 34;

wherein said device has a photoconductive geometry.

A photoconductive geometry refers to a planar geometry.

According to one embodiment, the device comprises at least two electronic contact layers (321, 322).

According to one embodiment, the device further comprises at least one encapsulating layer 36.

The encapsulation with the at least one encapsulating layer 36 enhances the stability of the device under air and/or humidity conditions, prevents the degradation of said device due to air and/or humidity exposure. Said encapsulation is not detrimental to the transport and/or optical properties of the device, and helps preserving said transport and/or optical properties of the device upon air and/or humidity exposure.

According to one embodiment, the device comprises a plurality of encapsulating layers 36.

According to one embodiment, the device comprises at least three encapsulating layers (361, 362, 363).

According to one embodiment, the device comprises three encapsulating layers (361, 362, 363).

According to one embodiment, the substrate 31 is as described hereabove.

According to one embodiment, the electronic contact layer 32 is as described hereabove.

According to one embodiment, the photoactive layer 34 is as described hereabove.

According to one embodiment, the at least two electronic contact layers (321, 322) are as described hereabove.

According to one embodiment, the encapsulating layer 36 is as described hereabove.

According to one embodiment, the device comprises a substrate 31; a first gold layer; a HgTe layer; and a second gold layer.

According to one embodiment, the device comprises a substrate 31; a first Pt layer; a HgTe layer; and a second Pt layer.

According to one embodiment, the device comprises a substrate 31; a first Al layer; a HgTe layer; and a second Al layer.

According to one embodiment, the device comprises a substrate 31; a first Ag layer; a HgTe layer; and a second Ag layer.

While various embodiments have been described and illustrated, the detailed description is not to be construed as being limited hereto. Various modifications can be made to the embodiments by those skilled in the art without departing from the true spirit and scope of the disclosure as defined by the claims

### BRIEF DESCRIPTION OF THE DRAWINGS

FIG. 1 is TEM images showing HgTe nanocrystals.

FIG. 1A is a TEM image showing HgTe nanocrystals.

FIG. 1B is a TEM image showing spherical HgTe nanocrystals.

FIG. 2 illustrates the absorption spectra of HgTe nanocrystals.

FIG. 2A illustrates the absorption spectrum of HgTe nanocrystals with different sizes.

FIG. 2B illustrates the absorption spectrum of HgTe nanocrystals of different sizes and presenting an absorption feature in the THz range.

FIG. 3 illustrates the cut off wavelength of the interband transition as a function of the nanocrystals size comparing nanocrystals of the present invention (stars) and nanocrystals of prior arts (circles and triangles).

FIG. 4 illustrates the size distribution for HgTe nanocrystals manufactured by the method of the invention at various temperatures and with different Hg precursors.

FIG. 5 illustrates the absorption spectrum and TEM images of HgTe nanocrystals manufactured by the method of the invention.

FIG. 5A illustrates the absorption spectrum of HgTe nanocrystals manufactured by the method of the invention with different ratio of the Hg and Te precursors.

FIG. 5B is a TEM image showing HgTe nanocrystals manufactured by the method of the invention with a ratio Hg:Te precursor of 1:1.

FIG. 5C is a TEM image showing HgTe nanocrystals manufactured by the method of the invention with a ratio Hg:Te precursor of 1.3:1.

FIG. 5D is a TEM image showing HgTe nanocrystals manufactured by the method of the invention with a ratio Hg:Te precursor of 1.6:1.

FIG. 6 illustrates absorption spectra and TEM images of HgS nanocrystals manufactured by the method of the invention.

FIG. 6A illustrates the absorption spectrum of HgS nanocrystals manufactured by the method of the invention with HgI2 as Hg precursor.

FIG. 6B is a TEM image showing HgS nanocrystals manufactured by the method of the invention with HgI2 as Hg precursor.

FIG. 6C illustrates the absorption spectrum of HgS nanocrystals manufactured by the method of the invention with HgCl₂ as Hg precursor.

FIG. 6D is a TEM image showing HgS nanocrystals manufactured by the method of the invention with HgCl₂ as Hg precursor.

FIG. 7 illustrates absorption spectra and TEM images of HgSe nanocrystals manufactured by the method of the invention.

FIG. 7A illustrates the absorption spectrum of HgSe nanocrystals manufactured by the method of the invention with HgI₂ as Hg precursor.

FIG. 7B is a TEM image showing HgSe nanocrystals manufactured by the method of the invention with HgI₂ as Hg precursor.

FIG. 7C illustrates the absorption spectrum of HgSe nanocrystals manufactured by the method of the invention with HgCl2 as Hg precursor.

FIG. 7D is a TEM image showing HgSe nanocrystals manufactured by the method of the invention with HgCl2 as Hg precursor.

FIG. 8 is a scheme of a dual (bottom and electrolytic) gated transistor based on a thin HgSe nanocrystals photoabsorptive film 2. The film has been deposited on a doped Si substrate 25 with a thin insulating SiO2 layer 1 on the top of said doped Si substrate 25. Metallic drain 22 and source 21 electrodes are deposited on the film using lithography method. On top of the nanocrystal photoabsorptive film 2, there is an electrolyte 23 which itself is covered by a metallic top gate electrode 24.

FIG. 9 illustrates transfer curves (current as a function of gate bias) for HgTe nanocrystals.

FIG. 9A illustrates transfer curves (current as a function of gate bias) for HgTe nanocrystals with an excitonic feature at 4000 cm⁻¹.

FIG. 9B illustrates transfer curves (current as a function of gate bias) for HgTe nanocrystals with a cut off at 2000 cm⁻¹.

FIG. 9C illustrates transfer curves (current as a function of gate bias) for HgTe nanocrystals with a plasmonic feature at 450 cm⁻¹.

FIG. 10 illustrates a TEM image and an infrared spectrum of HgSe nanocrystals.

FIG. 10A is a TEM image showing HgSe nanocrystals.

FIG. 10B illustrates an infrared spectrum of a HgSe nanocrystals film.

FIG. 11 illustrates a TEM image and an infrared spectrum of Ag₂Se nanocrystals.

FIG. 11A is a TEM image showing Ag₂Se nanocrystals.

FIG. 11B illustrates an infrared spectrum of a Ag₂Se nanocrystals film.

FIG. 12 illustrates TEM images showing nanocrystal cores and heterostructures.

FIG. 12A is a TEM image showing HgSe nanocrystal cores.

FIG. 12B is a TEM image showing HgSe/HgTe heterostructrures.

FIG. 12C is a TEM image showing HgSe/HgTe heterostructrures.

FIG. 13 illustrates infrared spectra and TEM images of HgTe cores and HgTe/HgSe hetero structures.

FIG. 13A illustrates an infrared spectrum of HgTe cores and HgTe/HgSe heterostructures, while 0.1 mmol of HgSe precursor have been introduced.

FIG. 13B is a TEM image showing HgTe/HgSe heterostructures, while 0.1 mmol of HgSe precursor have been introduced.

FIG. 13C illustrates an infrared spectrum of HgTe cores and HgTe/HgSe heterostructures, while 0.2 mmol of HgSe precursor have been introduced.

FIG. 13D is a TEM image showing HgTe/HgSe heterostructures, while 0.2 mmol of HgSe precursor have been introduced.

FIG. 13E illustrates an infrared spectrum of HgTe cores and HgTe/HgSe heterostructures, while 0.5 mmol of HgSe precursor have been introduced.

FIG. 13F is a TEM image showing HgTe/HgSe heterostructures, while 0.5 mmol of HgSe precursor have been introduced.

FIG. 13G illustrates an infrared spectrum of HgTe cores and HgTe/HgSe heterostructures, while 1 mmol of HgSe precursor have been introduced.

FIG. 13H is a TEM image showing HgTe/HgSe heterostructures, while 1 mmol of HgSe precursor have been introduced.

FIG. 14 illustrates a phase diagram for the band alignment of HgSe/HgTe heterostructure as a function of the core diameter and the HgTe shell thickness, and energy profiles and wavefunctions for different areas of the phase diagram.

FIG. 14A illustrates a phase diagram for the band alignment of HgSe/HgTe heterostructure as a function of the core diameter and the HgTe shell thickness. The red dashed line corresponds to the grown heterostructure later in the text.

FIG. 14B illustrates an energy profile and a wavefunction for area b of the phase diagram.

FIG. 14C illustrates an energy profile and a wavefunction for area c of the phase diagram.

FIG. 14D illustrates an energy profile and a wavefunction for area d of the phase diagram.

FIG. 14E illustrates an energy profile and a wavefunction for area e of the phase diagram.

FIG. 15 illustrates infrared spectra of HgSe/HgTe heterostrctures.

FIG. 15A illustrates an infrared spectrum of HgSe/HgTe heterostrcture for various amount of HgTe precursor introduced while the synthesis is conducted at 60° C.

FIG. 15B illustrates an infrared spectrum of HgSe/HgTe heterostrcture for various amount of HgTe precursor introduced while the synthesis is conducted at 80° C.

FIG. 15C illustrates an infrared spectrum of HgSe/HgTe heterostrcture for various amount of HgTe precursor introduced while the synthesis is conducted at 100° C.

FIG. 16 illustrates a size histogram obtained from TEM image of HgSe cores and for HgSe/HgTe heterostructures, and a deposited amount of HgTe on HgSe.

FIG. 16A illustrates a size histogram obtained from TEM image of HgSe cores and for HgSe/HgTe heterostructures (0.5 mmol of HgI₂ as Hg precursor and 80° C. as shell growth temperature.

FIG. 16B illustrates a deposited amount of HgTe on HgSe (in % of the total amount of material) obtained from XRD and from EDX as a function of the amount of introduced HgI₂.

FIG. 17 illustrates a transfer curve (drain and gate current as a function of the applied gate voltage at constant drain bias) for thin film of HgSe nanocrystals and HgSe/HgTe nanocrystals.

FIG. 17A illustrates a transfer curve (drain and gate current as a function of the applied gate voltage at constant drain bias) for thin film of HgSe nanocrystals.

FIG. 17B illustrates a transfer curve (drain and gate current as a function of the applied gate voltage at constant drain bias) for thin film of HgSe/HgTe nanocrystals for HgTe=0.1 mmol.

FIG. 17C illustrates a transfer curve (drain and gate current as a function of the applied gate voltage at constant drain bias) for thin film of HgSe/HgTe nanocrystals for HgTe=0.3 mmol.

FIG. 17D illustrates a transfer curve (drain and gate current as a function of the applied gate voltage at constant drain bias) for thin film of HgSe/HgTe nanocrystals for HgTe=0.4 mmol.

FIG. 17E illustrates a transfer curve (drain and gate current as a function of the applied gate voltage at constant drain bias) for thin film of HgSe/HgTe nanocrystals for HgTe=0.5 mmol.

FIG. 17F illustrates a transfer curve (drain and gate current as a function of the applied gate voltage at constant drain bias) for thin film of HgTe nanocrystals.

FIG. 18 illustrates the ratio of the electronic mobility over the hole mobility for HgSe/HgTe heterostructure with different amount of the two materials.

FIG. 19 illustrates a photoemission valence band signal for a thin film of HgSe nanocrystals.

FIG. 19A illustrates a photoemission valence band signal for a thin film of HgSe/HgTe heterostructure with 0.1 mmol of HgTe precursor introduced.

FIG. 19B illustrates a photoemission valence band signal for a thin film of HgSe/HgTe heterostructure with 0.4 mmol of HgTe precursor introduced.

FIG. 19C illustrates a photoemission valence band signal for a thin film of HgSe/HgTe heterostructure with 0.1 mmol of HgTe precursor introduced.

FIG. 20 illustrates a reconstructed electronic spectrum for HgSe core and HgSe/HgTe heterostructure in absolute energy scale.

FIG. 21 illustrates a current as a function of the temperature for thin film made of HgSe core and for thin film made of HgSe/HgTe heterostructure.

FIG. 22 illustrates temporal evolutions of the photoresponse and a bode diagram from a HgSe nanocrystals film and HgSe/HgTe heterostructure film while the light (4.4 μm QCL-16 mW of incident power) is modulated at 10 Hz.

FIG. 22A illustrates a temporal evolution of the photoresponse from a HgSe nanocrystals film while the light (4.4 μm QCL-16 mW of incident power) is modulated at 10 Hz.

FIG. 22B illustrates a temporal evolution of the photoresponse from a HgSe/HgTe heterostructure film while the light (4.4 μm QCL-8 mW of incident power) is modulated at 1 kHz.

FIG. 22C illustrates a bode diagram (normalized signal magnitude) as a function of the signal frequency for thin film made of HgSe core and thin film made of HgSe/HgTe heterostructure.

FIG. 23 illustrates an infrared spectrum of n-type HgTe nanocrystals and a transfer curve (drain and gate current as a function of the applied gate voltage at constant drain bias) for an electrolyte gated thin film of n-type HgTe.

FIG. 23A illustrates an infrared spectrum of n-type HgTe nanocrystals.

FIG. 23B illustrates a transfer curve (drain and gate current as a function of the applied gate voltage at constant drain bias) for an electrolyte gated thin film of n-type HgTe.

FIG. 24 illustrates an infrared spectrum of p-type HgTe nanocrystals, and a transfer curve (drain and gate current as a function of the applied gate voltage at constant drain bias) for an electrolyte gated thin film of p-type HgTe.

FIG. 24A illustrates an infrared spectrum of p-type HgTe nanocrystals.

FIG. 24B illustrates a transfer curve (drain and gate current as a function of the applied gate voltage at constant drain bias) for an electrolyte gated thin film of p-type HgTe.

FIG. 25 illustrates a device 3 comprising a substrate 31, two electronic contact layers 32, an electron transport layer 33, a photoactive layer 34.

FIG. 26 illustrates a device 3 comprising a substrate 31, two electronic contact layers (321, 322), a photoactive layer 34.

FIG. 27 illustrates the transfer curve (drain and gate current as a function of the applied gate voltage at constant drain bias) of the device 3 as a photodiode based on a HgTe nanocrystals film.

FIG. 28 illustrates the photocurrent as a function of time, a bode diagram of the photocurrent intensity, the noise current density as a function of frequency, the noise current density (at 100 Hz) as a function of applied bias, the responsivity as a function of the applied bias under blackbody illumination (T_{black body}=927° C.) and the room temperature detectivity at 100 Hz, as a function of the applied bias for a HgTe nanocrystals film.

FIG. 28A illustrates the photocurrent as a function of time for a HgTe nanocrystals film in a photoconductive configuration, while the light (λ=1.55 μm) is turned on and off with a frequency of 10 kHz.

FIG. 28B is a bode diagram of the photocurrent intensity for a HgTe nanocrystals film in a photoconductive configuration, as a function of the light chopping frequency.

FIG. 28C illustrates the noise current density as a function of frequency for a HgTe nanocrystals film in a photoconductive configuration under different biases.

FIG. 28D illustrates the noise current density (at 100 Hz) as a function of applied bias for a HgTe nanocrystals film in a photoconductive configuration.

FIG. 28E illustrates the responsivity as a function of the applied bias under blackbody illumination (T_{black body}=927° C.) for an a HgTe nanocrystals film in a photoconductive configuration.

FIG. 28F illustrates the room temperature detectivity at 100 Hz, as a function of the applied bias for a HgTe nanocrystals film in a photoconductive configuration.

FIG. 29 illustrates transmission spectra of a 1.1 mm glass slide without coating, and coated by 30 nm and 100 nm layer of ITO.

FIG. 30 illustrates TEM images of HgTe colloidal nanocrystals, a transfer curve (drain and gate current as a function of applied gate bias) of a HgTe nanocrystals based electrolyte gated transistor, a reconstructed electronic spectrum of HgTe nanocrystals film highlighting the position of vacuum, valence band, conduction band and the trap state distribution with respect to the fermi energy.

FIG. 30A is a TEM image of HgTe colloidal nanocrystals.

FIG. 30B is a high resolution TEM image showing HgTe colloidal nanocrystals having a tetrapodic shape.

FIG. 30C is a transfer curve (drain and gate current as a function of applied gate bias) of a HgTe nanocrystals based electrolyte gated transistor.

FIG. 30D is a reconstructed electronic spectrum of HgTe nanocrystals film highlighting the position of vacuum, valence band, conduction band and the trap state distribution with respect to the fermi energy.

FIG. 31 illustrates the current as a function of the temperature for a HgTe film with or without encapsulation.

FIG. 31A illustrates the current as a function of the temperature for a HgTe film without encapsulation.

FIG. 31B illustrates the current as a function of the temperature for a HgTe film with encapsulation.

FIG. 32 illustrates a device 3 comprising a substrate 31, two electronic contact layers (321, 322), a photoactive layer 34, and an encapsulating layer 36.

FIG. 33 illustrates the dark current as a function of time spent in air for a HgTe film in photoconductive mode, wherein the film is encapsulated by PMMA/PVA/PVDF encapsulating layers or non-encapsulated.

FIG. 34 illustrates a device 3 of the invention.

FIG. 34A illustrates a device 3 comprising a substrate 31, two electronic contact layers (321, 322), a photoactive layer 34, and three encapsulating layers (361, 362, 363).

FIG. 34B illustrates a device 3 comprising a substrate 31, two electronic contact layers (321, 322), a photoactive layer 34, and three encapsulating layers PMMA/PVA/PVDF.

FIG. 34C illustrates a device 3 comprising a substrate 31, two electronic contact layers (321, 322), an electron transport layer 33, a photoactive layer 34, and three encapsulating layers (361, 362, 363).

FIG. 34D illustrates a device 3 comprising a substrate 31, an ITO layer, a TiO₂ layer, a HgTe nanocrystals photoactive layer, a gold layer, and three encapsulating layers PMMA/PVA/PVDF.

FIG. 35 illustrates a device 3 of the invention.

FIG. 35A illustrates a device 3 comprising a substrate 31, an ITO layer, a TiO₂ layer, a HgTe nanocrystals photoactive layer, and a gold layer.

FIG. 35B is a SEM image of a device 3 comprising a substrate 31, an ITO layer, a TiO₂ layer, a HgTe nanocrystals photoactive layer, and a gold layer.

FIG. 35C is a picture of a device 3 comprising a HgTe nanocrystals photoactive layer, and gold electrodes.

FIG. 36 illustrates a device 3 of the invention.

FIG. 36A illustrates a device 3 comprising a substrate 31, an ITO layer, a ZnO layer, a HgTe nanocrystals photoactive layer, a MoO₃ layer and a gold layer.

FIG. 36B illustrates a device 3 comprising a substrate 31, an ITO layer, a ZnO layer, an ambipolar HgTe nanocrystals photoactive layer, a p-type HgTe nanocrystals photoactive layer, a MoO₃ layer and a gold layer.

FIG. 37 illustrates SEM images of a HgTe photoactive layer etched.

FIG. 37A is a SEM image of a HgTe photoactive layer etched using O₂ plasma etching to form the word NEXDOT.

FIG. 37B is a SEM image of a HgTe photoactive layer etched to form an array of pixels.

FIG. 38 illustrates a device 3 of the invention.

FIG. 38A illustrates a device 3 comprising a substrate 31, two electronic contact layers (321, 322), a photoactive layer 34, and contact pads 37.

FIG. 38B illustrates a device 3 comprising interdigitated electrodes 38 and contact pads 37.

FIG. 39 is an infrared transmission spectrum of a stack of encapsulating layers PMMA/PVA/PVDF.

FIG. 40 is a schematic representation of an intraband photodiode.

FIG. 41 shows the spectral photocurrent of an intraband photodiode at 80K under +1V and −1V.

FIG. 42 illustrates the conduction band profile of a mixture of HgSe and HgTe.

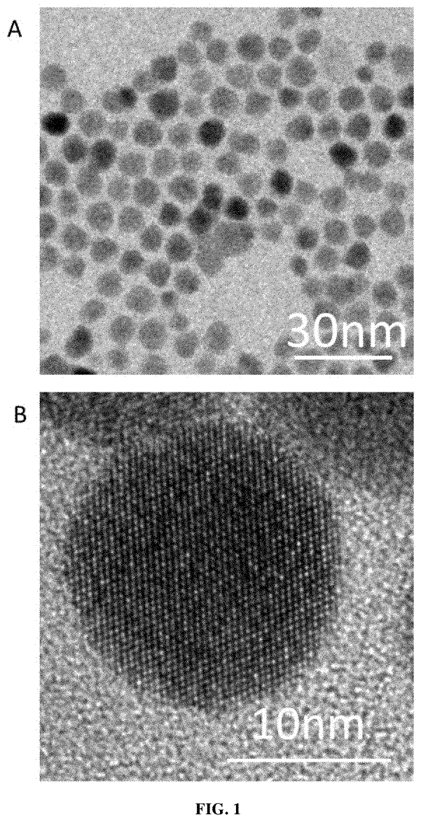

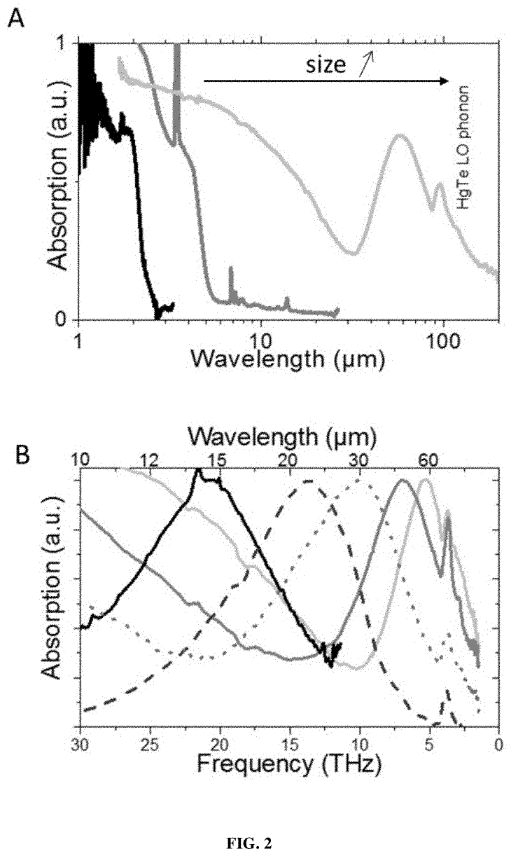

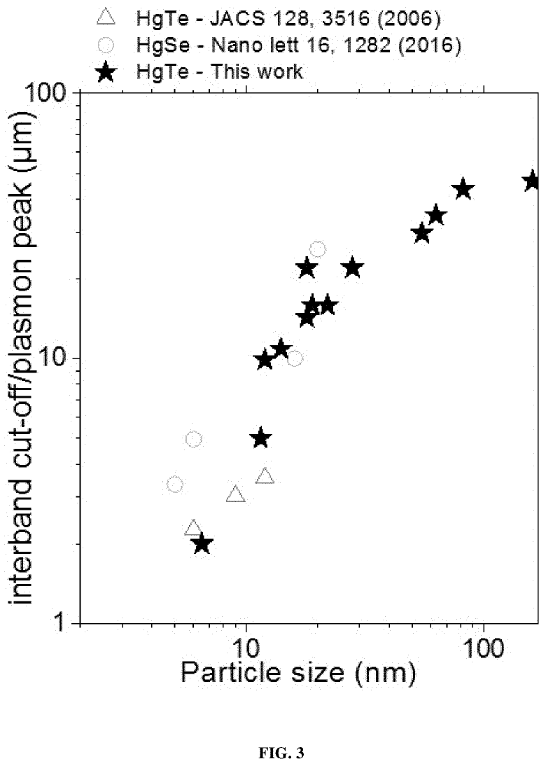

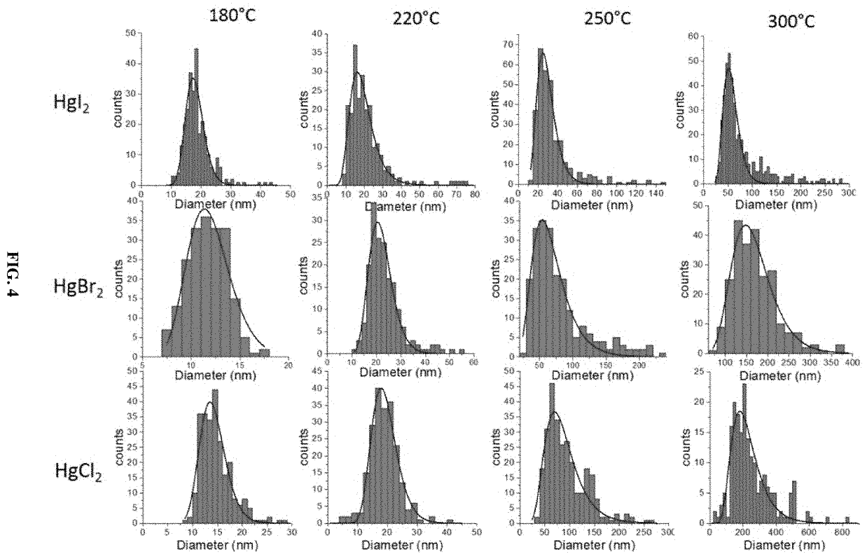

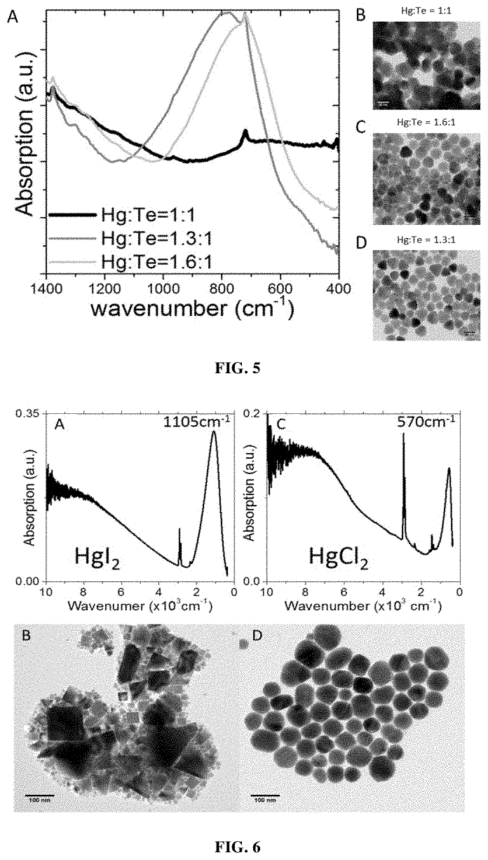

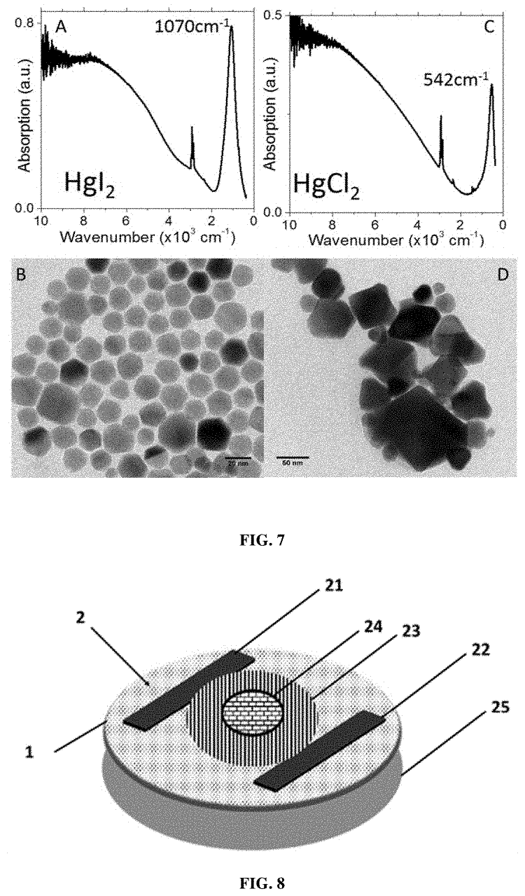

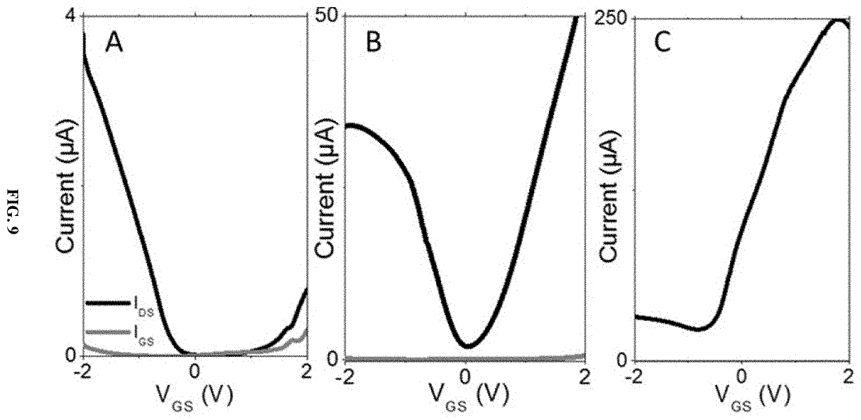

### EXAMPLES

The present invention is further illustrated by the following examples.

Material and Methods

Sb(oleate)₃ Preparation

In a 100 mL three neck flask, 1 g (3.35 mmol) of Sb(acetate)₃ and 40 mL of oleic acid are loaded and put under vacuum at 85° C. for 30 min. The final solution is clear yellowish and used as a stock solution.

Bi(oleate)₃ Preparation

In a 100 mL three neck flask, 0.5 g (1.3 mmol) of Bi(acetate)₃ and 20 mL of oleic acid are loaded and put under vacuum at 85° C. for 30 min. The final mixture is used as a stock solution.

1M TOPTe Preparation

TOP (Trioctylphosphine) complexed with tellurium is obtained by mixing 2.54 g of Te powder with 20 mL of TOP in a 50 mL three-neck flask. The solution is then degassed under vacuum for 30 min at 80° C. The mixture is further heated under Ar at 270° C. until the powder gets fully dissolved. At this temperature the solution is orange and becomes yellow once cooled. The stock solution is kept in the glove box.

1M TOPSe Preparation

TOP complexed with selenium is obtained by mixing 0.79 g of Se powder with 10 mL of TOP in a 20 mL flask. The black powder is dissolved with sonication in TOP at room temperature to form a clear colorless solution. The stock solution is kept in the glove box.

### Example 1: HgTe Nanocrystals Synthesis

Oleylamine was placed under vacuum and heated to 120° C. for 1 h. Then, the solution is placed to Argon atmosphere and heated up to the reaction temperature. A second solution is made by mixing 0.1 mmol of HgBr₂ and 0.1 mL of TOP:Te (1 M) in 0.9 mL of oleylamine The mercury and tellurium solution is quickly injected (within 5 min after mixing) in the hot oleylamine. The solution color quickly turns to dark brown and the reaction is made during 3 min A solution made of 1 mL of dodecanethiol, 9 mL of toluene and few drops of TOP is quickly added to quench the reaction. 90 mL of ethanol is added to precipitate the nanocrystals from the solution. The colorless supernatant is discarded and the precipitated redispersed with 3 mL of chloroform and few drops of dodecanethiol.

The nanocrystals are washed again with 90 mL of methanol and redispersed in 3 mL of chloroform.

### Example 2: Synthesis of HgTe with n-type Behavior

513 mg of HgCl₂ was added to 57 mL of oleylamine in a 100 mL round flask. The solution was placed under vacuum and heated to 110° C. for 1 h. Then, the temperature is increased to 120° C. and solution placed to Ar atmosphere. 1.9 mL of TOP:Te (1M) with 10 mL of oleylamine have been warm up before added to the mercury solution. The solution color immediately turns to dark brown and the reaction is made during 3 min. A solution made of 1 mL of dodecanethiol and 9 mL of toluene is quickly added to quench the reaction. 80 mL of ethanol is added to precipitate the nanocrystals from the solution. The colorless supernatant is discarded and the precipitated redispersed with 8 mL of chloroform and few drops of dodecanethiol. The nanocrystals are washed again with 60 mL of methanol and redispersed in 6 mL of chloroform.

FIGS. 23A and 23B show the infrared and spectrum transfer curve corresponding to said n-type HgTe nanocrystals.

### Example 3: Synthesis of HgTe with p-type Behavior

684 mg of HgBr₂ was added to 57 mL of oleylamine in a 100 mL round flask. The solution was placed under vacuum and heated to 110° C. for 1 h. Then, the temperature is decreased to 60° C. and solution placed to Ar atmosphere. 1.9 mL of TOP:Te (1M) with 10 mL of oleylamine have been warm up before added to the mercury solution. The solution color immediately turns to dark brown and the reaction is made during 3 min. A solution made of 1 mL of dodecanethiol and 9 mL of toluene is quickly added to quench the reaction. 80 mL of ethanol is added to precipitate the nanocrystals from the solution. The colorless supernatant is discarded and the precipitated redispersed with 8 mL of chloroform and few drops of dodecanethiol. The nanocrystals are washed again with 60 mL of methanol and redispersed in 6 mL of chloroform. The final solution is filtered with 0.2 μm PTFE filter.

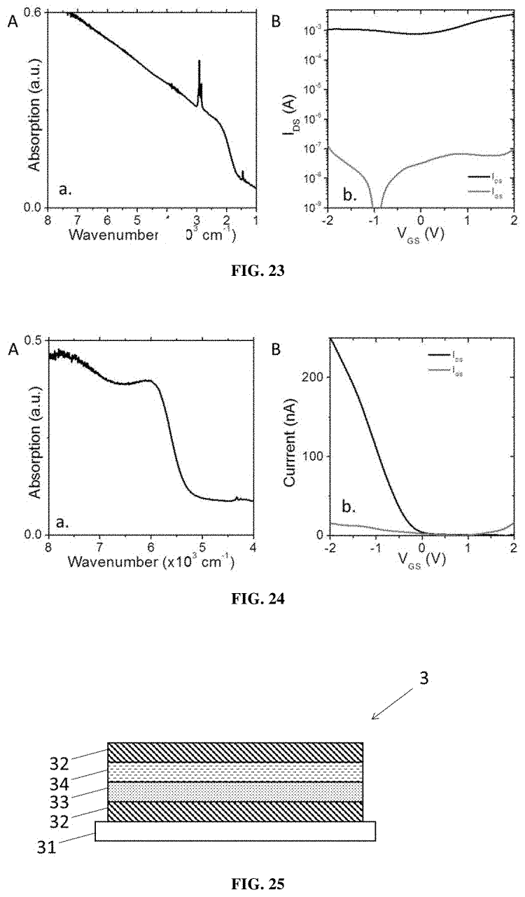

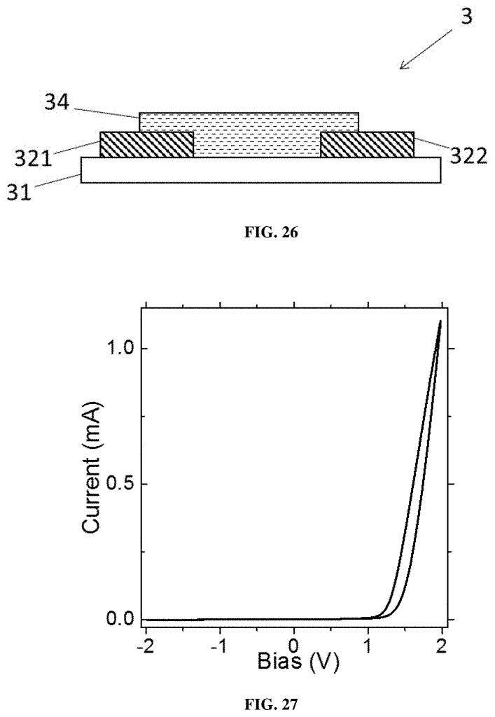

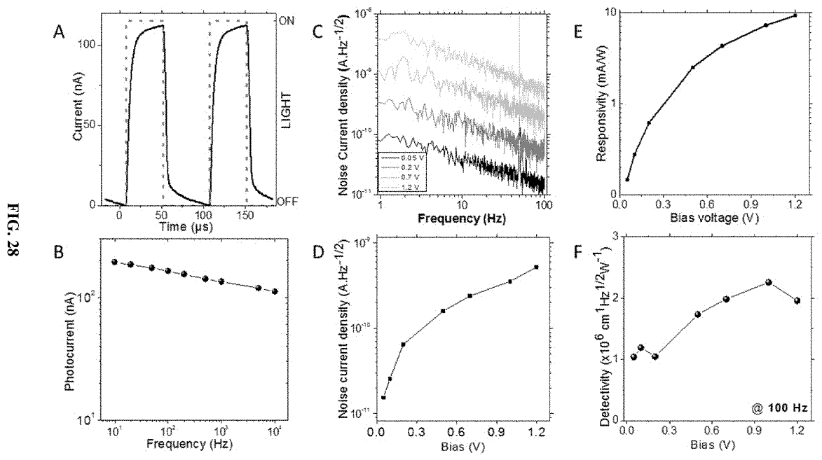

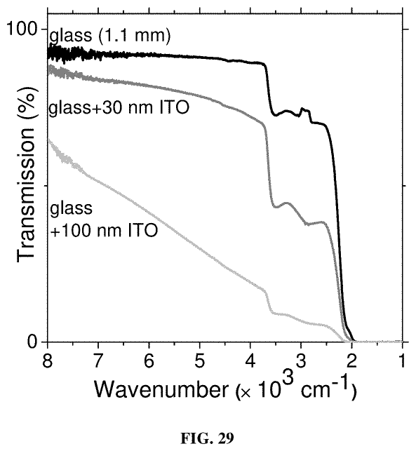

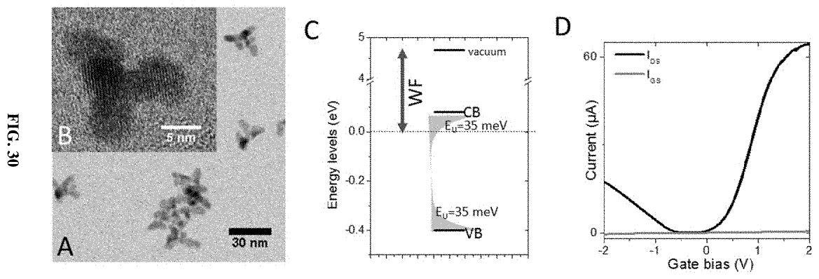

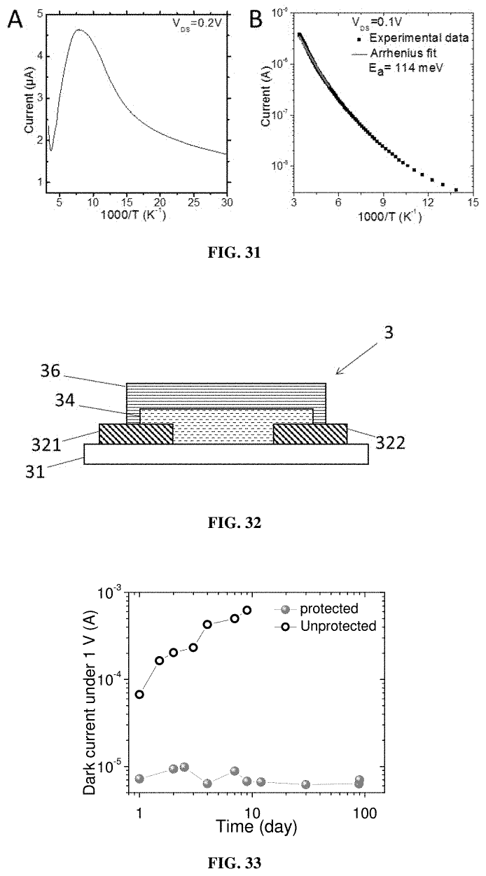

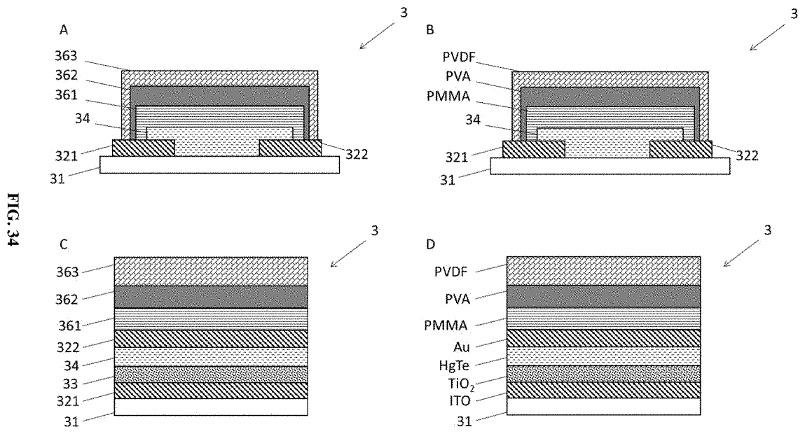

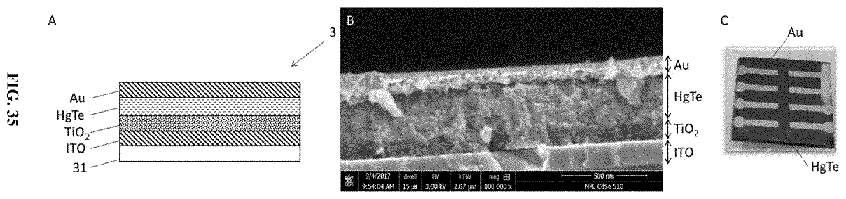

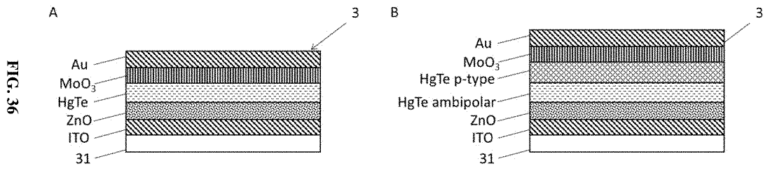

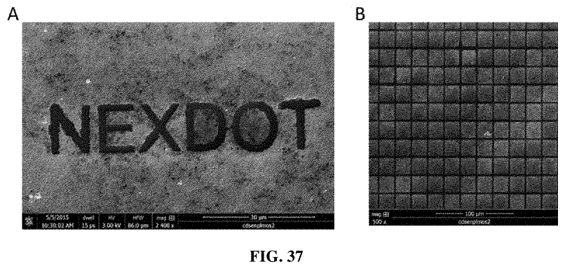

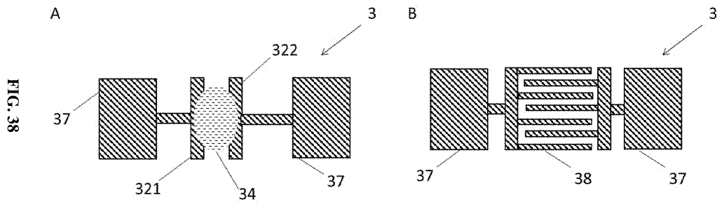

FIGS. 24A and 24B show the infrared and spectrum transfer curve corresponding to said p-type HgTe nanocrystals.

### Example 4: HgSe Nanocrystals Synthesis

45 mg of HgI₂ or 27 mg of HgCl₂ are dissolved in 9 mL of oleylamine and heated to 120° C. for 1 h. Then, the solution is placed to Argon atmosphere and heated up to the reaction temperature. A second solution is made by dissolving 1 mmol of Se in 10 mL of oleylamine 1 mmol of NaBH₄ is added to the solution to help dissolution of Se powder at room temperature. 1 mL of selenium solution is quickly injected in the hot oleylamine The solution color quickly turns to dark brown and the reaction is made during 3 min. A solution made of 1 mL of dodecanethiol, 9 mL of toluene and few drops of TOP is quickly added to quench the reaction. 90 mL of ethanol is added to precipitate the nanocrystals from the solution. The colorless supernatant is discarded and the precipitated redispersed with 3 mL of chloroform and few drops of dodecanethiol. The nanocrystals are washed again with 90 mL of methanol and redispersed in 3 mL of chloroform.

### Example 5: HgS Nanocrystals Synthesis

45 mg of HgI₂ or 27 mg of HgCl₂ are dissolved in 9 mL of oleylamine and heated to 120° C. for 1 h. Then, the solution is placed to Argon atmosphere and heated up to the reaction temperature. A second solution is made by dissolving 1 mmol of S in 10 mL of oleylamine at room temperature. 1 mL of sulfur solution is quickly injected in the hot oleylamine The solution color quickly turns to dark brown and the reaction is made during 3 min. A solution made of 1 mL of dodecanethiol, 9 mL of toluene and few drops of TOP is quickly added to quench the reaction. 90 mL of ethanol is added to precipitate the nanocrystals from the solution. The colorless supernatant is discarded and the precipitated redispersed with 3 mL of chloroform and few drops of dodecanethiol. The nanocrystals are washed again with 90 mL of methanol and redispersed in 3 mL of chloroform.

### Example 6: Sb₂Te₃ Nanocrystals Synthesis

In a 25 mL three neck flask, 4 mL of the antimony oleate in octadecene (ODE) (0.33 mmol Sb) are diluted with 10 mL of additional ODE. The flask is degassed under vacuum at 85° C. for 30 min. Then the atmosphere is switched to Ar and the temperature is raised to 200° C. 0.5 mL of 1M TOPTe is quickly injected and the solution rapidly turns metallic grey. The heating is continued for 5 min before the heating mantle is removed and air flow on the outside of the flask is used to cool the solution. The nanoparticles are precipitated by addition of ethanol and centrifuged for 3 min. The clear supernatant is discarded and the pellet is redispersed in hexane. The cleaning procedure is repeated two additional times.

### Example 7: Bi₂Te₃ Nanocrystal Synthesis

4 mL of the bismuth oleate solution (0.25 mmol Bi) and 10 mL of ODE are added to a 25 mL 3 neck flask. The flask is degassed under vacuum at 85° C. for 30 min. The atmosphere is then switched to Argon and the temperature raised to 200° C. 0.4 mL of TOPTe (1M) are quickly injected and the solution rapidly turns metallic grey. The heating is continued for 5 min before the reaction is cooled down. The nanoparticles are precipitated by addition of ethanol and centrifuged for 3 min. The cleaning procedure is repeated two additional times.

### Example 8: Ag₂Se Nanocrystal Synthesis

In a 25 mL flask, 7.8 g of trioctylphosphine oxide (TOPO) are dissolved in 6.6 mL of oleylamine. The solution is then degassed for 1 h at 120° C. under vacuum. 6 mL of TOPSe at 1M are added and the temperature is raised to 180° C. 4 mL of AgCl in TOP at 1M (made by dissolving 1.43 g of AgCl in 10 mL of TOP) are added and the reaction is conducted at 180° C. for 20 min. Then 5 ml of butanol are added to the solution, the heating mantle is removed and the flask cooled down to 50° C. The content of the flask is divided in two tubes and ethanol is added. The tube are centrifuged at 5000 rpm for 5 min. the supernatant is discarded and the formed pellet redissolved in a mixture made of chloroform and 2 drops of dodecanethiol. The particle are further cleaned by addition of methanol. The tubes are finally centrifuged at 5000 rpm for 5 min. The supernatant is discarded and the formed pellet redissolved in chloroform.

### Example 9: HgTe/HgSe Core Shell Heterostructure

HgTe nanocrystals dispersed in chloroform and with band edge exciton at 4000 or 3000 cm⁻¹ are used as seeds. Mercury oleate is prepared by dissolving 0.5 g of mercury acetate in 1.6 mL of oleic acid. The solution is degassed at room temperature and heated at 100° C. during 30 min. A viscous gel is obtained and stored at 5° C. The seeds are added to 2.4 mL of oleylamine and degassed under vacuum at 60° C. during 15 min. 5 mL of the mercury oleate solution and TOP:Se at 20 mM in oleylamine is added at 60° C. with a rate of 0.25 mL.min⁻¹. After injection, the 90 mL of ethanol is added to precipitate the nanocrystals from the solution. The colorless supernatant is discarded and the precipitate redispersed with 3 mL of chloroform and few drops of dodecanethiol. The nanocrystals are washed again with 90 mL of methanol and redispersed in 3 mL of chloroform.

### Example 10: HgSe/HgTe Core Shell Heterostructure

HgSe nanocrystals dispersed in chloroform and intraband exciton at 3000 cm⁻¹ are used as seeds. The seeds are mixed with 0.5 mmol of mercury halide in 3 mL of oleylamine and degassed under vacuum at 60° C. during 15 min 5 mL of TOPTe at 20 mM in oleylamine is added at 60° C. with a rate of 0.25 mL.min⁻¹. After injection, 90 mL of ethanol is added to precipitate the nanocrystals from the solution. The colorless supernatant is discarded and the precipitate redispersed with 3 mL of chloroform and few drops of dodecanethiol. The nanocrystals are washed again with 90 mL of methanol and redispersed in 3 mL of chloroform.

### Example 11: Ligand Exchange Procedure

To prepare thin films of nanocrystals with different capping ligands, a liquid phase transfer approach was used, where the nanocrystals end up being S²⁻ capped. Na₂S was dissolved in N-methylformamide Nanocrystals previously prepared and dissolved in hexane are mixed with this solution until a phase transfer occurs. The non-polar supernatant is discarded, before fresh hexane gets added. The polar phase is further cleaned and after decantation, the hexane is removed again. This procedure is repeated a third time. Then ethanol is added to precipitate the nanocrystals. After centrifugation, the clear supernatant is trashed and the formed pellet is redispersed in fresh N-methylformamide

### Example 12: Electrode Fabrication

Electrodes are fabricated using standard optical lithography methods. The surface of a Si/SiO₂ ( 400 nm thick) wafer is cleaned by sonication in acetone. The wafer is rinsed with isopropanol and finally cleaned using a O₂ plasma. AZ5214 resist is spincoated and baked at 110° C. for 90 s. The substrate is exposed under UV through a pattern mask for 2 s. The film is further baked at 125° C. for 2 min to invert the resist. Then a 40 s flood exposure is performed. The resist is developed using a bath of AZ726 for 32 s, before being rinsed with pure water. We then deposit a 3 nm Cr layer and a 40 nm gold layer using a thermal evaporator. The lift-off is performed by dipping the film for 1 h in acetone. The electrodes are finally rinsed using isopropanol and dried by air flow. The electrodes are 2 mm long and spaced by 20 μm.

### Example 13: Electrolyte Preparation

500 mg of LiClO₄ are mixed with 2.3 g of PEG on a hot plate in an Ar filled glove box at 170° C. for 2 h.

### Example 14: Electrolyte Gated Transistor Fabrication

The solution of HgTe nanocrystals capped with S²⁻ and dispersed in N-methylformamide is dropcasted onto the electrodes on a hot plate at 100° C. Meanwhile the electrolyte is softened at 100° C. The melted electrolyte is now clear and is brushed on the HgTe nanocrystals film A copper grid is then deposited on the top of the electrolyte and used as top gate.

### Example 15: Photovoltaic Detector

A thin layer of graphene is transferred on an undoped Si wafer to be used as quasi IR transparent electrodes. A colloidal solution of TiO₂ is spin-coated on top of said graphene layer at 2000 rpm and annealed at 250° C. for 30 min. Then a solution of HgTe nanocrystals at 20 mg/mL is spin-coated at 2000 rpm. Then the film is dipped in a solution of ethanedithiol (1% in mass in ethanol) and rinsed in pure ethanol. The film is then annealed on a hot plate at 80° C. The nanocrystals deposition is repeated two more times to build a 80 nm thick film. On the top of the nanocrystals film, a colloidal solution of VO₂ is spin-coated and used as hole transport layer. Finally MoOₓ and aluminum are evaporated and used as top electrode.

### Example 16: Photovoltaic Detector

A thin layer of graphene is transferred on an undoped Si wafer to be used as quasi IR transparent electrodes. A 50 nm thick layer of ZnO is evaporated on top of said graphene layer by sputtering. Then a solution of HgTe nanocrystals at 20 mg/mL is spin-coated on ZnO layer at 2000 rpm. The resulting film is dipped in a solution of ethanedithiol and rinsed in pure ethanol. The film is then annealed on a hot plate at 80° C. The nanocrystals deposition is repeated two more times to build a 80 nm thick film. On the top of the nanocrystals film, a colloidal solution of VO₂ is spin-coated and used as hole transport layer. Finally MoOₓ and aluminum are evaporated and used as top electrode.

### Example 17: Photovoltaic Detector

A colloidal solution of TiO₂ is spin-coated on a prepatterned ITO coated glass substrate at 2000 rpm and annealed at 250° C. for 30 min. Then a solution of HgTe nanocrystals at 20 mg/mL is spin-coated on top of the resulting TiO₂ layer at 2000 rpm. The resulting film is dipped in a solution of ethanedithiol and rinsed in pure ethanol. The film is then annealed on a hot plate at 80° C. The nanocrystals deposition is repeated two more times to build a 80 nm thick film On the top of the nanocrystals film, a colloidal solution of VO₂ is spin-coated and used as hole transport layer. Finally MoOₓ and aluminum are evaporated and used as top electrode.

### Example 18: Back Gated Transistor Fabrication

The solution of HgTe nanocrystals capped with S²⁻ and dispersed in N-methylformamide is dropcasted onto prefabricated electrodes on a doped Si wafer with a 100 nm thick Si₃N₄ layer on a hot plate at 100° C.

### Example 19: Top Gated Transistor Fabrication

A solution of dodecanthiol capped HgTe nanocrystals is dropcasted on a doped Si wafer with a 400 nm thick SiO₂ layer with prepatterned electrodes. The resulting film is dried and then dipped in a solution of ethanedithiol before being rinsed in pure ethanol. The deposition process is repeated at least a second time and possibly more if a thick film is desired. A solution of cytop was spin-coated on the surface at 7000 rpm and annealed for 30 min at 100° C. Finally, a top contact is evaporated though a shadow mask.

### Example 20: Diode Fabrication

A glass substrate with ITO coated is patterned using conventional lithography method to define some contact area. After the development of the resist, the unprotected ITO is exposed to a 28% in mass solution of HCl for 20 sec before being rinsed in pure water. The film is then dried. A thin layer of TiO₂ (60 nm) is deposited on top of said film by spin-coating.

### Example 21: Down Conversion in a Light Emitting Device

A solution of PMMA diluted in chloroform is prepared. A solution of metal chalcogenide nanocrystals diluted in chloroform is mixed with the PMMA mixture, so that the mass ratio of nanocrystals to PMMA is 1%. The solution is stirred for one hour in an air free glove box. This mixture is then spin-coated on a substrate or brushed on the top on a 800 nm LED. Finally a thin layer of CYTOP™ is deposited and annealed in order to insulate the nanocrystals layer from the environment.

### Example 22: All Inorganic Encapsulation for Down Conversion in a Light Emitting Device

A film of nanocrystals is prepared by spin-coating of a nanocrystal solution at 30 mg.mL⁻¹. The film is briefly dipped into a solution of HCl at 1% in volume in ethanol. The film is then rinsed in pure ethanol and dried using a nitrogen flow. 30 layers of Al₂O₃ are deposited using an Atomic Layer Deposition system.

### Example 23: Flexible Label System

An ITO coated PET substrate is connected to the positive side of a high bias source, and the negative side is connected to a metal plate. The electrodes are spaced by 1 cm. The two electrodes are dipped in a solution of metal chalcogenide nanocrystals where the solvent is a 50:50% in volume mixture of hexane and acetone. The bias is applied for 1 min and finally turned off. The ITO on PET electrodes is then coated by metal chalcogenide nanocrystals.

### Example 24: HgSe Core Nanocrystals

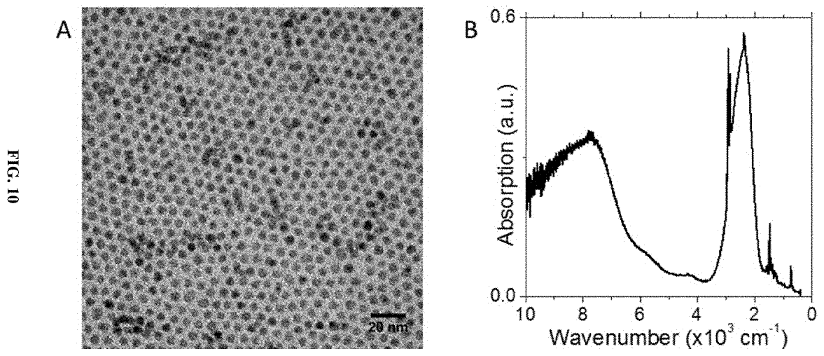

0.5 g of Hg(acetate)₂ is dissolved in 10 mL oleic acid and 25 mL oleylamine in a 50 mL three-neck flask. The solution is then degassed under vacuum at 85° C. during 1 hour. After switching the atmosphere to Ar, the temperature is raised to 110° C. 1 mL of TOP:Se (1M) is then injected and the solution color quickly changes from light yellow to dark solution. After 1 min, the reaction is quenched with injection of 1 mL of dodecanethiol and cooled down to room temperature with air flux. The nanocrystals are then precipitated with ethanol. After centrifugation, the nanocrystals are redispersed in chloroform. The washing step is repeated one more time. The final volume is 6 mL. TEM images and absorption spectrum of the obtained material are given in FIG. 10A-B.

### Example 25: Large HgSe Core Nanocrystals

In a 25 mL three neck flask, 100 mg of Hg(OAc)₂ is dissolved in 4 mL of oleic acid and 10 mL of oleylamine. The flask is degassed under vacuum for 30 min at 85° C. The atmosphere is switched to Ar and the temperature adjusted between 60 and 120° C. depending on the expected final nanocrystal size. Meanwhile 0.13 g of SeS₂ is dissolved in 2 mL of oleylamine under sonication. The brown mixture is injected into the flask and the color turns dark. After 1 to 60 min, 1 mL of dodecanthiol is used to quench the reaction. The heating mantle is removed and the flask is cooled using a flow of fresh air. The nanocrystals are precipitated by addition of ethanol. After centrifugation the formed pellet is redissolved in toluene. The cleaning procedure is repeated two other times. Nanoparticles are stored in toluene. However due to their large size (20 nm) they have a limited colloidal stability.

### Example 26: HgS Core Nanocrystals

In a 50 mL three necks flask, 2 g of mercury acetate and 80 mL of oleic acid are degassed at 85° C. under vacuum for 30 min. the obtained stock solution is transparent yellowish. 4 mL of this solution are mixed with 10 mL of oleylamine and degassed at 85° C. for 30 min. Meanwhile 11 mg of Sulfur powder are dissolved by sonication in 3 mL of oleylamine The final solution is clear and transparent. Under Ar at a temperature between 60 and 120° C., the sulfur solution is injected in the flask containing the Hg precursor. The mixture immediately turns dark; the reaction is performed for 30 s to 60 min. Then 1 mL of dodecanthiol is injected to quench the reaction and the flask quickly cooled down using fresh air flow. The content of the flask was split into 50 mL tube and ethanol is added to precipitate the nanoparticle. After centrifugation for 5 min at 5000 rpm, the clear supernatant is trashed and the pellet redissolved in 10 mL clear toluene. This cleaning procedure is repeated for a second time using ethanol as non-solvent and toluene as good solvent. The pellet is again redissolved in toluene and 3 mL of acetone is added before centrifuging the solution. The formed pellet is saved and dried under nitrogen flow before being redissolved in toluene. 5 mL of ethanol is added to the supernatant which is further centrifuged to form a second pellet. The latter is also dried and redissolved in toluene. Finally 20 mL of ethanol is used to precipitate the remaining nanocrystal into the supernatant and the third fraction is further processed like the first two ones.

### Example 27: Ag₂Se Core Nanocrystals

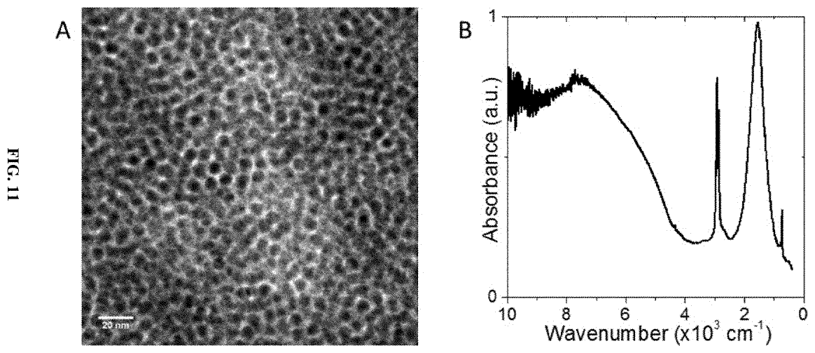

In a 25 mL flask, 8 g of trioctylphosphine oxide (TOPO) are dissolved in 6.5 mL of oleylamine. The solution is then degassed for 1 h at 120° C. under vacuum. 6 mL of TOPSe at 1M are added and the temperature is raised to 180° C. 4 mL of AgCl in TOP at 1M (made by dissolving 1.43 g of AgCl in 10 mL of TOP) are added and the reaction is conducted at 180° C. for 20 min then 1 mL of dodecanethiol is added to quench the reaction. The flask is cooled down. The cleaning procedure is conducted using ethanol as non-solvent and toluene as good solvent. TEM images and absorption spectrum of the obtained material are given in FIG. 11A-B.

### Example 28: Doped ZnO Core Nanocrystals

The example is taken from R. Buonsanti et al, Nano Lett. 11, 4706 (2011). A solution (A) containing zinc stearate (Alfa Aesar, 1 mmol), Aluminum acetylacetonate (Aldrich 99%, 0.05-1 mmol), oleic acid (Aldrich 90%, 3 mmol) in 4 mL of octadecene (Aldrich 90%) and a mixture (B) of 1,2-hexadecanedi (Aldrich 90%, 10 mmol) in 11 mL octadecene were loaded in three-neck flasks and magnetically stirred at 140° C. under argon for 1 h. Afterward, the temperature in B was increased to Tᵢₙⱼ and solution A was rapidly injected into B, which was accompanied by a temperature drop ΔT≈20° C. (T_{growth}=Tᵢₙⱼ−ΔT). After 5 hours at T_{growth}, the reaction mixture was allowed to cool. Ethanol was added (a white flocculate from the clear yellow-orange solution was generally only observed for the largest NCs) and the NCs were separated from the reaction mixture by centrifugation (9000 rpm for 20 min). After two cycles of redispersion in hexane (1 mL) and reprecipitation by ethanol, 20-30 mg of precipitate was eventually collected and dispersed in a suitable nonpolar solvent.

### Example 29: HgTe Nanocrystals

27 mg of HgCl₂ and 3 mL of oleylamine are degassed under vacuum at 120° C. in a 25 mL three-neck flask. A pre-heated solution made of 100 μL of TOP:Te and 4.9 mL of oleylamine is injected into the flask. For smaller core, the solution is cooled down to 80° C. One has to note that pre-heating is essential to synthesize nanocrystals with low size dispersion. The solution color quickly changes from light yellow to dark-brown solution. After 3 min, the reaction is quenched with an injection of a solution made of 1 mL of dodecanethiol and 9 mL of toluene. The temperature quickly drops to 70-80° C. The resulting solution is precipitated with addition of ethanol and then centrifuged. The precipitate is redispersed in chloroform a second washing step is carried out with methanol. The stability of the final colloidal solution is improved by redispersing the final nanocrystals in chloroform.

### Example 30: PbS Nanocrystals

In a three necks flask, we introduce 0.9 g lead oxide and 40 mL of oleic acid. The mixture is degassed for 1 h at 100° C. under vacuum and then heated under Argon at 150° C. for three hours. In the glove box 0.4 mL of Bis(trimethylsilyl)sulfide (TMSS) are mixed in 20 mL of octadecene (ODE). In a 100 mL three necks flask, 12 ml of the lead oleate (PbOA) mixture previously prepared are quickly degassed at 100° C. and then heated at 150° C. under Argon. 6 mL of the solution of TMSS in ODE are quickly injected to the flask and the reaction performed for 3 minutes. Finally the solution is quickly cooled to room temperature. The solution is precipitated by adding ethanol and centrifuged for 5 min at 3000 rpm. The solid is redispersed in toluene. The cleaning step is repeated a second time. At the third cleaning, selective precipitation is performed to separate the different size.

QD with a bluer band gap have also been synthetized for electrochromism measurement. In this case 0.45 g of lead oxide is stirred in 5 ml of oleic acid overnight at 100° C. under vacuum. The obtained yellowish solution is dissolved by adding 15 ml of ODE. The flask is then switch under Argon and the temperature risen up to 125° C. Then 10 ml of a TMMS in ODE solution (0.1M) are quickly injected. The heating mantle is removed and the solution gently cooled down up to room temperature. The three steps cleaning procedure including selective precipitation is done using a mixture of methanol/ethanol as polar solvent and chloroform as non-polar solvent.

### Example 31: PbSe Nanocrystals

In the glove box a 1M solution of trioctylphosphine selenide (TOPSe) is prepared by stirring Se powder in trioctylphosphine (TOP) at room temperature. In a three necks flask 650 mg of trihydrate lead(II) acetate Pb(Oac)₂(H₂O)₃ are introduced with 2 mL of phenyl ether, 1.5 mL of oleic acid and 8 mL of TOP. The solution is degassed, as well as a second flask only filled with 10 mL of pure phenyl ether, for 1 hour at 85° C. The one containing the lead precursor is cooled to 45° C. and 1.7 mL of the TOPSe solution is added. The solution is kept under stirring condition for 5 extra minutes. Finally the content of the flask is introduced in a 20 mL syringe. The flask filled with just phenyl ether is heated up to 200° C. under Ar. The content of the syringe is quickly injected. The Temperature of the flask cooled down to 140° C. after the injection. During the next 90 s the temperature is set at 120° C. to avoid a too fast cooling. After this delay the flask is promptly cooled to room temperature. The cleaning is operated in the first step by addition of methanol and ethanol. After centrifugation the solid is dispersed in toluene. For the second (third) cleaning step ethanol (acetone/ethanol) is used.

### Example 32: CsPbBr₃ Nanocrystals

CsPbBr₃ nanocrystals: In a three neck flask, we introduced 147 mg of PbBr₂ with 10 mL of ODE and degassed the solution for 30 min at 110° C. Then we injected 0.5 mL of OA and 0.5 mL of OLA into this degassed reaction mixture. The atmosphere was switched to Ar and the temperature was raised to 180° C. We then quickly injected 0.8 mL of caesium oleate. The reaction color turned yellow greenish immediately. We let the reaction occur for 30 sec and flux of fresh air was then used to cool down the flask. The obtained solution was centrifuged at 6000 rpm for 5 minutes. The supernatant was discarded and the obtained pellet was redispersed in 2 to 3 mL of hexane. For device purpose we carried out 2nd washing using methyl acetate as non-solvent. Typically methyl acetate was added twice the volume of dispersed nanocrystal solution and again centrifuged at 6000 rpm for 5 minutes. The obtained pellet was redispersed in hexane and used for device fabrication.

### Example 33: CsPbI₃ Nanocrystals

CsPbI₃ nanocrystals: In a three neck flask, we introduced 180 mg of PbI₂ with 10 mL of ODE and degassed the solution for 30 min at 110° C. Then we injected 0.5 mL of OA and 0.5 mL of OLA into this degassed reaction mixture. The atmosphere was switched to Ar and the temperature was raised to 180° C. We then quickly injected 0.8 mL of caesium oleate. The reaction color turned yellow greenish immediately. We let the reaction occur for 30 sec and flux of fresh air was then used to cool down the flask. The obtained solution was centrifuged at 6000 rpm for 5 minutes. The supernatant was discarded and the obtained pellet was redispersed in 2 to 3 mL of hexane. For device purpose we carried out 2nd washing using methyl acetate as non-solvent. Typically methyl acetate was added twice the volume of dispersed nanocrystal solution and again centrifuged at 6000 rpm for 5 minutes. The obtained pellet was redispersed in hexane and used for device fabrication.

### Example 34: HgSe/HgTe Heterostructure with Epitaxial Connection

In a typical synthesis, 45 mg (0.1 mmol) of HgI₂ is dissolved in 3 mL of hot oleylamine (≈50° C.). Then, 1 mL of HgSe nanocrystal solution is added. The solution is degassed under vacuum at 50° C. during 10 min in order to remove the chloroform. The atmosphere is switched to argon and the temperature to 80° C. 100 μL of TOP:Te (1 M) in 4.9 mL of oleylamine is injected to the solution with a syringe pump at 0.25 mL.min⁻¹. The reaction is made during 60 min and then quenched by adding a mixture of 1 mL of dodecanethiol and 9 mL of toluene. The nanocrystals are then precipitated with ethanol. After centrifugation, the nanocrystals are redispersed in chloroform. The washing step is repeated one more time.

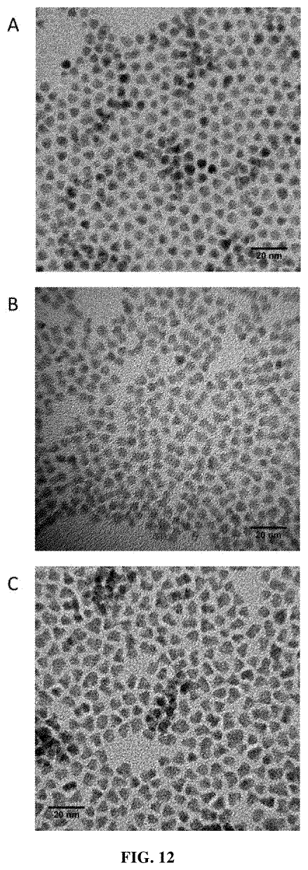

FIG. 12A-C illustrates the shell growth. We observe from TEM an increase of the CQD size from 2.6 nm in radius for the core to 3.2 nm for the heterostructure (FIG. 16A-B). Using EDX and XRD, we are able to determine the actual amount of HgTe material with respect to the introduced amount of Hg precursor, see FIG. 16B. The two methods are in a reasonable agreement.

### Example 35: HgSe/HgTe Heterostructure Obtained by Mixing Solution

A solution of HgSe nanocrystals is synthetized with an intraband feature at 2000 cm⁻¹ and is missed with a solution of HgTe nanocrystals with an interbank edge at 4000 cm⁻¹. The amount of the two material are chosen in order that the absorption relative to the interband transition of Hgte matched the magnitude of the absorption of HgSe intraband transistion. The solution made of the mixture is deposited onto electrodes. A ligand exchange procedure is conducted to better couple the nanoparticles of the two kinds. Typically the film is dipped in a 1% in volume solution of ethanedithiol for 1 min and then rinsed in pure ethanol.

### Example 36: HgSe/HgTe Heterostructure Obtained by Mixing Solution

A solution of HgSe nanocrystals is synthetized with an intraband feature at 2000 cm⁻¹ and is missed with a solution of HgTe nanocrystals with an interbank edge at 4000 cm⁻¹. The amount of the two material are chosen in order that the absorption relative to the interband transition of HgTe matched the magnitude of the absorption of HgSe intraband transistion. Meanwhile a solution of Na₂S in N-methyl formamide (30 mg/mL) is prepared, 1 mL of this soplution is missed in a testube with 2 mL of the mixture of HgTe and HgSe nanocrystals. After sonication, the nanocrystals are phased transferred toward the polar phase. The polar phase is further clean by adding hexane. The mixture is sonicated for 30 seconds, once the two phases split, the hexane is removed using a pipette. This cleaning is repeated three times. Then ethanol is added to precipitate the nanoparticle. After centrifugation, the formed pellet is redispersed in fresh N-methyl formamide The material can be deposited using drop casting of the obtain solution onto electrode on a hot plate at 100° C.

### Example 37: HgTe/HgSe Heterostructure with Epitaxial Connection

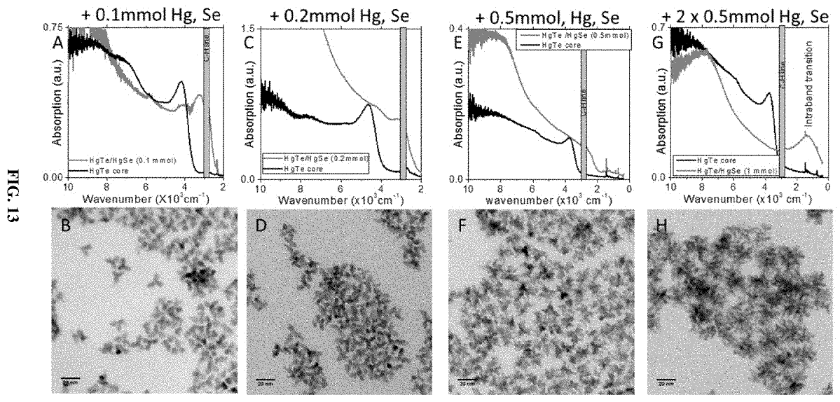

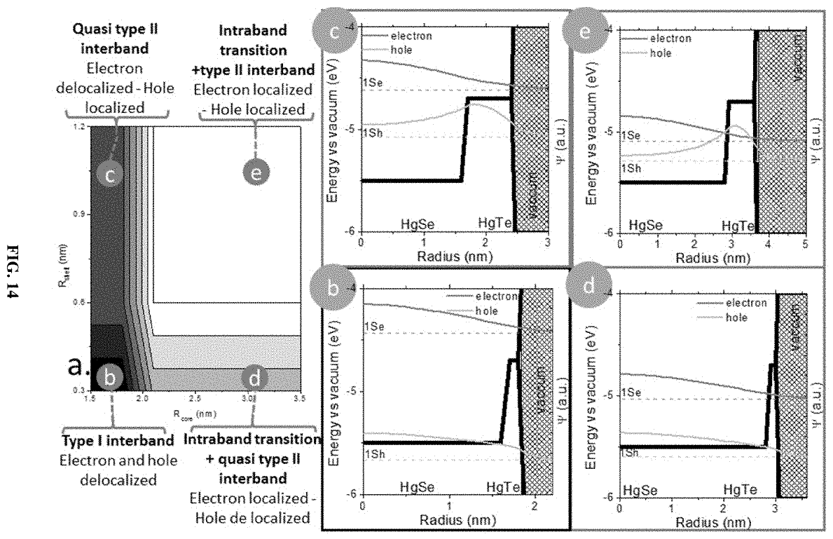

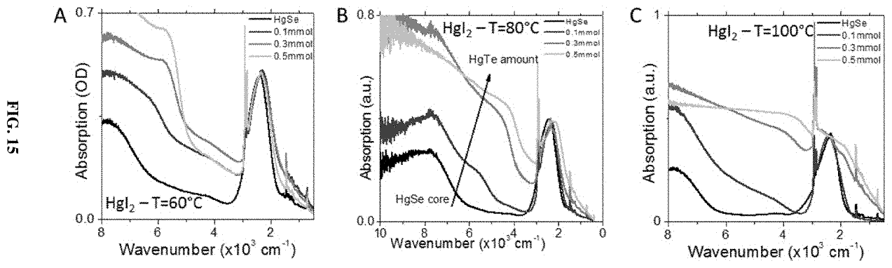

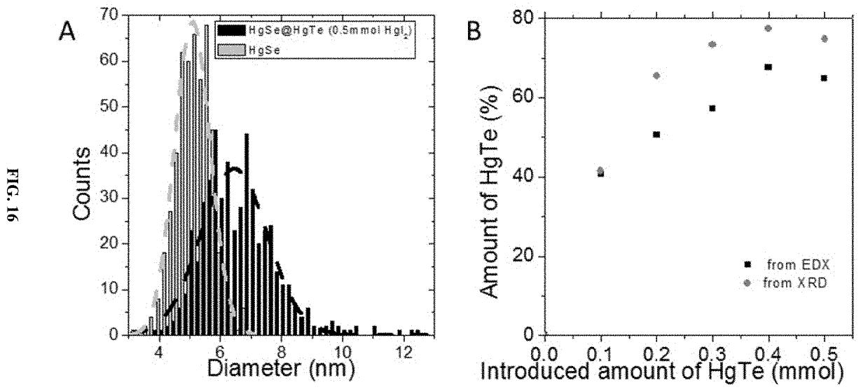

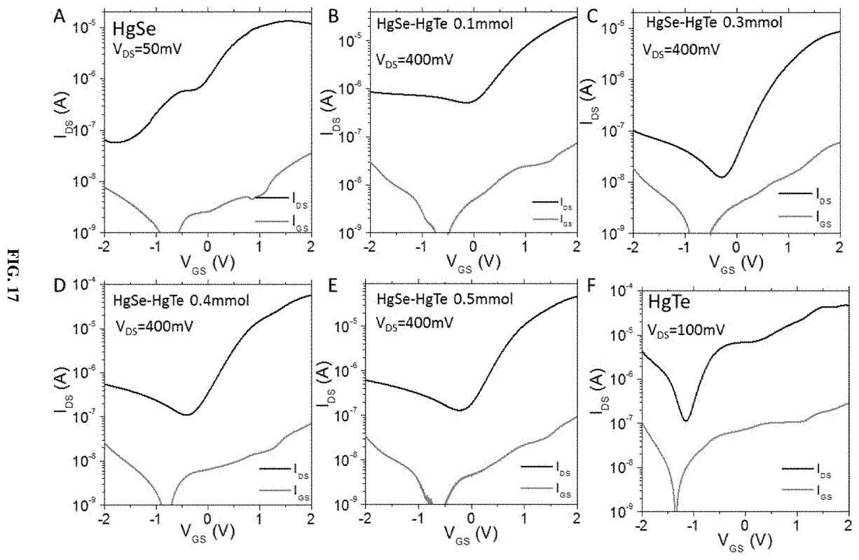

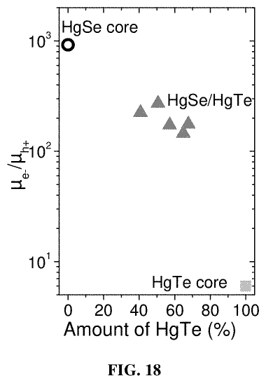

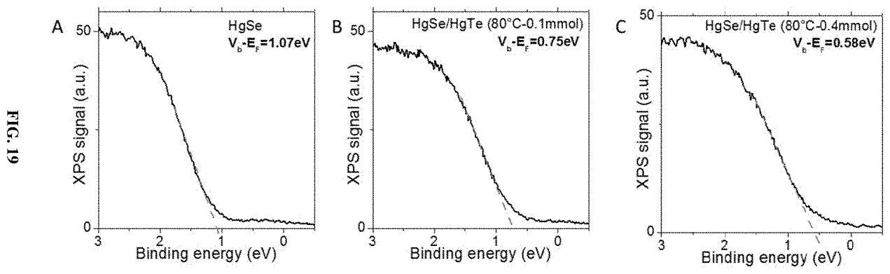

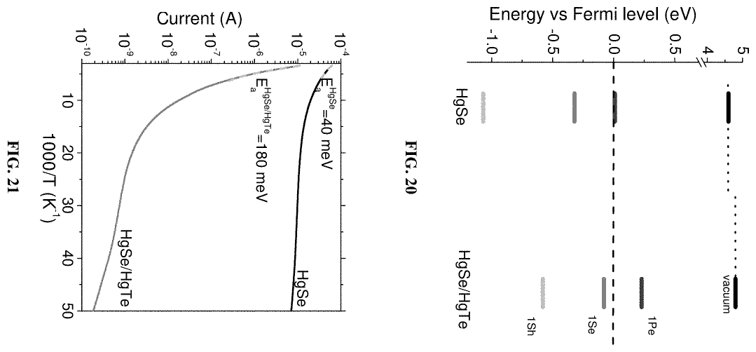

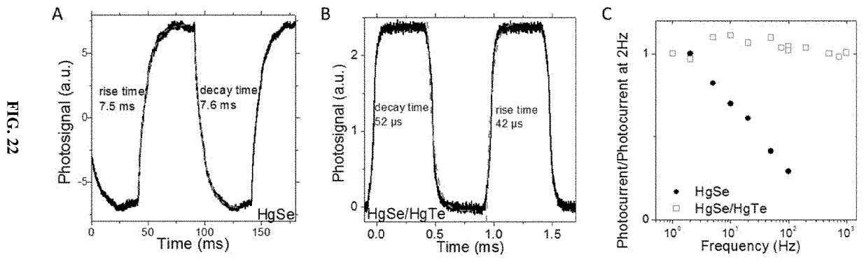

HgTe core dispersed in chloroform and with band edge exciton at 4000 or 3000 cm⁻¹ are used as seeds. The whole core solution is added to 3 mL of oleylamine and degassed under vacuum at 50° C. during 15 min. The atmosphere is switched to Ar. 5 mL solution made of mercury oleate and TOP:Se at 20 mM is added at 60° C. with a rate of 0.25 mL.min⁻¹. The reaction is quenched by adding a mixture of 1 mL of dodecanethiol and 9 mL of toluene. The nanocrystals are then precipitated with ethanol. After centrifugation, the nanocrystals are redispersed in chloroform. The washing step is repeated one more time. The infrared spectra and TEM image of the obtained material are shown in FIG. 13A-H.

### Example 38: Synthesis of HgTe with p-type Behavior with a Band Edge at 6000 cm⁻¹

171 mg of HgCl₂ was added to 20 mL of oleylamine in a 50 mL round flask. The solution was placed under vacuum and heated to 110° C. for lh. Then, the temperature is lowered to 55° C. and solution placed to Ar atmosphere. When temperature is stabilized to 55° C., 0.63 mL of TOP:Te (1M) with 6.3 mL of oleylamine are added to the mercury solution.

The solution color gradually turns to dark brown and the reaction is made during 3 min A solution made of 1 mL of dodecanethiol and 9 mL of toluene is quickly added to quench the reaction. The nanocrystals are precipitated with ethanol. After centrifugation, the nanocrystals are redispersed in chloroform. The washing step is repeated one more time. The solution is filtered with a 0.2 μm and the final volume is 6 mL.

### Example 39: Synthesis of Small PbS Nanocrystals

In this case 0.45 g of lead oxide is stirred in 5 ml of oleic acid overnight at 100° C. under vacuum. The obtained yellowish solution is dissolved by adding 15 ml of ODE. The flask is then switch under Argon and the temperature risen up to 125° C. Then 10 ml of a TMMS in ODE solution (0.1M) are quickly injected. The heating mantle is removed and the solution gently cooled down up to room temperature. The three steps cleaning procedure including selective precipitation is done using a mixture of methanol/ethanol as polar solvent and chloroform as non-polar solvent.

### Example 40: Synthesis Undoped ZnO Nanocrystals Used as Electron Transport Material

In a first vial 30 mL of DMSO and 3 mmol of zinc acetate are mixed together and sonicate to ensure a full dissolution. In a second vial, 5.5 mmol of TMAOH (Tetramethylammonium hydroxide) are mixed in 10 mL of ethanol. The two vials are mixed in a 100 mL three neck flask and stirred for 24 h in ambiant condition (room temperature and in air). After one day, an equal amount of ethyl acetate is added to the flask and the solution switch from clear transparent to white turbid aspect. The content of the flask is then transfer to falcons and centrifuge. The clear supernatant is discarded and the white pellet redissolved in ethanol/160 μL, of ethanolamine are added and the flask sonicated for one minute. By adding ethyl acetate, the flask is precipitated a second time. After centrifugation the pellet is dissolved a second time in 2 mL of ethanol. The solution is centrifuge and only the colloidally stable solution is saved. The obtained solution is then further filter through a 0.22 μm filter and is then ready to be used. the final particles are round 5 nm in size and present an absorption edge at 370 nm.

### Example 41: Ligand Exchange

Inside a N₂ filled glove-box, HgTe nanocrystals in toluene are dropcasted on pre-patterned interdigitated gold electrodes 38 (10 μm separation) on SiO₂/Si substrate. After complete drying, EDT ligand exchange is performed by dipping the film in an EDT solution in ethanol (1-2 wt %) for 90 s and rinsing it in pure ethanol for 30 s. This process is repeated 3 to 4 times to get homogeneous and crack filled film with the device resistance of 100-200 kΩ.

### Example 42: Liquid Ligand Exchange

A few mg of Na₂S are dissolved in 2 mL of N-methylformamide The solution is sonicated for 2 min. In a test tube 1 mL of the previous solution is introduced with 3 mL of HgSe QD dispersed in hexane. The solution is strongly stirred and further sonicated. A phase transfer of the nanoparticle occurred and the polar phase turns dark. The non-polar phase is then cleaned three times by adding hexane and let the solution settle. The clear top phase is trashed each time. Finally, 3 mL of ethanol are added and the tube is centrifuged at 3000 rpm for 3 min. The liquid is trashed and the formed pellet is dried under nitrogen flow, before getting redispersed into fresh N-methyl formamide

### Example 43: Liquid Ligand Exchange

A few mg of NH₄I are dissolved in 2 mL of N-methylformamide The solution is sonicated for 2 min. In a test tube, 1 mL of the previous solution is introduced with 3 mL of HgTe QD capped with oleic acid dispersed in chloroform. The solution is strongly stirred and further sonicated. A phase transfer of the nanoparticles occurrs and the polar phase turns dark. The non-polar phase is then cleaned three times by adding hexane, and the solution is let to settle. The clear top phase is trashed each time. Finally, 3 mL of ethanol are added and the tube is centrifuged at 3000 rpm for 3 min The liquid is trashed and the formed pellet is dried under nitrogen flow, before getting redispersed into fresh 2,6 difluoropyridine.

### Example 44: Liquid Ligand Exchange with As₂S₃

A few mg of As₂S₃ are dissolved into 1 mL of propylamine The solution is sonicated for 1 min. The final solution is yellow and clear. 500 μL of this solution is then mixed with 1 mL of N-methyl formamide. The solution is sonicated for 2 min. In a test tube 1 mL of the previous solution is introduced with 3 mL of HgSe nanocrystals dispersed in hexane. The solution is strongly stirred and further sonicated. A phase transfer of the nanoparticle occurred and the polar phase turns dark. The non-polar phase is then cleaned three times by adding hexane and let the solution settle. The clear top phase is trashed each time. Finally, 3 mL of ethanol are added and the tube is centrifuged at 3000 rpm for 3 min. The liquid is trashed and the formed pellet is dried under nitrogen flow, before getting redispersed into fresh N-methyl formamide

### Example 45: Nanotrench Fabrication

On a Si/SiO₂ wafer, a first electrode is prepared either using standard optical lithography or electron beam lithography. In a typical preparation AZ 5214 E resist is deposit by spin coating on the wafer. The wafer is then baked for 90 s at 110° C. A first UV exposure using the lithography mask is performed for a couple second. Then the film is further baked at 125° C. for 2 minutes. We then process to metal deposition by evaporating Ti (5 nm) and a layer of gold (54 nm) using electron evaporator. Finally, the lift off is conducted by dipping the substrate into acetone for 12 h, before rinsing the electrodes with isopropanol. A second pattern is prepared using the same lithography procedure. The second metallic evaporation is made while the sample is tilted by 60° C. in order that the first electrode shadows some part of the second pattern. In this case 5 nm of Cr and 50 nm of gold are deposited. This shadow effect allows the formation of nanogap at the scale of a few tenth nanometers.

### Example 46: Protective Layer of PMMA/PVA/PVDF

PMMA (5 wt % in CHCl₃) solution is spin-coated on a substrate at 2000 rpm for 60 s, then a quick annealing step at 50° C. for 1 min is performed. In next steps, PVA (centrifuged solution at 10 wt % in water) and PVDF (10 wt % in DMF) are spin-coated at 4000 rpm for 60 s and 1500 rpm for 30 s, respectively. At each step, the substrates are annealed for 1 min at 50° C. Finally, device is kept in vacuum overnight for complete drying of encapsulation layers. Thus, obtained thicknesses for these encapsulating layers are found to be 1.3 μm, 0.5 μm and 0.5 μm of PMMA, PVA and PVDF, respectively.

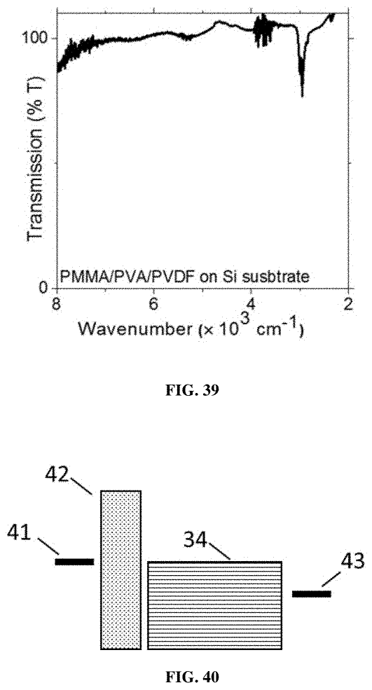

FIG. 39 is an FTIR spectrum of a stack of PMMA/PVA/PVDF encapsulating layers. The overall absorbance is weak with a transmittance above 80%from 8000 to 2000 cm⁻¹. The two main residual absorbance come from water and C—H bond (3000 cm⁻¹).

### Example 47: Lithography to Design an Array of Pixels

Films of HgSe nanocrystals capped with As₂S₃ are dropcasted on a clean doped Si wafer. The films are typically 100 nm thick. PMMA is spin-coated and baked at 160° C. for 15 min. A 6.4 nA current and 20 kV electron acceleration is used to perform the e-beam writing. The film is developed using a Methyl isobutyl ketone (MIBK): Isopropanol (IPA) mixture and rinsed in pure isopropanol. The etching of the nanocrystal film results from an O₂ plasma operated for 5 min Finally, the resist is removed by dipping the film for 5 min in pure acetone. The film is further rinsed in pure IPA and dried. This method allows the design array of pixel with a 20 μm and 60 μm pitch.

### Example 48: Photoconductive Device Fabrication with Air Stable Performance

Electrode preparation: A Si/Si₃N₄ wafer is sliced and used to mimic the surface of a read out circuit. The surface is cleaned by dipping the wafer in acetone. The substrate is sonicated for 5 min before being rinsed with acetone first and then isopropanol. The film is dried and finally etched using a O₂ plasma for 5 min. Some AZ5214 resist is spin-coated at 400 rpm for 30 s. The resist is then basked for 90 s at 110° C. Using a photomasker and an appropriate mask, the resist is illuminated for 1.5 s though the shadow mask which is used to define interdigitated electrodes. The resist is then baked for 2 min at 125° C. and then re-illuminated without mask for 40 s. The resist is then developed for 32 s using AZ726 as developer. The development is quenched by dipping the substrate into water and the substrate is finally dried and gently etched for 5 min using a O₂ plasma. Finally, 5 nm of Cr and 80 nm of gold are thermally evaporated.

HgTe nanocrystals film preparation and EDT ligand exchange in air free conditions: Film preparation and ligand exchange were carried out inside a N₂ filled glovebox. In a typical procedure, 80 μL of concentrated HgTe nanocrystals (25 mg/mL) from toluene is spin-coated at 2000 rpm for 30 s on above fabricated Glass/ITO/TiO₂ substrates. After complete evaporation of solvent, ligand exchange is carried out by dipping the film in 1-2 wt % EDT solution in ethanol for 90 s and rinsing it in pure ethanol for 30 s. Afterwards, a quick annealing step at low temperature (50° C.) for 1 min is carried out. This procedure is repeated for 8-9 times to get thicker (180-200 nm) and pin-hole free HgTe film.

FIG. 28A illustrates the photocurrent as a function of time for a HgTe nanocrystals film in a photoconductive configuration, while the light (λ=1.55 μm) is turned on and off with a frequency of 10 kHz.

FIG. 28B is a bode diagram of the photocurrent intensity for a HgTe nanocrystals film in a photoconductive configuration, as a function of the light chopping frequency.

FIG. 28C illustrates the noise current density as a function of frequency for a HgTe nanocrystals film in a photoconductive configuration under different biases.

FIG. 28D illustrates the noise current density (at 100 Hz) as a function of applied bias for a HgTe nanocrystals film in a photoconductive configuration.

FIG. 28E illustrates the responsivity as a function of the applied bias under blackbody illumination (T_{BB}=927° C.) for an a HgTe nanocrystals film in a photoconductive configuration.

FIG. 28F illustrates the room temperature detectivity at 100 Hz, as a function of the applied bias for a HgTe nanocrystals film in a photoconductive configuration.

Encapsulation of device: Finally, the fabricated device is transferred back to the glove box under N₂ environment. PMMA (5 wt % in CHCl₃) solution is spin-coated on the device at 2000 rpm for 60 s, then a quick annealing step at 50° C. for 1 min is performed.

In next steps, PVA (centrifuged solution at 10 wt % in water) and PVDF (10 wt % in DMF) are spin-coated at 4000 rpm for 60 s and 1500 rpm for 30 s, respectively. At each step, the device is annealed for 1 min at 50° C. Finally, the device is kept in vacuum overnight for complete drying of encapsulation layers. Thus, obtained thicknesses for these encapsulating layers are found to be 1.3 μm, 0.5 μm and 0.5 μm of PMMA, PVA and PVDF, respectively.

### Example 49: Photovoltaic Device Fabrication-First Strategy

ITO patterning: ITO substrates are cut into 17×17 mm size and thoroughly cleaned by sonication in acetone for 5 min, rinsed with acetone and isopropanol, then dried completely with dry N₂ gun. AZ5214E photoresist is spin-coated for 30 s and subsequently the substrates are baked at 110° C. for 90 s. At next stage, standard photolithography is performed using mask aligner for exposing the substrates to UV light for 5 s through a lithography mask (1 mm width). Photoresist is developed using AZ726 developer for 40 s and immediately rinsed with de-ionized water. Thus, exposed ITO surface is completely etched out with 25% HCl (in water) for 6 min and substrates are dipped immediately in de-ionized water. At next stage, lift-off is conducted in an acetone bath and patterned ITO substrates are cleaned with acetone and isopropanol. Finally, substrates are dried with dry N₂ gun.

TiO₂ film preparation: 200 μL of anatase TiO₂ nanoparticles solution is spin-coated on above patterned ITO substrate at 5000 rpm for 30 s. The TiO₂ film is annealed at 200° C. for 15 min and its thickness is measured to be 65 nm with Dektak profilometer.

HgTe nanocrystals film preparation and EDT ligand exchange in air free conditions: Film preparation and ligand exchange is carried out inside N₂ filled glovebox. In a typical procedure, 80 μL of concentrated HgTe nanocrystals (25 mg/mL) from toluene is spin-coated at 2000 rpm for 30 s on above fabricated Glass/ITO/TiO₂ substrate. After complete evaporation of solvent, ligand exchange is carried out by dipping the film in 1-2 wt % EDT solution in ethanol for 90 s and rinsing it in pure ethanol for 30 s. Afterwards, a quick annealing step at low temperature (50° C.) for 1 min is carried out. This procedure is repeated for 8-9 times to get thicker (180-200 nm) and pin-hole free HgTe film

Au electrode deposition in air free conditions: Fabricated Glass/ITO/TiO₂/HgTe substrate was transferred from glove box to the thermal evaporator chamber under N₂ environment. 80 nm thick Au was evaporated at a rate of 2-5 A/s using shadow mask (1 mm width) technique and the mask was aligned to get a pixel of 1×1 mm area.

Encapsulation of device: Finally, the fabricated device is transferred back to the glove box under N₂ environment. PMMA (5 wt % in CHCl₃) solution is spin-coated on substrates at 2000 rpm for 60 s, then a quick annealing step at 50° C. for 1 min is performed.

In next steps, PVA (centrifuged solution at 10 wt% in water) and PVDF (10 wt % in DMF) are spin-coated at 4000 rpm for 60 s and 1500 rpm for 30 s, respectively. At each step, substrates are annealed for 1 min at 50° C. Finally, device is kept in vacuum overnight for complete drying of encapsulation layers. Thus, obtained thicknesses for these encapsulating layers are found to be 1.3 μm, 0.5 μm and 0.5 μm of PMMA, PVA and PVDF, respectively.

### Example 50: Photovoltaic Device Fabrication-Second Strategy

A glass substrate with FTO coated is commercially purchased. On the FTO layer, AZ5214 resist is spin-coated for 30 s at 4000 rpm and then baked for 90 s at 110° C. on a hot plate. The film is then coated with (fresh) zinc powder and dipped for 6 minutes in 2M HCl. The film is finally rinsed using water, then acetone, then isopropanol. The film is then further cleaned using O₂ plasma for 30 min.

A solution of undoped ZnO nanocrystals is spin-coated over two steps to form a 100-200 nm thick layer of ZnO. The film is then annealed to 200° C. for 15 min.

Then inside a N₂ filled glovebox. 80 μL of concentrated HgTe nanocrystals (25 mg/mL) with ambipolar behavior and a band edge at 4000 cm⁻¹ from toluene is spin coated at 2000 rpm for 30 s on above fabricated Glass/ITO/TiO₂ substrates. After complete evaporation of solvent, ligand exchange is carried out by dipping the film in 1-2 wt % EDT solution in ethanol for 90 s and rinsing it in pure ethanol for 30 s. Afterwards, a quick annealing step at low temperature (50° C.) for 1 min is carried out. This procedure is repeated for 8-9 times to get thicker (180-200 nm) and pin-hole free HgTe film.

A final layer of HgTe nanocrystals with a p-type behavior and a band edge at 6000 cm⁻¹ is deposited and ligand exchange using the same procedure as describe above.

The film is then transferred in air free condition to an evaporator connected to the glove box, where 40 nm of MoO₃ and 80 nm of gold are thermally evaporated. The sample is then brought to the air free glove box to deposit the encapsulating layer. PMMA (5 wt % in CHCl₃) solution is spin-coated on substrates at 2000 rpm for 60 s, then a quick annealing step at 50° C. for 1 min is performed. In next steps, PVA (centrifuged solution at 10 wt % in water) and PVDF (10 wt % in DMF) are spin-coated at 4000 rpm for 60 s and 1500 rpm for 30 s, respectively. At each step, the device is annealed for 1 min at 50° C. Finally, device is kept in vacuum overnight for complete drying of encapsulating layers. Thus, obtained thicknesses for these encapsulating layers are found to be 1.3 μm, 0.5 μm and 0.5 μm of PMMA, PVA and PVDF, respectively.

### Example 51: Photovoltaic Device Fabrication-Strategy for Mid Wave Detection with Back Side Illumination

A sapphire wafer is sliced and used as 3-5 μm transparent substrate. Then a bottom partly transparent need to be designed, as follow. Using previously described optical lithography a metallic grid with a low filling factor (25% typically) is used to form an array of electrodes. This part of the electrodes is here to collect the current with low access resistance. These electrodes are made of 5 nm of Cr and 200 nm of gold. The design of the mask is optimized to make collection of carrier occurs on a length scale always smaller than 10 μm. Then using a second optical lithography step, a thin (from 5 to 10 nm) metallic layer is deposited on the first metallic grid to improve the charge collection while preserving the bottom electrode transparency.

A solution of TiO₂ nanoparticles is then spin-coated and annealed at 200° C. for 15 min to form a 60-70 nm thick TiO₂ layer.

Then inside a N₂ filled glovebox, 80 μL of concentrated HgTe nanocrystals (25 mg/mL) with ambipolar behavior and a band edge at 2000 cm⁻¹ from toluene is spin coated at 2000 rpm for 30 s on above fabricated Glass/ITO/TiO₂ substrates. After complete evaporation of solvent, ligand exchange is carried out by dipping the film in 1-2 wt % EDT solution in ethanol for 90 s and rinsing it in pure ethanol for 30 s. Afterwards, a quick annealing step at low temperature (50° C.) for 1 min is carried out. This procedure is repeated for 8-9 times to get thicker (180-200 nm) and pin-hole free HgTe film.

The film is then transferred in air free condition to an evaporator connected to the glove box, where 40 nm of MoO₃ and 80 nm of gold are thermally evaporated. The sample is then brought to the air free glove box to deposit the encapsulation layer. PMMA (5 wt % in CHCl₃) solution is spin-coated on the device at 2000 rpm for 60 s, then a quick annealing step at 50° C. for 1 min is performed. In next steps, PVA (centrifuged solution at 10 wt % in water) and PVDF (10 wt % in DMF) are spin-coated at 4000 rpm for 60 s and 1500 rpm for 30 s, respectively. At each step, the device is annealed for 1 min at 50° C. Finally, device is kept in vacuum overnight for complete drying of encapsulating layers. Thus, obtained thicknesses for these encapsulating layers are found to be 1.3 μm, 0.5 μm and 0.5 μm of PMMA, PVA and PVDF, respectively.

### Example 52: Design of an Intraband Photodiode

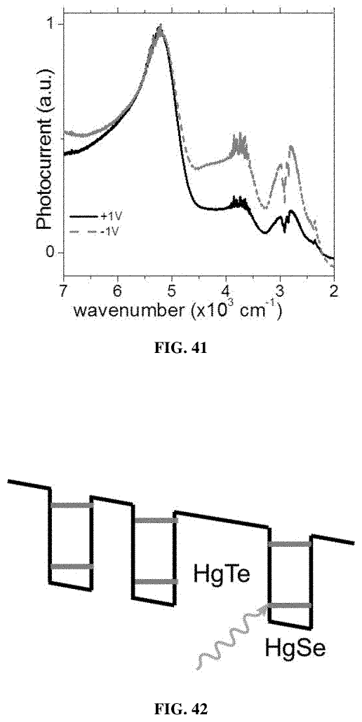

Onto a sapphire substrate, a grid made of Al or Ag is deposited using conventional optical lithography method. This grid has a low filling factor (20-30%) to let the light pass through the grid and allow back side illumination of the device. A layer of HgTe nanocrystals with a band edge energy of 6000 cm⁻¹ is spin coated on top of the metallic grid. A step of ligand exchange toward ethanedithiol is conducted. Then a mixture made of 75% of HgTe nanocrystals with a band edge energy at 4000 cm⁻¹ and 25% of HgSe nanocrystals with an intraband feature at 2500 cm⁻¹ is prepared and spin coated on top of the previous layer. A schematic representation of the conduction band profile of the mixture is given in FIG. 42. This mixture is spin-coated and ligand exchanged several times to form a 200 nm thick film. On top of this layer, a gold contact is evaporated. A schematic representation of the device is given in FIG. 40. Said device comprises a first contact 41, a unipolar barrier 42, a photoactive layer 34 and a second contact 43. A photocurrent spectrum of the device is given in FIG. 41.

### Example 53: High Temperature Synthesis

0.5 g of Hg(acetate)₂ is dissolved in 10 mL oleic acid and 25 mL oleylamine in a 50 mL three-neck flask. The solution is then degassed under vacuum at 85° C. during 1 hour. After switching the atmosphere to Ar, the temperature is raised to 150° C. While at temperatyure below 120° C., the solution is clear with a yellowish aspect, we observe for temperature above 150° C. the formation of a grey liquid ball at the bottom of the flask. The latter is characteristic from liquid mercury. Under injection of TOPSe, no HgSe nanocrystals are formed.

### REFERENCES

1—Insulating SiO₂ layer

2—Nanocrystals photoabsorptive film

21—Source

22—Drain

23—Electrolyte

24—Top gate electrode

25—Doped Si substrate

3—Device

31—Substrate

32—Electronic contact layer

321—First electronic contact layer

322—Second electronic contact layer

33—Electron transport layer

34—Photoactive layer

35—Hole transport layer

36—Encapsulating layer

361—First encapsulating layer

362—Second encapsulating layer

363—Third encapsulating layer

37—Contact pad

38—Interdigitated electrodes

41—First contact

42—Unipolar barrier

43—Second contact

1-48. (canceled)

49. A device comprising:
at least one substrate;
at least one electronic contact layer;
at least one electron transport layer; and
at least one photoactive layer;
wherein said device has a vertical geometry;
wherein the at least one photoactive layer is a layer or a film comprising a plurality of metal chalcogenide nanocrystals AₙXₘ having an optical absorption feature above 12 μm;
wherein said metal A is selected from Hg, Pb, Ag, Bi, Cd, Sn, Sb or a mixture thereof;
wherein said chalcogen X is selected from S, Se, Te or a mixture thereof; and
wherein n and m are independently a decimal number from 0 to 5 and are not simultaneously equal to 0.

50. The device according to claim 49, further comprising at least one hole transport layer.

51. The device according to claim 49, wherein the at least one electron transport layer comprises at least one n-type oxide or at least one n-type polymer.

52. The device according to claim 51, wherein the n-type oxide is selected from ZnO, aluminum doped zinc oxide, TiO₂, Cr₂O₃, CuO, CuO₂, Cu₂O, Cu₂O₃, SnO₂, ZrO₂, MoO₃, mixed oxides, or a mixture thereof.

53. The device according to claim 51, wherein n-type polymer is selected from polyethylenimine, poly(sulfobetaine methacrylate), amidoamine-functionalized polyfluorene, or a mixture thereof.

54. The device according to claim 50, wherein the at least one hole transport layer comprises a p-type oxide.

55. The device according to claim 54, wherein the at least one hole transport layer comprises molybdenum trioxide MoO₃, vanadium pentoxide V₂O₅, tungsten trioxide WO₃, nickel oxide NiO, chromium oxide CrOₓ, rhenium oxide ReO₃, ruthenium oxide RuOₓ, cuprous oxide Cu₂O, cupric oxide CuO, or a mixture thereof; wherein x is a decimal number ranging from 0 to 5.

56. The device according to claim 49, wherein the at least one electronic contact layer is a metal contact.

57. The device according to claim 49, further comprising at least one encapsulating layer.

58. The device according to claim 57, wherein the at least one encapsulating layer is an inorganic layer or a polymer layer.

59. The device according to claim 57, wherein the device comprises three encapsulating layers.

60. The device according to claim 59, wherein:
the first encapsulating layer comprises poly(methyl methacrylate), poly(lauryl methacrylate), poly(maleic anhydride-alt- 1-octadecene) or a mixture thereof;
the second encapsulating layer comprises polyvinyl alcohol; and
the third encapsulating layer comprises a fluorinated polymer

61. The device according to claim 49, being an intraband photodiode.

62. The device according to claim 61, wherein the intraband photodiode further comprises a unipolar barrier.
